(19) United States
(12) Patent Application Publication
(10) Pub. No.: US 2025/0088396 A1
(43) Pub. Date: Mar. 13, 2025

(54) METHOD AND APPARATUS TO PROVIDE FREQUENCY TRANSLATION OF AUDIO SIGNAL VIA SWITCHING AND/OR DC RESTORATION

(71) Applicant: Ronald Quan, Cupertino, CA (US)

(72) Inventor: Ronald Quan, Cupertino, CA (US)

(21) Appl. No.: 18/824,411

(22) Filed: Sep. 4, 2024

Related U.S. Application Data
(60) Provisional application No. 63/537,496, filed on Sep. 9, 2023.

(51) Int. Cl. H04L 25/49; H03F 3/217; H04L 27/00

(52) U.S. Cl. CPC H04L 25/4902; H03F 3/2176; H04L 2027/0057

(57) ABSTRACT

Methods and apparatuses for providing a signal sideband signal via one or more switching method or apparatus. Pulse width modulation is utilized and high efficiency of amplification is provided via a switch mode amplifier. DC restoration may provide for improved carrier suppression. Also subtraction of complementary pulse width modulated signals provides for a multiplier circuit or a multiplier function. A nonlinear carrier signal coupled to a pulsewidth modulator provides for improved amplitude modulation linearity and/or reduced sideband distortion.

This application claims benefit of U.S. provisional Ser. No. 63/537,496 filed Sep. 9, 2023, which is incorporated by reference.

### BACKGROUND

This patent application pertains to processing signals.

### SUMMARY

One or more embodiments includes pulsewidth modulation of at least one of the following: 1) A leading edge of a first signal and a trailing edge of a second signal; 2) A trailing edge of a second signal and a leading edge of a second signal; 3) A leading edge and a trailing edge of a first signal, and a leading edge and a trailing edge of a second signal.

One or more embodiments may include a method and/or apparatus to provide a single sideband signal. One or more embodiments may include providing a one or more signals to enable efficient amplification (e.g., efficient amplification may include a switch mode amplifier, or may include Class D, E, S or the like amplifier circuit or topology).

One or more embodiments may include at least one method to reduce phase modulation from another modulated signal (e.g., reducing phase modulation from an amplitude modulated signal and/or single sideband signal.).

One or more embodiments may include a DC (direct current) restoration circuit, a clamp circuit, a peak detector, a zero crossing detector, and/or a gating circuit. For example a DC (direct current) restoration circuit, a clamp circuit, a peak detector, a zero crossing detector, and/or a gating circuit may be utilized to provide an improved carrier suppression method/apparatus in generating a single sideband signal or a frequency translated signal. In one example an audio signal (or modulating signal) is coupled to an input of a DC restoration circuit whereby an output signal from a DC restoration signal is coupled to a pulse width modulation circuit, a pulse width modulation system, and/or to a modulation system or circuit.

Another embodiment may includes coupling an audio signal to an input terminal of an audio operated switch, voice operated switch (e.g., also known as a VOX or VOX audio processor), or a gating system/circuit. An output signal (e.g., from an audio signal) from an audio operated switch, voice operated switch (e.g., also known as a VOX or VOX audio processor), or a gating system/circuit is for example coupled to a pulse width modulation circuit, a pulse width modulation system, and/or to a modulation system or circuit. One or more of these devices in this paragraph may be used to reduce a carrier signal of a modulated signal (e.g., improve carrier suppression).

An embodiment may include a DC (direct current) restoration circuit, a clamp circuit, a peak detector, a zero crossing detector, and/or a gating circuit. For example a DC (direct current) restoration circuit, a clamp circuit, a peak detector, a zero crossing detector, an audio operated switch, voice operated switch (e.g., also known as a VOX or VOX audio processor), and/or a gating circuit/system.

### BRIEF DESCRIPTION OF THE DRAWINGS

FIG. 1 shows block diagram of an example embodiment.

FIG. 2 shows examples of pulse width modulated signals.

FIG. 3 shows an example of a processed signal (e.g., such a DC restorated signal via a signal process by a DC restoration circuit or clamp circuit).

FIG. 4 shows one or more examples of pulse width modulated signals (e.g., multiplication of signals via pulse width modulation).

FIG. 5A shows an example embodiment, which may include In-Phase and Quadrature pulse modulated signals (e.g., a pulse modulated signal may include at least one pulse width modulated signal).

FIG. 5B shows an example embodiment, which may include In-Phase and/or Quadrature pulse modulated signals (e.g., a pulse modulated signal may include at least one pulse width modulated signal).

FIG. 5C shows an example embodiment (e.g., including a combination of pulse signals).

FIG. 6 shows an example embodiment (e.g., including one or more amplifying or switching devices).

FIG. 7 shows another example embodiment (e.g., including one or more amplifying or switching devices).

FIG. 8 shows one or more examples of pulsewidth modulation.

FIG. 9 shows one or more examples of pulsewidth modulation.

FIG. 10 shows an example embodiment (e.g., including combining two or more pulses).

FIG. 11 shows another example embodiment (e.g., including combining two or more pulses).

FIG. 12 shows another example embodiment (e.g., including combining two or more pulses).

FIG. 13 shows a modulating technique.

FIG. 14 shows example of pulsewidth modulation relating to a modulating technique.

FIG. 15 shows yet another modulating technique and/or an example of nonlinearity.

FIG. 16 shows at least one example of an embodiment (e.g., at least one DC restoration circuit).

FIG. 17 shows an embodiment including multiple phase signals.

FIG. 18 shows another embodiment including multiple phase signals.

FIG. 19 shows an embodiment including a combiner, logic function, and/or subtractor.

FIG. 20 shows an example embodiment for synthesizing or providing one or more single sideband signals.

FIG. 21 shows an example embodiment (e.g., including multiple phase modulated signals and/or multiple phase carrier signals and/or amplifier).

FIG. 22 shows an example embodiment (e.g., including multiple phase modulated signals and/or multiple phase carrier signals and/or amplifier system).

FIG. 23 shows an example embodiment (e.g., including multiple phase modulated signals and/or multiple phase carrier signals.

FIG. 24 shows one or more example embodiments including of multiple phase signals.

FIG. 25A shows an embodiment including an amplifier with multiple phase pulsewidth modulated signals.

FIG. 25B shows another embodiment including an amplifier with multiple phase pulsewidth modulated signals.

FIG. 26 shows an example embodiment including a nonlinear carrier signal pertaining to distortion reduction and/or pertaining to linearizing an amplitude modulated signal.

FIG. 27 shows an embodiment pertaining to distortion reduction.

FIG. 28 shows another embodiment pertaining processing an audio signal or processing a modulation signal.

FIG. 29 shows an example embodiment pertaining processing an audio signal or processing a modulation signal.

FIG. 30 shows another example embodiment pertaining processing an audio signal or processing a modulation signal.

FIG. 31 shows an embodiment pertaining processing an audio signal or processing a modulation signal.

FIG. 32 shows an example of an embodiment including multiple phase signals.

FIG. 33 shows another example of an embodiment including multiple phase signals.

FIG. 34 shows an example of (e.g., sideband) distortion reduction when utilizing a nonlinear carrier waveform/signal.

### DETAILED DESCRIPTION

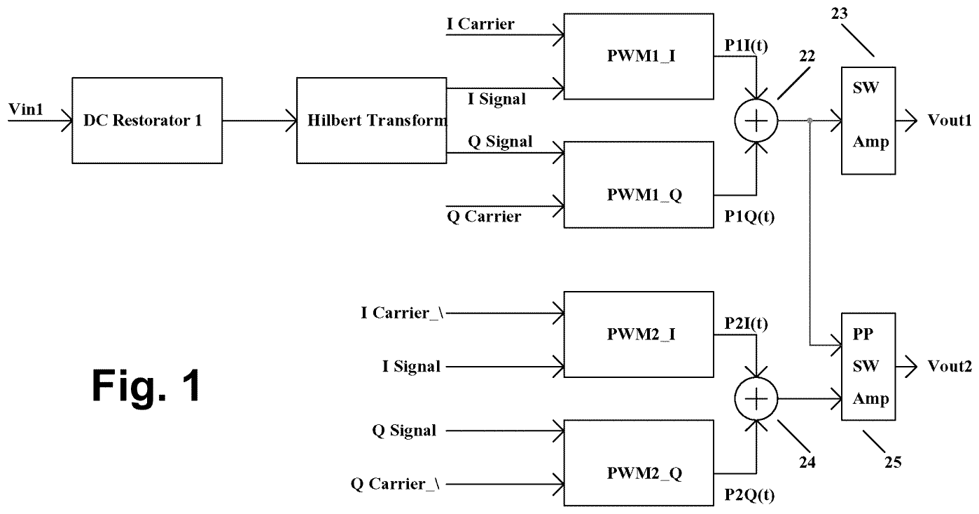

FIG. 1 shows an example embodiment (e.g., method or apparatus) to provide frequency translation of an input signal Vin1. One example of frequency translation is converting an audio signal to a single sideband signal of a higher frequency (e.g., a frequency in the Radio Frequency (RF) range, or a frequency within an audio range or a frequency beyond an audio range). For example, input signal Vin1 is coupled to a Hilbert Transform function/circuit to provide a 0 degrees phase shifted signal of Vin1, I Signal (e.g., a DC restored I Signal), and a 90 degrees phase shifted signal of Vin1, Q Signal (e.g., a DC restored Q Signal). In one example, Vin1 is coupled to an input of a DC restoration circuit/function and an output of a DC restoration circuit/function is coupled to a Hilbert Transform Alternatively, Vin1 may be coupled to an input of a Hilbert Transform and a Hilbert Transform may be coupled to a first DC restoration circuit/function, wherein an output of the first DC restoration circuit/function provides a DC restored I Signal and/or the Hilbert Transform may be coupled to a second DC restoration circuit/function, wherein an output of the second DC restoration circuit/function provides a DC restored Q Signal. A 0 degree phase shifted I Carrier signal, is coupled to a carrier signal input of a first pulse width modulator, PWM_I and an I Signal (e.g., associated with Vin1) is coupled to an I modulation input of the first pulse width modulator, PWM_1. Similarly, A 90 degree phase shifted Q Carrier signal, is coupled to a carrier signal input of a second pulse width modulator, PWM1_Q and a Q Signal (e.g., associated with Vin1) is coupled to a Q modulation input of the second pulse width modulator, PWM1_Q. A pulse width modulated signal, P1I(t), is provided by an output of pulse width modulator PWM1_I; pulse width modulated output signal P1I(t) provides an amplitude modulated signal, which approximates multiplication of I Carrier with I Signal, for example P1I(t)˜I Carrier×I Signal; similarly, a pulse width modulated signal, P1Q(t), is provided by an output of pulse width modulator PWM1_Q; pulse width modulated output signal P1Q(t) provides an amplitude modulated signal, which approximates multiplication of Q Carrier with Q Signal, for example P1Q(t)˜Q Carrier×Q Signal. A combiner, 22 (e.g., an OR gate, or alternatively, an adding function) combines pulse width modulated signals P1I(t) and P1Q(t), which combiner 22 output a signal indicative of a single sideband signal or a frequency translated signal of Vin1. Signals P1I(t) and P1Q(t) are 90 degrees apart (e.g., a quarter cycle apart or 90 phase difference from each other). Output of Combiner 22 is coupled to an input of switching amplifier SW Amp 23. Output signalVout1 from SW Amp provides single sideband signal (e.g., a single side band signal with suppressed carrier signal or a single sideband signal with carrier signal).

FIG. 1 also includes capability for push pull switching amplifier operation. For example inverted I Carrier signal, I Carrier_\, and inverted Q Carrier signal, Q Carrier_\are coupled to inputs of 3^{rd} and 4^{th} pulse width modulators PWM2_I and PWM2_Q as shown in FIG. 1. The I Signal and Q Signal are coupled to inputs of PWM2_I and PWM2_Q. Output signals P2I(t) and P2Q(t) from the 3^{rd} and 4^{th} pulse width modulators are combined via combiner 24 (e.g., similar to combiner 22). An output signal of combiner 24 is coupled to a second input of a push pull or differential (e.g., switching) amplifier 25, wherein an output signal from combiner 22 is coupled to a first input of push pull (or differential) switching amplifier 25. Output signal Vout2 is provided from an output of (e.g., push pull and/or switching) amplifier 25. Note: An I signal may be named as an In Phase signal, and/or a Q signal may be named as a Quadrature phase signal.

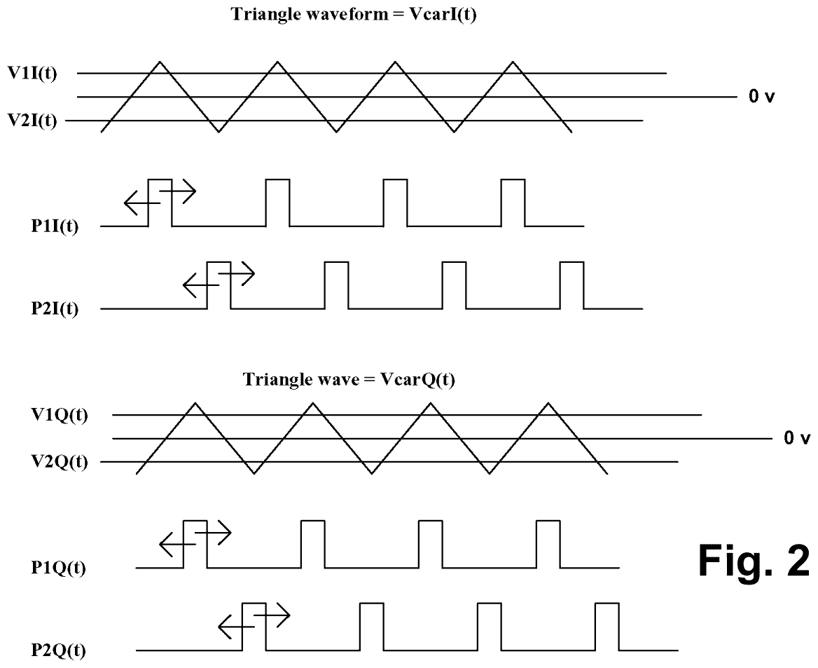

FIG. 2 shows examples of pulse width modulated signals of P1I(t) a first In Phase pulsewidth modulated signal, P2I(t) a second In Phase pulsewidth modulated signal, P1Q(t) a first Quadrature Phase pulsewidth modulated signal, and P2Q(t) a second Quadrature Phase pulsewidth modulated signal. Note that V1I(t) includes a first In Phase modulating signal, V2I(t) includes a second In Phase modulating signal, V1Q(t) includes a first Quadrature Phase modulating signal, and/or V2Q(t) includes a second Quadrature Phase modulating signal. Although the modulated edges are shown with ← and → on the first pulses of each waveform/signal P1I(t), P2I(t), P1Q(t) and P2Q(t), the modulated edges denoted by ← and → may be repeated or implemented for other (e.g., 3) pulses in each of P1I(t), P2I(t), P1Q(t) and/or P2Q(t). Note that FIG. 2 shows just one example and other pulse width, frequency, period, duration, and/or edge modulation (e.g., single and/or double edge) may be utilized. Triangle waveforms include an In Phase carrier signal, VcarrI(t), and a Quadrature Phase carrier signal VcarrQ(t). For example, VcarrI(t) may be coupled to a first input terminal of first comparator and a first input of a second comparator, wherein a modulating I signal (e.g., In Phase modulating signal such as V1I(t)) may be coupled to a second terminal of the first comparator and a modulating Q signal (e.g., Quadrature Phase modulating signal such as V1Q(t)) may be coupled to a second terminal of the second comparator. Output terminals of the first and second comparators provide pulse width modulated signals such P1I(t) and P1Q(t). A third and a fourth comparator is utilized similarly which may provide at their outputs provide pulse width modulated signals such P2I(t) and P2Q(t) via modulation signal V2I(t) with carrier signal VcarI(t) and/or via modulation signal V2Q(t) and carrier signal VcarQ(t).

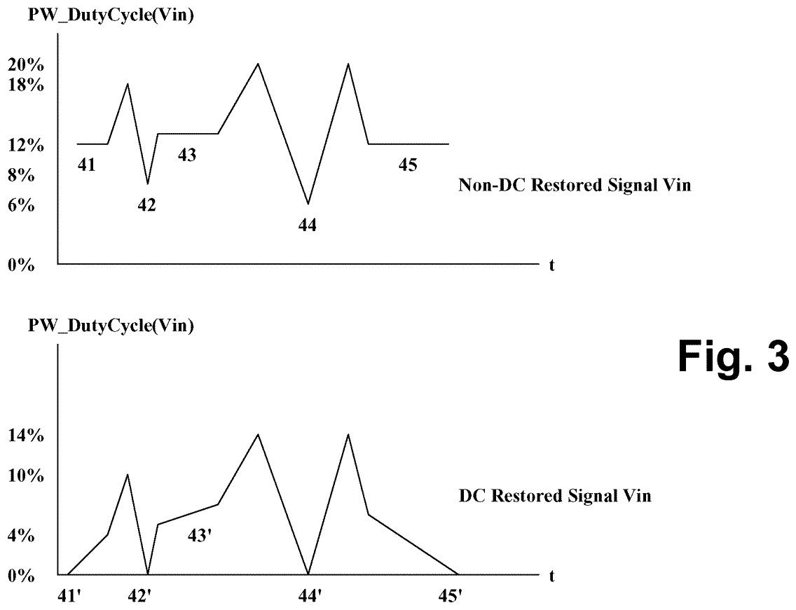

FIG. 3 shows examples of a modulating signal with sections 41, 41, 43, 44, and 45, which is not DC restored. Sections 41, 43, and 45 may represent a no signal condition (e.g., such as a pause in voice or music). At the no signal condition, an output of a pulsewidth modulator shows for example a 12% duty cycle (e.g., other duty cycle numbers may be used). This means that a residual carrier is present when the modulating signal is at rest or zero. To provide improved or further suppression of a carrier signal at the no signal condition of sections 41, 43, and 45, the modulating signal may be processed via a DC restoration circuit or function. FIG. 3 bottom section shows that the no signal condition sections 41′ and 45′ goes to zero pulse width, which provides improved carrier suppression (e.g., for a single side band signal). For example, a DC restoration circuit or function in FIG. 3 provides restored negative peaks 42′ and 44′ to 0% pulse width, whereas in a non restored example negative peak 42 provides an 8% duty cycle pulse width and negative peak 44 provides a 6% duty cycle pulse width. Processing a modulating signal with DC restoration provides for higher carrier suppression (e.g., while maintaining intelligible transmission). Alternatively a DC restoration circuit/function may be substituted with a voice operated gate circuit/function (e.g., VOX) for improved carrier suppression. A combination of DC restoration and/or voice operated gate may be utilized (e.g., for improving carrier suppression on a signal such as a single side band signal).

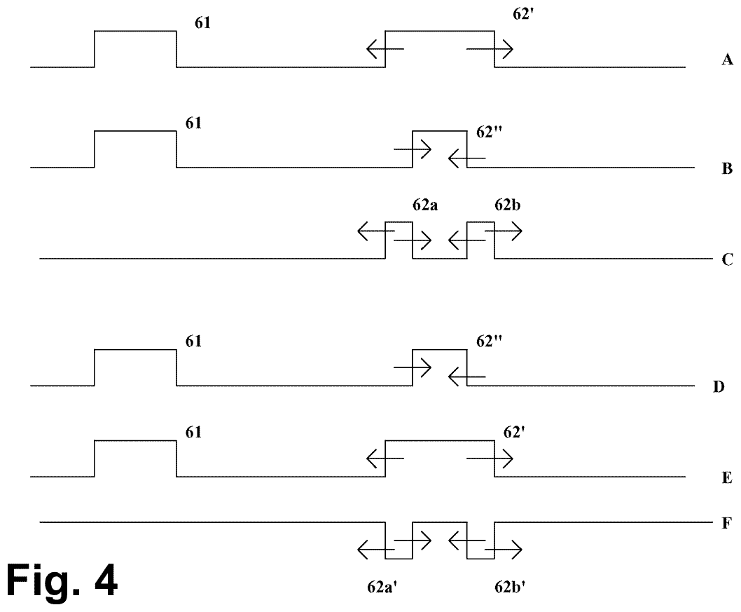

FIG. 4 shows an example of multiplying (e.g., 2) signals, a carrier and modulating signal, wherein a carrier signal is suppressed or canceled out; for example, in FIG. 4 waveform 61 in “A” and waveform 61 in “B” subtract to zero at a no modulation condition. Two waveforms are provided wherein a first waveform is pulse width modulated in an increasing duty cycle manner (e.g., see FIG. 4 “A” 62′) and a second waveform is pulse width modulated in a decreasing duty cycle manner (e.g., see FIG. 4 “B” 62″). The two waveforms (e.g., “A” and “B”) are subtracted (e.g., via a differencing circuit or function, which may include a transformer or balun) to provide a waveform such as shown in FIG. 4 “C” with one or more pulse width modulated pulses/signals, 62a and/or 62b. Waveform “C” for example with pulse width modulated signals 62a and/or 62b provides a multiplication of a two signals such as Vmodulation×Vcarrier, wherein a carrier signal is canceled out (e.g., see FIG. 4 “A” and “B” and note that an unmodulated signal 61 is canceled out by subtraction in FIG. 4 “C”, wherein 61 is missing or cancelled out). Similarly FIG. 4 waveforms “D” and “E” shows a decreasing pulse width modulated signal 62″ subtracted by an increasing pulse width modulated signal 62′, which is provided by waveform “F”, which shows pulse width modulated signals 62a′ and/or 62b′ with unmodulated signal 61 missing, canceled, or attenuated in “F” via subtraction.

FIG. 4 shows an example of providing multiplication of two signals with carrier suppression (e.g., at zero modulation) with switch mode (or with digital) signals. By using two multiplier circuits via pulse width modulation, a single sideband signal (or frequency translated signal) may be provided. For example each subtracted signal output signal at “A” (e.g., “A” minus “B”) can be characterized as a multiplier, and a single sideband signal may be characterized as: SSB signal=(I Modulation Signal multiplied by I Carrier signal) plus/minus (Q Modulation Signal multiplied by Q Carrier signal). Note in FIG. 4 increasing and decreasing pulse width modulated signals may be provided by a push pull modulating signal or differential modulating signal.

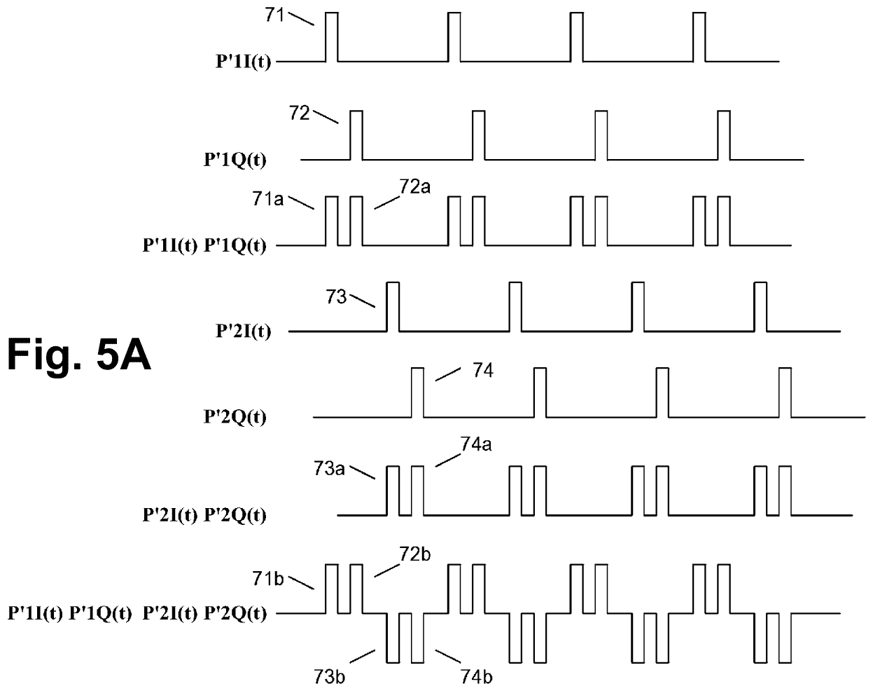

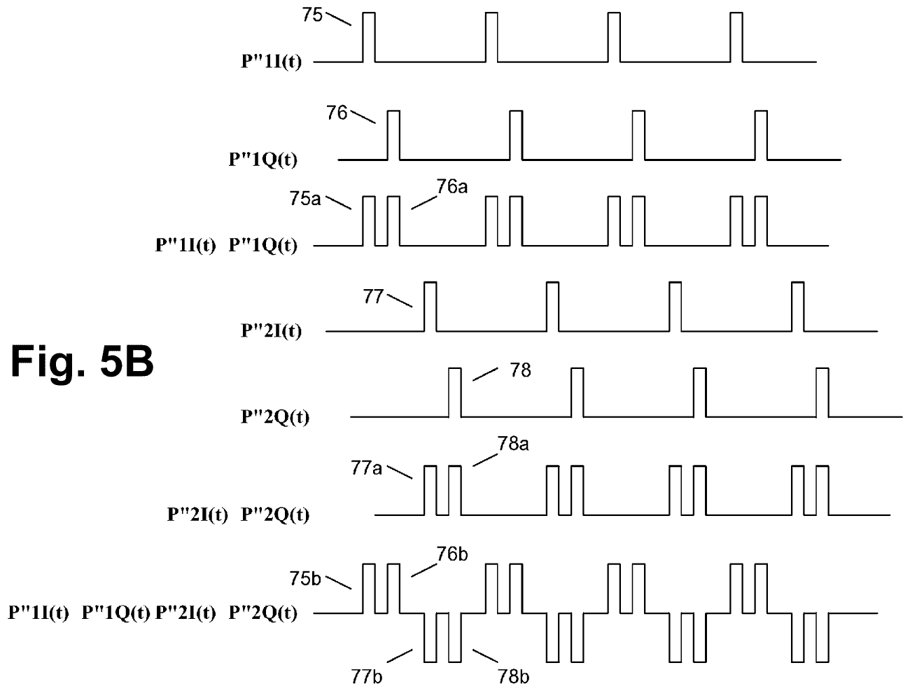

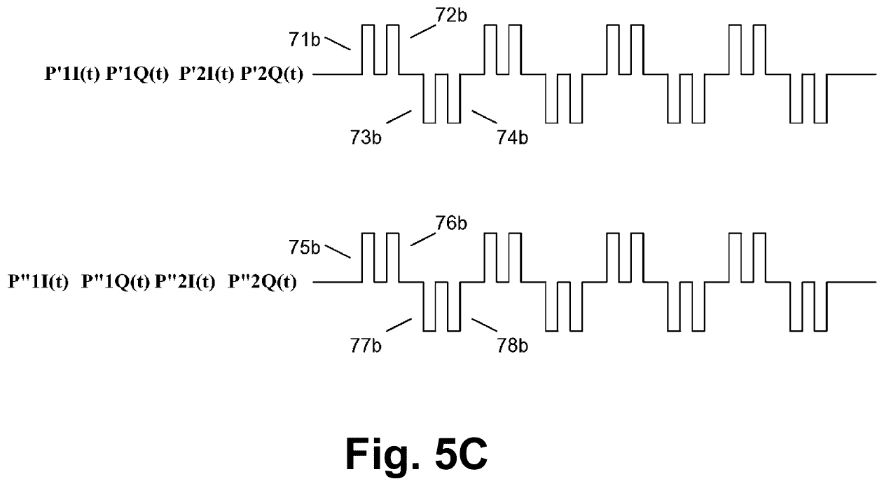

FIG. 5A shows an example method of providing a single sideband signal. Pulses 71, 72, 71a, 72a, 73, 74, 73a, 74a, 71b, 72b, 73b, and/or 74b may include pulse width modulation of one or more edges (e.g., leading edge and/or trailing edge). Should one or more modulating signal(s) include a bias/condition such that at zero amplitude modulating signal, the pulsewidth of pulses 71, 72, 71a, 72a, 73, 74, 73a, 74a, 71b, 72b, 73b, and/or 74b will provide a finite pulsewidth that includes a residual carrier signal. In one example to remove or to attenuate a residual carrier when the modulating signal has a low or zero amplitude, DC restoration is utilized. In one embodiment a DC restoration circuit/function which processes In Phase and/or Quadrature Phase modulating signals provides a near zero pulsewidth or zero pulsewidth of one or more pulses when the modulating signal is at near zero amplitude or at zero amplitude.

FIG. 5A illustrates an example of optimizing in providing efficiency of power output over a time interval (e.g., period or cycle). Pulse 71 (e.g., P′1I(t)) shows an example of an In Phase carrier pulsewidth modulated by an In Phase modulating signal. Pulse 72 (e.g., P′1Q(t)) shows an example of a Quadrature Phase carrier pulsewidth modulated by a Quadrature Phase modulating signal. Waveform P′1I(t) P′1Q(t) shows a combination (e.g., combining, adding, or logically providing an OR function) of pulses shown in P′1I(t) and P′1Q(t), which for example is shown as a combination of pulse 71 and pulse 72 providing pulses 71a and 72a shown in P′1I(t) P′1Q(t). Pulses 71a and 72a provide a single sideband signal comprising a carrier signal and a first sideband signal (e.g., first sideband signal, a lower sideband signal or an upper sideband signal; or for example, first sideband signal of either a lower sideband signal or an upper sideband signal).

In FIG. 5A waveform P′2I(t) shows pulse 73, an In Phase carrier signal with a phase shift (e.g., 180 degrees from pulse 71) modulated (e.g., pulsewidth modulated) by an In Phase modulating signal. Waveform P′2Q(t) shows pulse 74, a Quadrature Phase carrier signal with a phase shift (e.g., 180 degrees from pulse 72) modulated (e.g., pulsewidth modulated) by a Quadrature Phase modulating signal. Waveform P′2I(t) P′2Q(t) shows a combination (e.g., combining, adding, or logically providing an OR function) of pulses shown in P′2I(t) and P′2Q(t), which for example is shown as a combination of pulse 73 and pulse 74 providing pulses 73a and 74a (as shown in P′2I(t) P′2Q(t)). Pulses 73a and 74a provide another single sideband signal (e.g., phase shifted from pulses 71a and 72a) for comprising a (e.g., phase shifted) carrier signal and a first sideband signal or another first sideband signal (e.g., first sideband signal, a lower sideband signal or an upper sideband signal; or for example, first sideband signal of either a lower sideband signal or an upper sideband signal).

FIG. 5A shows an example optimizing power per unit time (or cycle of carrier) by combining providing a differential or tri-level signal via waveform P′1I(t) P′1Q(t) and an inverted version of waveform P′2I(t) P′2Q(t), or vice versa (e.g., inverted P′1I(t) P′1Q(t) combined with non-inverted P′2I(t) P′2Q(t)). An illustration of providing a differential or tri-level signal is shown by signal P′1I(t) P′1Q(t) P′2I(t) P′2Q(t), with example (e.g., positive going) pulses 71b and 72b (e.g., non-negative values) and example (e.g., negative going) pulses 73b and 74b (e.g., non-positive values). Signal P′1I(t) P′1Q(t) P′2I(t) P′2Q(t) illustrates a single sideband signal with carrier and/or signal P′1I(t) P′1Q(t) P′2I(t) P′2Q(t) may be filtered (e.g., coupling to an input of a band pass filter and/or an input of a low pass filter) to provide an amplitude modulated single sideband signal (e.g., including a carrier signal) from a filter output terminal.

In FIG. 5A, an example of (e.g., carrier signal) phase (e.g., shift) values for pulses may include the following: 0 degree phase pulse(s) may include 71, 71a, and/or 71b; 90 degrees phase pulse(s) may include 72, 72a, and/or 72b; 180 degrees phase pulse(s) may include 73,73a, and/or 73b; 270 degrees phase pulse(s) may include 74, 74a, and/or 74b. Note in the FIG. 5A, for example, pulses 73b and 74b have been (e.g., further) inverted to provide negative going pulses.

In FIG. 5A a single sideband signal is provided by P′1I(t) P′1Q(t), P′2I(t) P′2Q(t), and/or P′1I(t) P′1Q(t) P′2I(t) P′2Q(t). In FIG. 5A a single sideband signal with a carrier signal is provided by P′1I(t) P′1Q(t), P′2I(t) P′2Q(t), and/or P′1I(t) P′1Q (t) P′2I(t) P′2Q(t).

FIG. 5B shows an example method of providing a single sideband signal. Pulses 75, 76, 75a, 76a, 77, 78, 77a, 78a, 75b, 76b, 77b, and/or 78b may include pulse width modulation of one or more edges (e.g., leading edge and/or trailing edge). Should one or more modulating signal(s) include a bias/condition such that at zero amplitude modulating signal, the pulsewidth of pulses 75, 76, 75a, 76a, 77, 78, 77a, 78a, 75b, 76b, 77b, and/or 78b will provide a finite pulsewidth that includes a residual carrier signal. In one example to remove or to attenuate a residual carrier when the modulating signal has a low or zero amplitude, DC restoration is utilized. In one embodiment a DC restoration circuit/function which processes In Phase and/or Quadrature Phase modulating signals provides a near zero pulsewidth or zero pulsewidth of one or more pulses when the modulating signal is at near zero amplitude or at zero amplitude.

FIG. 5B illustrates an example of optimizing in providing efficiency of power output over a time interval (e.g., period or cycle). Pulse 75 (e.g., P″1I(t)) shows an example of an In Phase carrier pulsewidth modulated by an In Phase modulating signal. Pulse 76 (e.g., P″1Q(t)) shows an example of a Quadrature Phase carrier pulsewidth modulated by a Quadrature Phase modulating signal. Waveform P″1I(t) P″1Q(t) shows a combination (e.g., combining, adding, or logically providing an OR function) of pulses shown in P″1I(t) and P″1Q(t), which for example is shown as a combination of pulse 75 and pulse 76 providing pulses 75a and 76a shown in P″1I(t) P″1Q(t). Pulses 75a and 76a provide a single sideband signal comprising a carrier signal and a first sideband signal (e.g., first sideband signal, a lower sideband signal or an upper sideband signal; or for example, first sideband signal of either a lower sideband signal or an upper sideband signal).

In FIG. 5B waveform P″2I(t) shows pulse 77, an In Phase carrier signal with a phase shift (e.g., 180 degrees from pulse 75) modulated (e.g., pulsewidth modulated) by an In Phase modulating signal. Waveform P″2Q(t) shows pulse 78, a Quadrature Phase carrier signal with a phase shift (e.g., 180 degrees from pulse 76) modulated (e.g., pulsewidth modulated) by a Quadrature Phase modulating signal. Waveform P″2I(t) P″2Q(t) shows a combination (e.g., combining, adding, or logically providing an OR function) of pulses shown in P″2I(t) and P″2Q(t), which for example is shown as a combination of pulse 77 and pulse 78 providing pulses 77a and 78a (as shown in P″2I(t) P″2Q(t)). Pulses 77a and 78a provide another single sideband signal (e.g., phase shifted from pulses 75a and 76a) for comprising a (e.g., phase shifted) carrier signal and a first sideband signal or another first sideband signal (e.g., first sideband signal, a lower sideband signal or an upper sideband signal; or for example, first sideband signal of either a lower sideband signal or an upper sideband signal).

FIG. 5B shows an example optimizing power per unit time (or cycle of carrier) by combining providing a differential or tri-level signal via waveform P″1I(t) P″1Q(t) and an inverted version of waveform P″2I(t) P″2Q(t), or vice versa (e.g., inverted P″1I(t) P″1Q(t) combined with non-inverted P″2I(t) P″2Q(t)). An illustration of providing a differential or tri-level signal is shown by signal P″1I (t) P″1Q (t) P″2I(t) P″2Q(t), with example (e.g., positive going) pulses 75b and 76b (e.g., non-negative values) and example (e.g., negative going) pulses 77b and 78b (e.g., non-positive values). Signal P″1I(t) P″1Q(t) P″2I(t) P″2Q(t) illustrates a single sideband signal with carrier and/or signal P″1I(t) P″1Q(t) P″2I(t) P″2Q(t) may be filtered (e.g., coupling to an input of a band pass filter and/or an input of a low pass filter) to provide an amplitude modulated single sideband signal (e.g., including a carrier signal) from a filter output terminal.

In FIG. 5B, an example of (e.g., carrier signal) phase (e.g., shift) values for pulses may include the following: 0 degree phase pulse(s) may include 75, 75a, and/or 75b; 90 degrees phase pulse(s) may include 76, 76a, and/or 76b; 180 degrees phase pulse(s) may include 77,77a, and/or 77b; 270 degrees phase pulse(s) may include 78, 78a, and/or 78b. Note in the FIG. 5A, for example, pulses 77b and 78b have been (e.g., further) inverted to provide negative going pulses.

In FIG. 5B a single sideband signal is provided by P″1I(t) P″1Q(t), P″2I(t) P″2Q(t), and/or P″1I(t) P″1Q(t) P″2I(t) P″2Q(t). In FIG. 5B a single sideband signal with a carrier signal is provided by P″1I(t) P″1Q(t), P″2I(t) P″2Q(t), and/or P″1I(t) P″1Q(t) P″2I(t) P″2Q(t).

One or more DC restoration circuit(s) or function(s) which will process the In Phase modulating signal and/or Quadrature Phase modulating signal may couple one or more DC restorated signals to at least one input terminal of at least one pulsewidth modulator to provide for a suppressed carrier single sideband signal when the amplitude of the (e.g., one or more) modulating signal(s) is zero or near zero.

Another embodiment may include a combination of pulsewidth modulated signal to provide a single sideband signal with suppressed carrier. FIG. 5C illustrates combining two waveforms, a first pulsewidth modulated waveform includes a first modulating signal which is processed in a non-inverting manner/method, and a second pulsewidth modulated waveform includes a second modulating signal whereby the second modulating signal is an inverted version (e.g., phase=180 degrees) of the first modulating signal. For example if the first modulating signal is denoted by m(t), then the second modulating signal is denoted by −m(t). In one example shown in FIG. 5C the top waveform or signal P′1I(t) P′1Q(t) P′2I(t) P′2Q(t) may include a modulating signal −m(t) to provide pulsewidth modulation on pulses 71b, 72b, 73b, and/or 74b; waveform or signal P″1I(t) P″1Q(t) P″2I(t) P″2Q(t) may include a (e.g., inverting) modulating signal −m(t) to pulsewidth modulation on pulses 75b, 76b, 77b, and/or 78b. To provide a single sideband suppressed carrier signal, signals P″1I(t) P″1Q(t) P″2I(t) P″2Q(t) and P′1I(t) P′1Q(t) P′2I(t) P′2Q(t) may be combined in a manner to include subtraction (e.g., combining may include subtraction or addition). Other methods of combining may include providing a combination logic function of (e.g., positive going) pulses 71b and 72b with pulses 75b and 76b and/or providing a combination logic function of (e.g., negative going) pulses 73b and 74b with pulses 77b and 78b.

For example in FIG. 5C a subtractive (or algebraic) process may provide at least a bipolar, bi-level, and/or tri-level signal single sideband signal. (e.g., a signal including positive, 0, and/or negative values).

[P″1I(t) P″1Q(t) P″2I(t) P″2Q(t)]−[P′1I(t) P′1Q(t) P′2I(t) P′2Q(t)]=SSBSC_1, a first single sideband suppressed carrier signal via pulse modulated waveforms.

Alternatively, the order of subtraction may be reversed to provide the following:

[P′1I(t) P′1Q(t) P′2I(t) P′2Q(t)]−[P″1I(t) P″1Q(t) P″2I(t) P″2Q(t)]=SSBSC_2, a second single sideband suppressed carrier signal via pulse modulated waveforms.

An illustrative example of combining positive going pulses result in combining positive going pulses which are pulsewidth modulated is shown in FIG. 4, waveform C. Alternatively combining negative going pulses which are pulsewidth modulated is shown in waveform F in FIG. 4. FIG. 4 shows for example in waveform A having been modulated with a modulation signal m(t), which shows expansion in pulsewidth, whereby FIG. 4, waveform B shows a modulation signal −m(t), which contraction in pulsewidth.

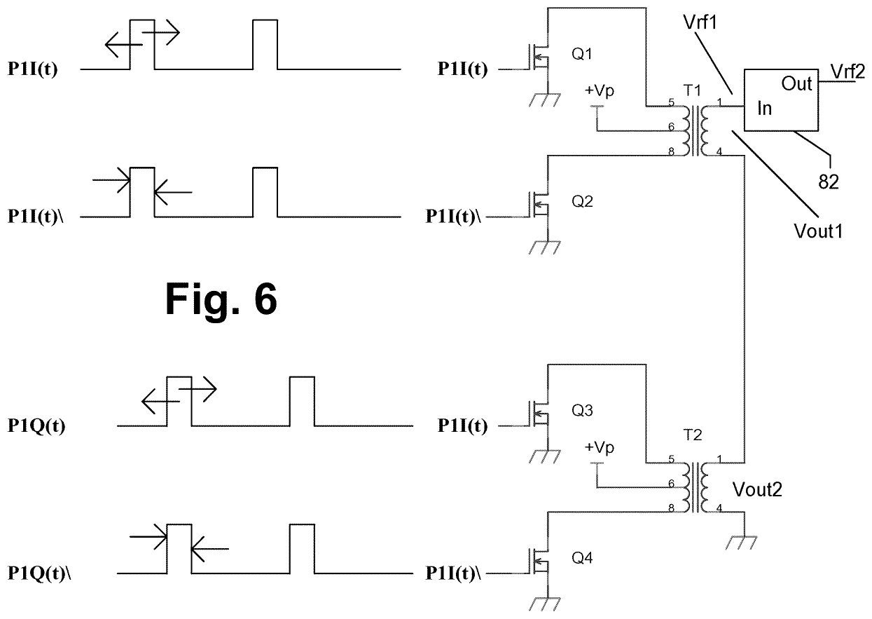

FIG. 6 shows an example embodiment utilizing a one or more push pull amplifiers to provide a single sideband signal (e.g., a single sideband signal with suppressed carrier or a single sideband single whose carrier is suppressed when modulation→0). In FIG. 6, waveform P1I(t) may include an In Phase carrier pulse which is pulsewidth modulated by an In Phase modulating signal such as m_{I}(t). Signal P1I(t) is coupled to a first input of a first push-pull amplifier (e.g., coupled to a gate of Q1 amplifying device such as a field effect transistor). Signal P1I(t)\ may represent an In Phase carrier pulse which is modulated by an inverted In Phase modulating signal such as −m_{I}(t). For example, for P1I(t) the pulsewidth widens with its modulating signal (e.g., m_{I}(t)) while for P1I(t)\ the pulsewidth narrows with its modulating signal (e.g. −m_{I}(t)). Signal P1I(t)\ is coupled to a second input of a first push-pull amplifier (e.g., coupled to a gate of Q2 amplifying device such as a field effect transistor). The gate of Q1 and the gate of Q2 provides for differential (e.g., subtractive), balanced, and/or push pull input terminals. Signals common to the first input and the second input of the first amplifier provide a canceled output signal (e.g., a common mode signal will provide near zero or zero output across the secondary winding of T1) such as canceled output signal across the drain terminal of Q1 and the drain terminal of Q2, or zero signal (or near zero signal) across the secondary winding of T1. When the modulating signal is at zero such as m_{I}(t)→0 and −m_{I}(t)→0, the pulsewidth P1I(t) and P1I(t)\ will be same (e.g., same non zero pulsewidth), which will provide a common mode signal, which is then canceled out at the output of the first amplifier (e.g., output signal across the secondary winding of T1); this cancelation is the cancelation (e.g., or subtraction) of a carrier signal (e.g., when the modulation signal has a zero amplitude). For one example, the first amplifier may be characterized as Vout1=k₁×(P1I(t)−P1I(t)\), a subtractive function, where Vout1 includes the voltage across the secondary winding of T1.

In FIG. 6 for another example where m_{I}(t) is positive, which for example widens the pulse of P1I(t), and with m_{I}(t) is positive results in −m_{I}(t)=negative value, or for example narrows the pulse of P1I(t)\. The output voltage from the first amplifier is then the voltage across the secondary winding of T1→Vout1=k₁×(P1I(t)−P1I(t)\); and this provides for example a pulse shown in FIG. 4 similar to waveform “C” or in FIG. 4 pulses 62a and/or 62b.

FIG. 6 includes Quadrature Phase carrier signal P1Q(t) pulsewidth modulated by a Quadrature Phase modulating signal and Quadrature Phase carrier signal P1Q(t)\ is modulated by an inverting Quadrature Phase modulating signal. Signal P1Q(t) is coupled to a first input of a second push-pull amplifier (e.g., coupled to a gate of Q3 amplifying device such as a field effect transistor). Signal P1Q(t)\ may represent a Quadrature Phase carrier pulse which is modulated by an inverted In Phase modulating signal such as −m_{Q}(t). For example, for P1Q(t) the pulsewidth widens with its modulating signal (e.g., m_{Q}(t)) while for P1I(t)\ the pulsewidth narrows with its modulating signal (e.g., −m_{Q}(t)). Signal P1Q(t)\ is coupled to a second input of a second push-pull amplifier (e.g., coupled to a gate of Q4 amplifying device such as a field effect transistor). The gate of Q3 and the gate of Q4 provide for differential (e.g., subtractive), balanced, and/or push pull input terminals. Signals common to the first input and the second input of the first amplifier provide a canceled output signal (e.g., a common mode signal will provide near zero or zero output across the secondary winding of T2) such as canceled output signal across the drain terminal of Q3 and the drain terminal of Q4, or zero signal (or near zero signal) across the secondary winding of T2. When the modulating signal is at zero such as m_{Q}(t)→0 and −m_{Q}(t)→0, the pulsewidth P1Q(t) and P1Q(t)\ will be same (e.g., same non zero pulsewidth), which will provide a common mode signal, which is then canceled out at the output of the first amplifier (e.g., output signal across the secondary winding of T2); this cancelation is the cancelation (e.g., or subtraction) of a carrier signal (e.g., when the modulation signal has a zero amplitude). For one example, the first amplifier may be characterized as Vout2=k₂×(P1Q(t)−P1Q(t)\), a subtractive function, where Vout2 includes the voltage across the secondary winding of T2.

In FIG. 6 signals from the secondary windings of transformers T1 and T2 are combined (e.g., added or subtracted) to provide a single sideband signal (e.g., Vref1). Block 82 may include a filter (e.g., band pass filter and/or low pass filter) to transform (or to convert) the pulse width modulated signals from the combined secondary winding signals (e.g., Vrf1) from T1 and T2 to an amplitude modulated single sideband signal at Vrf2.

FIG. 6 combines a signal from a first amplifier (e.g., including an In Phase carrier signal pulsewidth modulated by an In Phase modulating signal) and a signal from a second amplifier (e.g., including a Quadrature Phase carrier signal pulsewidth modulated by Quadrature Phase modulating signal) to provide at least one (e.g., amplitude modulated) single sideband signal (e.g., wherein the pulsewidth modulated signals from output terminals of the first amplifier and second amplifier include filtering such as bandpass filtering and/or low pass filtering).

FIG. 6 combines a signal from a first amplifier (e.g., including an In Phase carrier signal pulsewidth modulated by an In Phase (e.g., non zero) modulating signal) and a signal from a second amplifier (e.g., including a Quadrature Phase carrier signal pulsewidth modulated by a Quadrature Phase (e.g., non zero) modulating signal) to provide at least one (e.g., amplitude modulated) single sideband signal with a carrier signal present (e.g., wherein the pulsewidth modulated signals from output terminals of the first amplifier and second amplifier include filtering such as bandpass filtering and/or low pass filtering); wherein the carrier signal is present when the amplitude of the modulating signal (e.g., In Phase modulating signal and/or Quadrature Phase modulating signal) is non zero (e.g., m_{Q}(t)≠0 and/or −m_{Q}(t)≠0); and/or wherein the carrier signal is not present (e.g., carrier is suppressed) when the amplitude of the modulating signal (e.g., In Phase modulating signal and/or Quadrature Phase modulating signal) is zero (e.g., m_{Q}(t)=0 and/or −m_{q}(t)=0).

FIG. 6 may include an embodiment for providing signals to a switching amplifier (e.g., RF switching amplifier, Class D amplifier, Class E amplifier, and/or Class S amplifier). For example, devices Q1, Q2, Q3, and/or Q4 may be operated as switching devices. For instance, signals P1I(t), P1I(t)\ P1Q(t), and or P1Q(t)\ provide signals (e.g., such as binary signals or logic level signals) to one or more inputs to a switching amplifier; for example the gate terminals of Q1, Q2, Q3, and/or Q4 provide one or more inputs to switching amplifier (e.g., wherein an output of the switching amplifier provides a single sideband signal).

Alternatively the apparatus/method shown in FIG. 6 may include signals P1I(t), P1I(t)\ P1Q(t), and/or P1Q(t)\ coupled to one or more input terminals of a Class A, Class B, Class C, Class D, Class E, and/or Class S amplifier (e.g., wherein an output of the Class A, Class B, Class C, Class D, Class E, and/or Class S amplifier provides a single sideband signal).

FIG. 6 may provide an example embodiment of including binary signals to generate one or more single sideband signals. For example, providing a subtractive (or combinational logic function) to P1I(t), P1I(t)\,P1Q(t), and/or P1Q(t)\ and then combining in a manner to provide a single sideband signal. For example, [k₁×(P1I(t)−P1I(t)\)]±[k₂×(P1Q(t)—P1Q(t)\)] provides a single sideband signal.

Note that k₁ and/or k₂ are constants; or k₁ and/or k₂ may include time varying values.

In reference to FIG. 6, k₁×(P1I(t)−P1I(t)\) may be implemented with a first differential input device (e.g., a first differential amplifier, a first push pull amplifier, and/or a first transformer), and/or k₂×(P1Q(t)−P1Q(t)\) may be implemented with a second differential input device (e.g., a second differential amplifier, a second push pull amplifier, and/or a second transformer), whereby the an output of the first differential device is combined (e.g., addition, subtraction, and/or combinational logic) with an output of the second device to provide one or more single sideband signals.

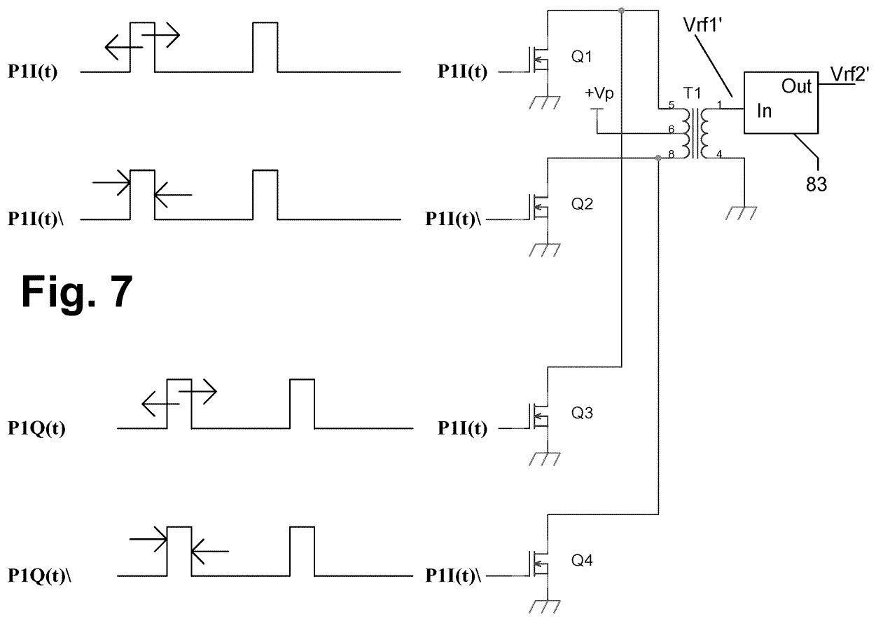

FIG. 7 shows another embodiment to provide a single sideband signal via pulsewidth modulated signals. In Phase carrier signal, P1I(t), is pulsewidth modulated by an In Phase modulating signal and In Phase carrier signal, P1I(t)\, is pulsewidth modulated by an inverting In Phase modulating signal. Quadrature Phase carrier signal, P1Q(t), is pulsewidth modulated by a Quadrature Phase modulating signal and Quadrature Phase carrier signal, P1Q(t)\, is pulsewidth modulated by an inverting Quadrature Phase modulating signal. Signal P1I(t) is coupled to a first input of a first amplifier (e.g., coupled to a gate of Q1 amplifying device such as a field effect transistor). Signal P1Q(t)\ is coupled to a second input of the first amplifier (e.g., coupled to a gate of Q2 amplifying device such as a field effect transistor). Signal P1Q(t) is coupled to a third input of an amplifier (e.g., coupled to a gate of Q3 amplifying device such as a field effect transistor). Signal P1Q(t)\ is coupled to a fourth input of the first amplifier (e.g., coupled to a gate of Q4 amplifying device such as a field effect transistor). With equations related to the input signals, k₁×(P1I(t)−P1I(t)\) and k₂×(P1Q(t)-P1Q(t)\), an equivalent relationship or equation can be provided as: [(k₁×P1I(t)+k₂×P1Q(t)]−[(k₁×P1I(t)\+k₂×P1Q(t)\], which can be implemented by summing/coupling/combining output signal from Q1 (e.g., drain terminal of Q1) with output signal of Q3 (e.g., drain terminal of Q3), and/or summing/coupling/combining output signal from Q2 (e.g., drain terminal of Q2) with output signal of Q4 (e.g., drain terminal of Q4) as shown in FIG. 7. The output signals from Q1 and Q3 are coupled to a first terminal of a transformer and/or the output signals from Q2 and Q4 are coupled to a second terminal of the transformer (e.g., as shown in FIG. 7). The first terminal and the second terminal of the transformer provide a subtractive or combining function/method. An output of the transformer (e.g., Vrf1′) provides a pulsewidth modulated signal including one or more single sideband signals. Block 83 in FIG. 7 may provide filtering of output signal from the transformer and provide one or more amplitude modulated single sideband signals.

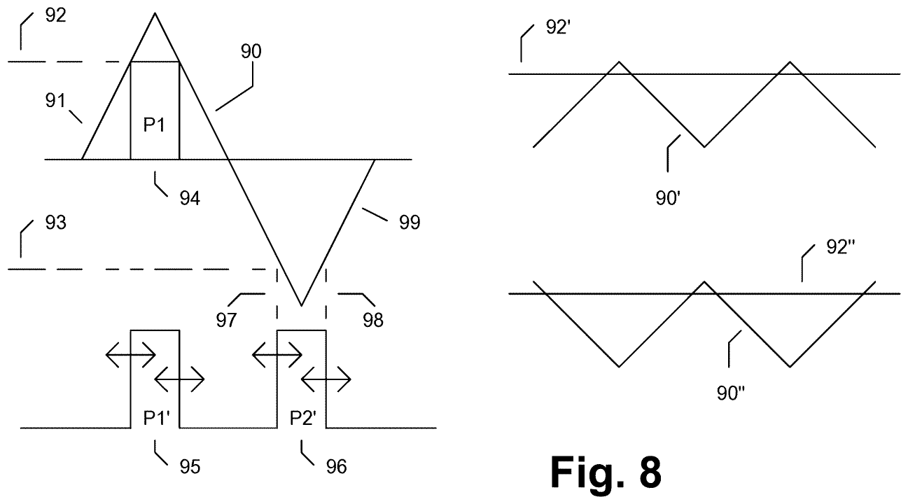

FIG. 8 illustrates generating or providing pulsewidth modulation. For example, a carrier frequency triangle (or sawtooth) waveform, 90, is coupled to a first input of a comparator while a second input of the comparator is coupled to a modulating signal whose amplitude level is denoted by 92. The level of 92 may fluctuate up and down to provide a pulsewidth modulated signal, P1′; for example, level of 92 downward provides a widened pulse P1′. For a constant level for modulating signal 92, a constant pulsewidth signal P1 or 94 is provided. A second modulating signal whose level is denoted by modulating signal 93 may be included to provide a pulsewidth modulated signal P2′ (or 96) delayed or phase shifted from P1, 94 or from P1′, 95. The level of 93 may fluctuate up and down to provide a pulsewidth modulated signal, P2′; for example the of 93 upward provides a widened pulse P2′. For example, P2′ is delayed by half a cycle (e.g., phased shifted 180 degrees, or phase shifted to an arbitrary phase angle) from P1′. In one implementation including modulation signals 92 and 93, the modulating signal 93 may be 180 out of phase from modulating signal 92 to provide the two pulsewidth modulated signals 96 (e.g., P2′) and 95 (e.g., P1′) for example respectively.

FIG. 8 illustrates an example method/apparatus for utilizing a common modulation signal (or same phase modulation signals, e.g., no inversion of one signal compared to the other) to provide at least 2 pulse width modulated signals such as P1′ and P2′. With a carrier frequency waveform 90′ and a carrier frequency inverted waveform 90″, a modulating signal 92′ and modulating signal 92″ may be included to provide pulsewidth modulated signals (e.g., such as 95 and 96). Modulating signals 92′ and 92″ may have the same phase in a manner where 92′ and 92″ track in the same direction of increasing or decreasing in level. Alternatively, modulation signal 92″ may equal 92′, or signal 92″ may be replaced with 92′ to provide two pulsewidth modulated signals (e.g. two pulsewidth modulated signal of different timing or delay, or two pulsewidth modulated signals such as P1′ and P2″).

In FIG. 8 an example embodiment may include one or more carrier signals (e.g., 90, 90′ and/or 90″) coupled to one or more comparator circuits (e.g., a first input of a comparator) and one or more modulating signals (e.g., 92, 93, 92′, and/or 92″) coupled to the one or more comparator circuits (e.g., a second input of a comparator) where one or more output(s) of the one or more comparators provides one or more pulsewidth modulated signals (e.g., 95 and/or 96, or Pl for a fixed duration pulsewidth (e.g., zero modulation)).

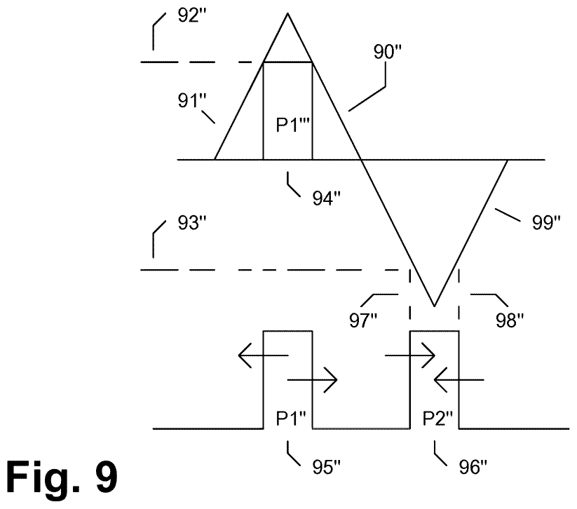

FIG. 9 shows an example of including a first modulating signal 92″ and a second modulating signal 93″, which is a level shifted version of 92″ or a signal with the same phase (e.g., not inverted) of 92″, wherein 93″ includes a (e.g., DC) offset voltage. For example, modulating signal 92″ shifts down in level to increase pulsewidth of pulse 95″; or modulating signal 93″ shifts down in level to decrease pulsewidth of pulse 96″. With a first modulating waveform 92″ and carrier waveform 90″ coupled to input terminals of a first comparator, an output of the first comparator provides a pulse modulated signal such as shown in 95″ or P1″. With a second modulating waveform 93″ and carrier waveform 90″ coupled to input terminals of a second comparator, an output of the second comparator provides a pulse modulated signal such as shown in 96″ or P2″, where the second comparator is operating with a delayed (e.g., 180 degrees) portion of 90″. In this example, a first output pulse modulated signal 95″ shows a widening of the pulse (e.g., P1″), whereas a second output pulse modulated signal 96″ shows a narrowing of the pulse (e.g., P2″). For example the pulse modulated signals P1″ and P2″ are providing signals in a push-pull manner or differential output manner (e.g., manner in terms of pulse width).

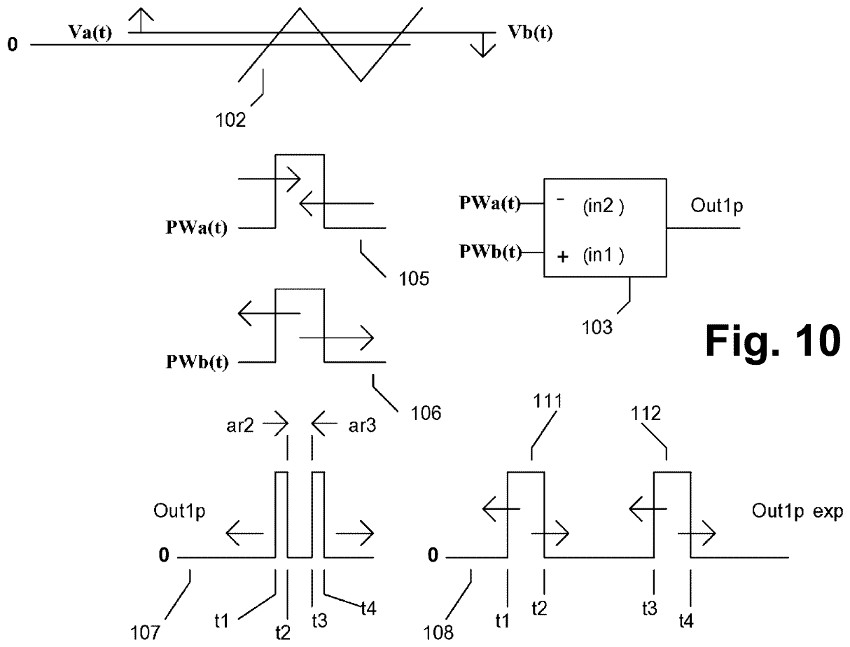

FIG. 10 shows another example embodiment including a double (e.g., pulsewidth) modulated pulse (e.g., 107 and/or 108) which is provided by processing two pulsewidth modulated pulses (e.g., 105 and/or 106) via combination logic or via a processing function/circuit such as block 103. For example, a carrier signal, 102, is coupled to a first input of a first comparator wherein a second input of the first comparator is coupled with a first modulating signal Va(t) (e.g., where Va(t) comprises a signal (k+m(t)), where k is a constant or DC voltage, and m(t) includes an AC modulating signal). An output of the first comparator provides a pulsewidth modulated signal PWa(t), 105; for example PWa(t) narrows as Va(t) includes increasing in amplitude or in level. Pertaining to a second modulating Vb(t) (e.g., and carrier signal 102), carrier signal, 102, is coupled to a first input of a second comparator wherein a second input of the second comparator is coupled with a second modulating signal Vb(t) (e.g., where Vb (t) comprises a signal (k−m(t)), where k is a constant or DC voltage, and wherein −m(t) includes/represents an AC modulating signal that is inverted or 180 degrees out of phase of m(t)). An output of the second comparator provides a pulsewidth modulated signal PWb(t), 106; for example PWb(t) widens as Vb(t) includes decreasing in amplitude or in level. By processing PWa(t) and PWb(t), a double pulse comprising a first pulse of the double pulse (e.g., 107 and/or 108) whose timing is described as t1 and t2, and a second pulse of the double pulse whose timing is described as t3 and t4. As illustrated for an example embodiment, schematically, the pulse edges related t1 and t4 expand (e.g., widen), whereas the pulse edges related to t2 and t3 contracts (e.g., narrows as shown with inward arrows denoted by ar2 and ar3). Waveform or pulse 108 shows an expanded or time magnified presentation of 107. For example, the first pulse of the double pulse is denoted as pulse 111, which includes pulsewidth modulation (e.g., double edge pulsewidth modulation), and the second pulse is denoted as pulse 112, which includes pulsewidth modulation (e.g., double edge pulsewidth modulation). In one example, pulses 111 and 112 pulsewidth modulate in phase (e.g., for an increasing pulsewidth with 111, pulse 112 also has an increasing pulsewidth; or for a decreasing pulsewidth with 111, pulse 112 also has an decreasing pulsewidth).

A subtractive process/circuit/function (e.g., in general) may be implemented (or may be comprised) by a transformer, differential amplifier, balun, and/or a logic circuit/function.

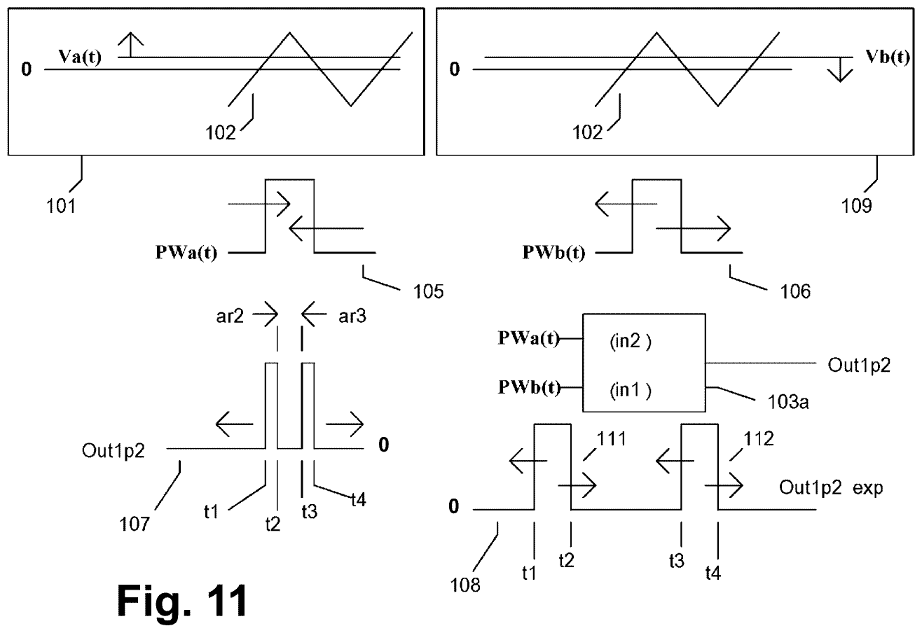

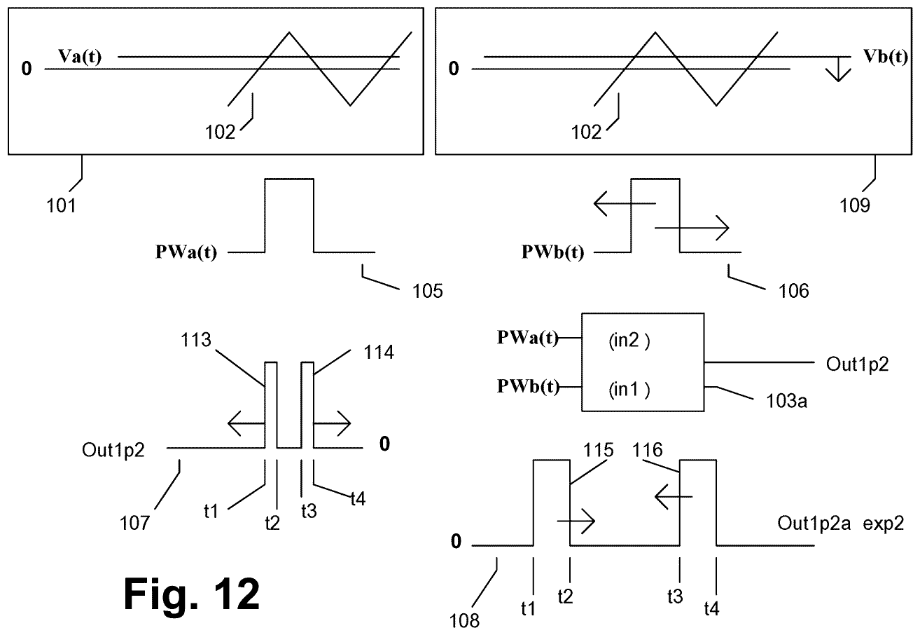

For example in FIG. 10, 11, and/or 12, a subtractive process/circuit/function (e.g., 103 in FIG. 10; 103a in FIG. 11; 103a in FIG. 12) may include/comprise a transformer, differential amplifier, balun, and/or a logic circuit/function

In an example in FIG. 10, 11, and/or 12, a subtractive process/circuit/function (e.g., 103 in FIG. 10; 103a in FIG. 11; 103a in FIG. 12) may be implemented by a logic function/circuit comprising with one or more logic gates such as a multiple input AND gate; wherein a first input of the AND gate is coupled to for example, waveform PWb(t), and a second input of the AND gate is coupled to waveform PWa(t) (e.g., PWa(t) is coupled to an input of a logic gate inverter and an output of the logic gate inverter is coupled the second input of the AND gate). In one example, an output of an AND gate provides a double (e.g., pulse) pulsewidth modulated signal. For example, in FIG. 10 with PWa(t) and PWb(t) coupled to block 103, an output signal Out1P from an AND gate (or from an output of a subtractor) provides two pulsewidth modulated signals such as 111 and 112 in FIG. 10 and/or FIG. 11, or alternatively illustrated in FIG. 12 two pulsewidth modulated signals shown as 115 and 116 or shown as 113 and 114 (e.g., via block 103a and Out1p2 for pulsewidth modulated signals 113 and 114 or for pulsewidth modulated signals 115 and 116 in FIG. 12).

In FIG. 10, FIG. 11, and/or FIG. 12, a method of using push pull (or balanced or differential) modulating signals such as Va(t) and Vb(t) to provide push pull (or balanced or differential) pulsewidth modulated signal PWa(t) and PWb(t). An unexpected distortion reduction result is provided via a subtractive process/circuit/function of PWa(t) and PWb(t), whereby a double pulsewidth modulated signal such as 107 and/or 108 (e.g., including 111 and 112) provides lower sideband distortion when compared to the sideband distortion from PWa(t) and/or PWb(t). Sideband distortion may include a signal including a frequency that is a multiple of |f_{c}−f_{mod}| such as n×|f_{c}−f_{mod}|, where n is an integer and n≥2 or n≤−2, and where f_{c}=frequency of a carrier signal and f_{mod}=frequency of a modulating signal (e.g., a sine wave modulating signal). Alternatively, when a single sideband signal is demodulated, which ideally provides a demodulated signal of frequency f_{mod}, a sideband distortion will provide a demodulated distortion signal whose frequency is a multiple of f_{mod}. For example, the double pulsewidth modulated signals such as 107 and/or 108 provides for a single sideband signal when demodulated by a single sideband signal detector/demodulation to provide less distortion than when compared to demodulating the single pulsewidth modulated signals such as PWa(t) or PWb(t).

In FIG. 10 it should be noted that when there is no modulation (e.g., m(t)→0 and/or −m(t)→0), the pulsewidth of PWa(t) and PWb(t) are equal, which provide a zero pulsewidth for waveforms 107, 108, 111, and/or 112. This no modulation condition provides a suppressed carrier amplitude or zero carrier amplitude.

FIG. 11 shows another example of generating, synthesizing, and/or providing a double pulse-pulsewidth modulated signals such as depicted in 107 and/or 108. Block 101 shows a first modulating signal Va(t) and a carrier signal 102. Block 109 shows a second modulating signal Vb(t) and the carrier signal 102. In one example a first processor may be included to process Va(t) and waveform 102 to provide waveform 105, PWa(t), and/or a second processor may be included to process Vb(t) and waveform 102 to provide waveform 106, PWb(t). The signals Va(t) and Vb(t) provide a push-pull signal (e.g., a differential signal); for example, Va(t) and Vb(t) may provide push pull or differential signals in terms of pulsewidth modulation. The waveforms PWa(t) and PWb(t) provide a set of push-pull pulsewidth modulated signals. A subtractor or logic circuit/function provides a double pulse pulsewidth modulated signal (e.g., 107 and/or 108), or a subtractor or logic circuit provides two pulsewidth modulated signals, 111 and 112. Another description of FIG. 11 may include an example embodiment including a double (e.g., pulsewidth) modulated pulse (e.g., 107 and/or 108) which is provided by processing two pulsewidth modulated pulses (e.g., 105 and/or 106) via combination logic or via a processing function/circuit such as block 103a. For example, a carrier signal, 102, is coupled to a first input of a first comparator wherein a second input of the first comparator is coupled with a first modulating signal Va(t) (e.g., where Va(t) comprises a signal (k+m(t)), where k is a constant or DC voltage, and m(t) includes an AC modulating signal). An output of the first comparator provides a pulsewidth modulated signal PWa(t), 105; for example PWa(t) narrows as Va(t) includes increasing in amplitude or in level. Pertaining to a second modulating Vb(t) (e.g., and carrier signal 102), carrier signal, 102, is coupled to a first input of a second comparator wherein a second input of the second comparator is coupled with a second modulating signal Vb(t) (e.g., where Vb(t) comprises a signal (k−m(t)), where k is a constant or DC voltage, and wherein −m(t) includes/represents an AC modulating signal that is inverted or 180 degrees out of phase of m(t)). An output of the second comparator provides a pulsewidth modulated signal PWb(t), 106; for example PWb(t) widens as Vb(t) includes decreasing in amplitude or in level. By processing PWa(t) and PWb(t), a double pulse comprising a first pulse of the double pulse (e.g., 107 and/or 108) whose timing is described as t1 and t2, and a second pulse of the double pulse whose timing is described as t3 and t4. As illustrated for an example embodiment, schematically, the pulse edges related t1 and t4 expand (e.g., widen), whereas the pulse edges related to t2 and t3 contracts (e.g., narrows as illustrated with inward arrows ar2 and ar3). Waveform or pulse 108 shows an expanded or time magnified presentation of 107. For example, the first pulse of the double pulse is denoted as pulse 111, which includes pulsewidth modulation (e.g., double edge pulsewidth modulation), and the second pulse is denoted as pulse 112, which includes pulsewidth modulation (e.g., double edge pulsewidth modulation). In one example, pulses 111 and 112 pulsewidth modulate in phase (e.g., for an increasing pulsewidth with 111, pulse 112 also has an increasing pulsewidth; or for a decreasing pulsewidth with 111, pulse 112 also has an decreasing pulsewidth). A subtractor or logic circuit/function may comprise a subtractive process/circuit/function (e.g., in general) may be implemented (or may be comprised) by a transformer, differential amplifier, balun, and/or a logic circuit/function.

In FIG. 11 it should be noted that when there is no modulation (e.g., m(t)→0 and/or −m(t)→0), the pulsewidths of PWa(t) and PWb(t) are equal, which provide a zero pulsewidth for waveforms 107, 108, 111, and/or 112. This no modulation condition provides a suppressed carrier amplitude or zero carrier amplitude.

Another embodiment is shown in FIG. 12, where block 101 shows for illustrative purposes that with Va(t)=a constant voltage with carrier signal 102, coupling a constant voltage, Va(t) to a first input of a first comparator, and coupling waveform 102 to a second input of the first comparator, provides a constant pulsewidth pulse shown in PWa(t), waveform 105. In block 109 of FIG. 12, a dynamic modulating signal, Vb(t) is coupled to a first input of a second comparator, and carrier waveform 102 is coupled to a second input of the second comparator. An output of the second comparator provides a pulsewidth modulated signal 106. Waveforms 105 and 106 are coupled to a subtractive process/circuit/function to provide a double pulse pulsewidth modulated signal where in each of the double pulses (e.g., 115 and/or 116 in waveform 108), only one (e.g., single) edge is modulated in position or modulated as a function of time. For example, pulses 113, 114, 115, and/or 116 in FIG. 12 are distinguished from pulses 111 and 112 (e.g., as shown in FIG. 10 and/or FIG. 11) in that pulses 111 and 112 have double edge modulation whereas FIG. 12 pulses 113, 114, 115 and/or 116 have single edge modulation. In FIG. 12, one example of single edge modulation of each pulse 113 and 114 in waveform 107, wherein the (e.g., outer) edges of pulses 113 and or 114 move out or expands. In an example shown in FIG. 12, another example of single edge modulation of each pulse 115 and 116 in waveform 108, wherein the (e.g., inner) edges of pulses 115 and or 116 move in or contract. FIG. 12 shows example of providing a double pulse pulsewidth modulated signal, wherein when a modulation signal→0 or when Va(t)=a constant=Vb(t), the output signals 107 and 108 will have no carrier signal (e.g., pulsewidth of pulses113, 114, 115, and/or 116→0). Note that constant pulsewidth signal PWa(t) may be generated or synthesized without a comparator, waveform 102, and/or Va(t).

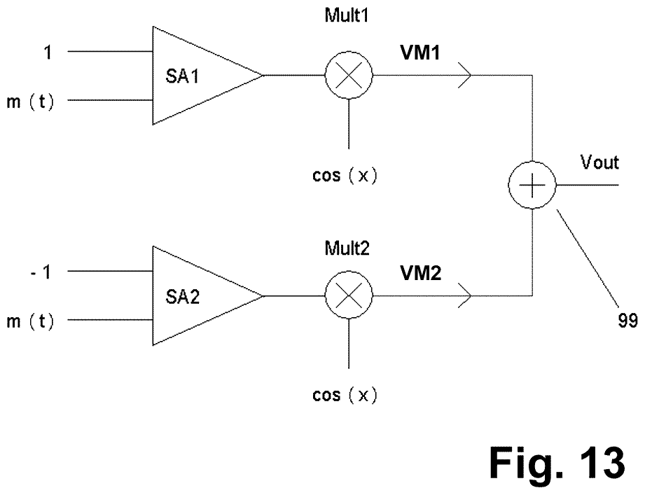

FIG. 13 shows an example of characterizing a pulsewidth modulated signal via a first pulsewidth modulator to provide a first amplitude modulated signal, Am₁(t), where for example, (1+m(t)) cos(ωt)=Am₁(t)=VM1 with cos(x)=cos(ωt) and/or wherein a second pulsewidth modulator provide a second amplitude modulated signal (1−m(t))(−1) cos(ωt)=Am2(t), which equivalently is (m(t)−1) cos(ωt)=Am2(t)=VM2 for example by combining Am₁(t) and Am₂(t)=VM1+VM2, such as summing and/or scaling to provide: [(VM1+VM2)/2]=[(Am(t)+Am2(t))/2]=m(t) cos(ωt), or alternatively to provide from the two pulsewidth modulators an output signal such as: [Am₁(t)+Am₂(t)]=2m(t)=(VM1+VM2)=Vout.

For example, FIG. 13 shows a first summing function/circuit, SA1, which combines a DC offset voltage or constant such as 1 with a first modulating signal m(t) to provide (1+m(t)) which coupled to a first input multiplier or mixer Mult1; and where a second input of Mult1 is coupled a first carrier signal cos(ωt), wherein FIG. 13, cos(x)=cos(ωt); Mult1 provides an output signal, (1+m(t)) cos(ωt)=Am₁(t)=VM1. A second summing function/circuit, SA2, which combines a (e.g., negative) DC offset voltage or constant such as −1 with the first modulating signal m(t) provides (−1+m(t))=(m(t)−1) which is coupled to a first input to a second multiplier or mixer, Mult2; a second input of Mult2 is to the first carrier signal cos(ωt). Mult2 provides an output signal, VM2=(m(t)−1) cos(ωt)=Am2(t). An adder 99 combines an output signal from Mult1 and an output signal from Mult2, wherein an output signal from adder 99 provides 2 m(t) cos(ωt)=Am₁(t)+Am₂(t)=(VM1+VM2)=Vout.

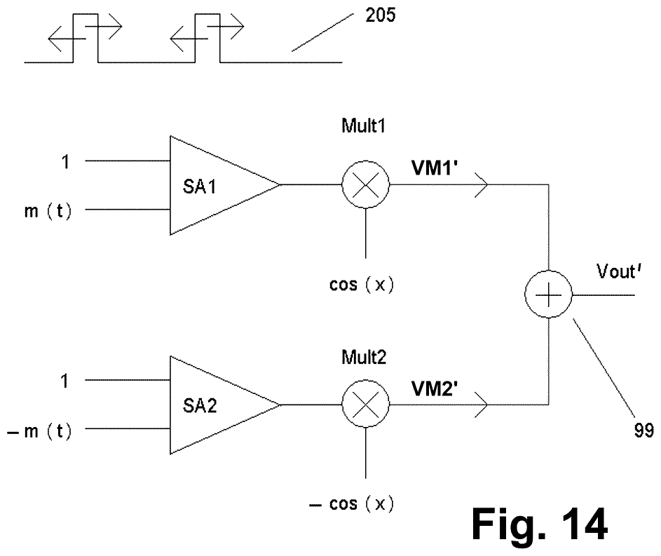

In FIG. 14 an alternative embodiment may include the second summing function/circuit, SA2, which combines a DC offset voltage or constant such as 1 with an inverted first modulating signal, −m(t), which provides (1−m(t)) that is coupled to a first input to a second multiplier or mixer, Mult2; a second input of Mult2 is to an inverted first carrier signal [−cos(ωt)], with cos(x)=cos(ωt) and −cos(x)=−cos(ωt). An output signal from Mult2 provides VM2′=(1−m(t)) (−cos(ωt))=Am₂(t). Also note that a first summing function/circuit, SA1, which combines a DC offset voltage or constant such as 1 with a first modulating signal m(t) to provide (1+m(t)) which coupled to a first input multiplier or mixer Mult1; and where a second input of Mult1 is coupled a first carrier signal cos (ωt), and wherein Mult1 provides an output signal, VM1′=(1+m(t)) cos(ωt)=Am₁(t). An adder 99 combines an output signal from Mult1 and an output signal from Mult2, wherein an output signal from adder 99 provides Vout′=2m(t) cos(ωt)=Am₁(t)+Am₂(t)=(VM1′+VM2′).

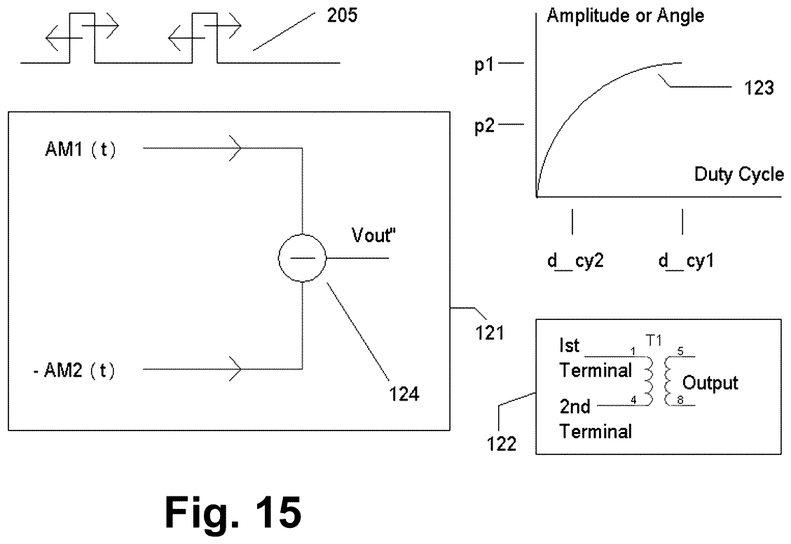

In FIG. 14 (or FIG. 15) waveform 205, a pulsewidth modulated signal, may be characterized in terms of a fundamental frequency carrier signal which is amplitude modulated as [K+m(t)] cos(ωt), where ω=2πf and f=a fundamental carrier frequency, or an arbitrary frequency; and/or where K is a constant.

FIG. 15 shows an example transfer function, 123, of width of a pulse and its associated output in carrier level. Curve or math function 123 shows that there is a nonlinear relationship in carrier signal output versus duty cycle of the pulse (e.g., pulsewidth modulation). For example, this nonlinear relationship of carrier signal output versus a linear duty cycle increase or decrease provides extra sideband distortion products (e.g., when a pulsewidth modulated signal provides an amplitude modulated signal with a carrier, upper sideband, and/or lower sideband). An example transfer function 123 may be described (or included) as: y=sin(x)=carrier output amplitude, where “x” is related to duty cycle or pulsewidth. For example, given x=a duty cycle, d_cy2, an output amplitude of carrier signal is p2, and given x=a duty cycle, d_cy1, an output amplitude of carrier signal is p1; and given the transfer function curve, 123, the carrier signal amplitude is not proportional, but nonlinear, which shows increasing pulsewidth provides a leveling off of carrier signal amplitude output.

FIG. 15 shows providing multiplication of two signals via a subtractive (e.g., via 124) method/apparatus of two signals Am1(t) and −Am2(t) by providing an equivalence to 2 m(t) cos(ωt)=Am1(t)+Am2(t) being equal to Am1(t)−[−Am2(t)]=2m(t) cos(ωt). Vout″=Am1(t)−[−Am2(t)]=2 m(t) cos(ωt). In an alternative embodiment, taking the difference between two signals (e.g., Am1(t)−[−Am2(t)]) may be implemented via a differential device such as a balun, a transformer, a differential amplifier, and/or a difference function. Block 121 shows an example of using a subtractor to provide a multiplication of two signals such as m(t) and cos(ωt). Block 121 shows an example including a subtractive function 124 to provide Am1(t)−[−Am2(t)], wherein Am1(t) is coupled to a first input of subtractive function 124 and −Am2(t) is coupled to a second input of subtractive function 124; one or more output terminals subtractive function 124 provides an output signal indicative of a multiplication of m(t) and cos(ωt) via input signals Am1(t) and −Am2(t). Block 122 shows an example including a transformer to provide a subtractive function wherein Am1(t) is coupled to a first input terminal of a transformer and Am2(t) is coupled to a second input terminal of a transformer; one or more output terminals of the transformer provides an output signal indicative of a multiplication of m(t) and cos(ωt) provided by input signals Am1(t) and Am2(t).

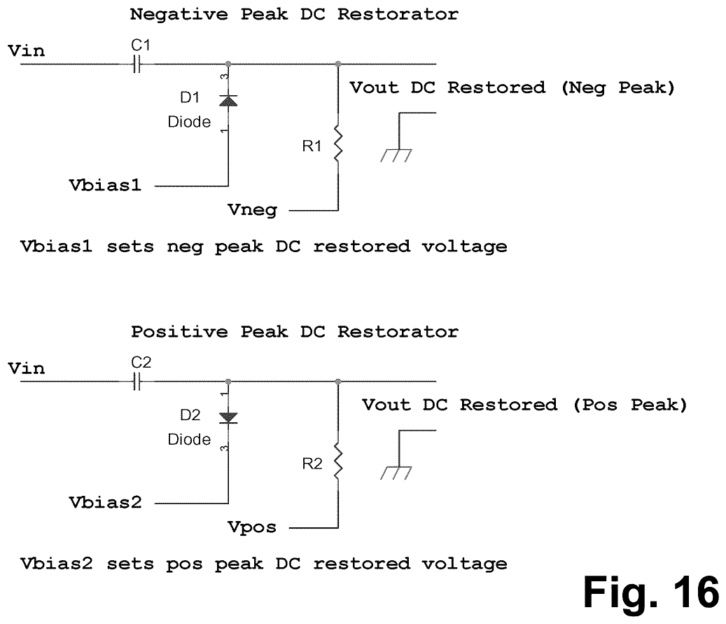

FIG. 16 shows one or more examples of processing a signal to provide a DC restored signal. For example, an input signal Vin is coupled to a first terminal of capacitor C1 wherein a second terminal of capacitor C1 is coupled to a first terminal of resistor R1 and to a cathode terminal of diode D1. The diode D1 anode terminal is coupled to bias voltage Vbias1 and a second terminal of resistor R1 is coupled to voltage source Vneg. For example values, C1 may include a range of 0.1 uF to 10 uF, and for example C1→1 uF; R1 values may include a range of 10,000 ohms to 10 million ohms, and for example, R1→1,000,000 ohms (1 meg ohm or 1MΩ). Components C1, D1, and R1 form a circuit for negative (e.g. peak) DC restoration of input signal Vin, and Vout which is coupled to R1 and D1 (e.g., cathode of D1) provides a DC restored signal with the negative peaks of Vin being restored typically to an arbitrary voltage such as 0 volt or some other voltage value as set by Vbias1. For a circuit or apparatus providing DC restoration on positive peaks of an input signal such as Vin, Vin is coupled to a first terminal of capacitor C2 wherein a second terminal of capacitor C2 is coupled to a first terminal of resistor R2 and to an anode terminal of diode D2. The diode D2 cathode terminal is coupled to bias voltage Vbias2 and a second terminal of resistor R2 is coupled to voltage source Vpos. For example values, C2 may include a range of 0.1 uF to 10 uF, and for example C2→1 uF; R2 values may include a range of 10,000 ohms to 10 million ohms, and for example, R2→1,000,000 ohms (1 meg ohm or 1MΩ). Components C2, D2, and R2 form a circuit for negative (e.g. peak) DC restoration of input signal Vin, and Vout which is coupled to R2 and D2 (e.g., anode of D2) provides a DC restored signal with the positive peaks of Vin being restored typically to an arbitrary voltage such as 0 volt, 1 volt, 2 volts, or some other voltage value as set by Vbias2.

FIG. 16 shows DC restoration circuits/functions to clamp or restore one or more negative peaks of a modulating waveform to a constant voltage, or to clamp or restore one of more positive peaks of a modulating waveform to a constant voltage. One embodiment may include a DC restoration circuit (e.g., for providing a modulated signal with zero carrier when a modulating signals→0) comprising coupling an input signal to a first terminal of a capacitor, coupling a second terminal of the capacitor to a a first terminal of a diode, coupling a first voltage source to a second terminal of the diode, providing an output signal coupled to the first terminal of the diode, wherein the output signal provide a processed signal of the input signal, wherein the processed signal includes a DC restored signal of the input signal; the output terminal may include draining a current or supplying a current coupled to the first terminal of the diode; a first terminal of a resistor may coupled to the first terminal of the diode, wherein a second terminal of the resistor is coupled to a second voltage source; alternatively the resistor may be substituted with a current source circuit including a first terminal and a second terminal.

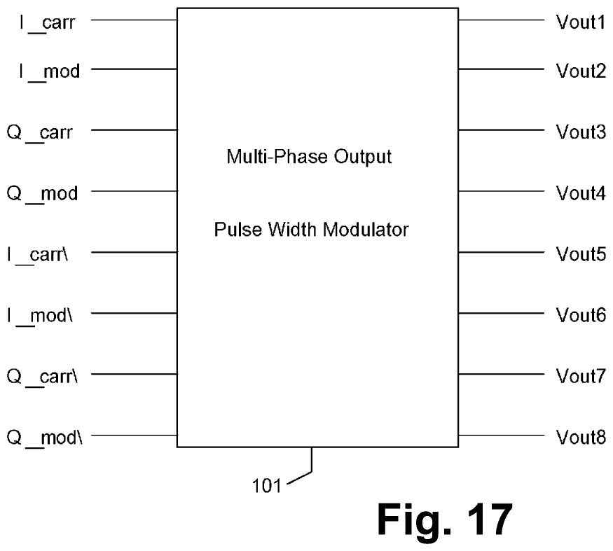

FIG. 17 shows an example embodiment including multiple phase signals (e.g., carrier signals with different phases including 0 degree, 90 degrees, 180 degrees, and/or 270 degrees; and/or modulating signals with with different phases including 0 degree, 90 degrees, 180 degrees, and/or 270 degrees; for example 0 degree represents an In-Phase signal, 90 degrees represent a Quadrature-Phase signal, 180 degrees represent an inverted In-Phase signal, and/or 270 degrees represent an inverted Quadrature-Phase signal). Block 101 shows an example processor 101, which processes (e.g., input) signals, I_carr, I_mod, Q_carr, Q_mod, I_carr\, I_mod\, Q_carr\, and/or Q_mod\; processor 101 provides output signals Vout1, Vout2, Vout3, Vout4, Vout5, Vout6, Vout7, and/or Vout8. I_carr represents an In-Phase carrier frequency signal, I_mod represents an In-Phase modulating signal, Q_carr represents a Quadrature-Phase carrier frequency signal, Q_mod represents a Quadrature-Phase modulating signal, I_carr\ represents an inverted In-Phase carrier frequency signal, I_mod\ represents an inverted In-Phase modulating signal, Q_carr\ represents an inverted Quadrature-Phase carrier frequency signal, and/or Q_mod\ represents an inverted Quadrature-Phase modulating signal. In one example each signal from Vout1, Vout2, Vout3, Vout4, Vout5, Vout6, Vout7, and/or Vout8 provides a (e.g., unique) pulsewidth modulated signal. A combination of Vout1, Vout2, Vout3, Vout4, Vout5, Vout6, Vout7, and/or Vout8 may provide at least one single sideband signal (e.g., a single sideband signal with a carrier signal, or a single sideband suppressed carrier signal).

In FIG. 17 it was found experimentally that one combination of adding, logically combining, and/or subtracting provided multiple (e.g., simultaneous) single sideband suppressed carrier signals of different frequencies wherein for example at a fundamental frequency carrier a sideband single sideband suppressed carrier signal was provided while at a harmonic frequency of the fundamental frequency, another single sideband suppressed carrier signal was provided but at the opposite sideband. For example, at the fundamental frequency carrier a lower sideband single sideband suppressed carrier signal was provided while at a harmonic frequency of the fundamental frequency, an upper sideband single sideband suppressed carrier signal was provided. Alternatively, another example may include at the fundamental frequency carrier an upper sideband single sideband suppressed carrier signal was provided while at a harmonic frequency of the fundamental frequency, a lower sideband single sideband suppressed carrier signal was provided.

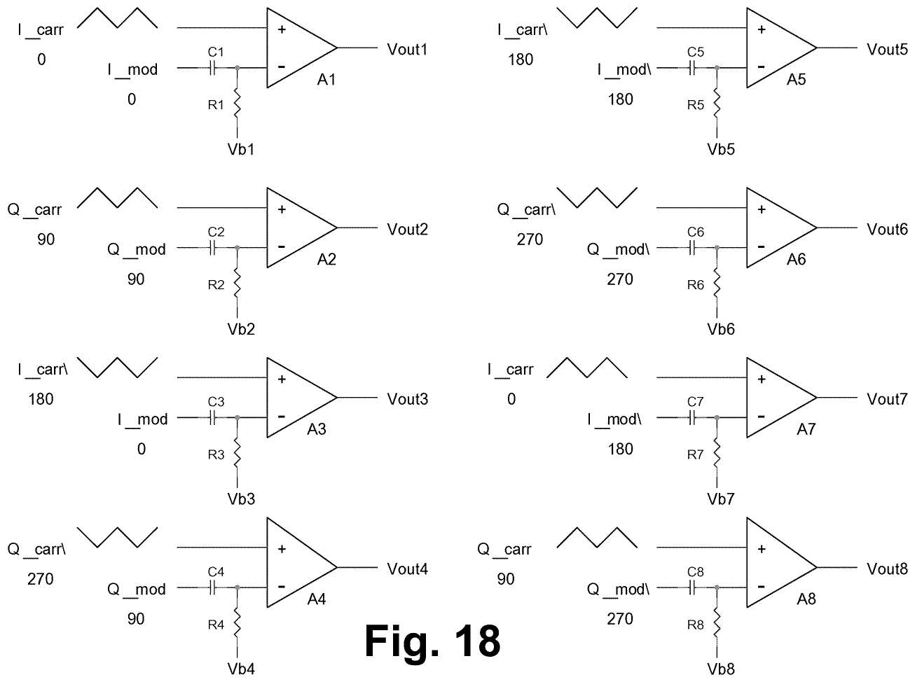

FIG. 18 shows an example of processing multiple pairs of signals (or multiple signals) of different phases to provide one or more pulsewidth modulated signals wherein one or more of the pulsewidth modulated signal may be converted (e.g., via filtering such as with a low pass filter, band pass filter, and/or high pass filter) to one or more single sideband signals, one or more amplitude modulated signals, one or more phase modulated signals, and/or one or more carrier suppressed signals. In one embodiment, each pulsewidth modulated signal (e.g., Vout1, Vout2, Vout3, Vout4, Vout5, Vout6, Vout7, and/or Vout8) provide independent or unique pulsewidth modulated signals (e.g., in phase of a carrier signal and/or phase of a modulating signal).

For example, FIG. 18 shows multiple pairs of signals, each pair a carrier signal of a set phase and a modulation signal of a set phase with each pair of signals coupled to a comparator to provide an output signal (e.g., pulse signal, pulsewidth modulated signal, and/or a unique or independent pulsewidth modulated signal). In one embodiment input signal I_carr (e.g., 0 degree or In-Phase carrier signal) is coupled to a first input terminal of comparator A1, and input signal I_mod (0 degree or In-Phase modulating/modulation signal) is coupled to a second input terminal of A1; for example, input signal I_mod is coupled to a first terminal of a capacitor C1, and a second terminal of capacitor C1 is coupled to the second terminal of comparator A1 wherein a first terminal of resistor R1 is coupled to the second input terminal of comparator A1 and a second terminal of resistor R1 is coupled to a voltage source, Vb1, wherein Vb1 is set to provide a slice level (e.g., at zero modulation) for comparator A1, which provides a set pulsewidth (e.g., at zero modulation) or a range of pulsewidths (e.g., when a modulating signal is non zero in amplitude). Output signal Vout1 from comparator A1 provides a pulsewidth modulated signal (e.g., a pulsewidth modulated signal which provides one or more amplitude modulated signals).

In FIG. 18, input signal Q_carr (e.g., 90 degree or Quadrature-Phase carrier signal) is coupled to a first input terminal of comparator A2, and input signal Q_mod (90 degree or Quadrature-Phase modulating/modulation signal) is coupled to a second input terminal of A2; for example, input signal Q_mod is coupled to a first terminal of a capacitor C2, and a second terminal of capacitor C2 is coupled to the second terminal of comparator A2 wherein a first terminal of resistor R2 is coupled to the second input terminal of comparator A2 and a second terminal of resistor R is coupled to a voltage source, Vb2, wherein Vb2 is set to provide a slice level (e.g., at zero modulation) for comparator A2, which provides a set pulsewidth (e.g., at zero modulation) or a range of pulsewidths (e.g., when a modulating signal is non zero in amplitude). Output signal Vout2 from comparator A2 provides a pulsewidth modulated signal (e.g., a pulsewidth modulated signal which provides one or more amplitude modulated signals).

In FIG. 18, input signal I_carr\ (e.g., 180 degree or inverted In-Phase carrier signal) is coupled to a first input terminal of comparator A3, and input signal I_mod (0 degree or In-Phase modulating/modulation signal) is coupled to a second input terminal of A3; for example, input signal I_mod is coupled to a first terminal of a capacitor C3, and a second terminal of capacitor C3 is coupled to the second terminal of comparator A3 wherein a first terminal of resistor R3 is coupled to the second input terminal of comparator A3 and a second terminal of resistor R3 is coupled to a voltage source, Vb3, wherein Vb3 is set to provide a slice level (e.g., at zero modulation) for comparator A3, which provides a set pulsewidth (e.g., at zero modulation) or a range of pulsewidths (e.g., when a modulating signal is non zero in amplitude). Output signal Vout3 from comparator A3 provides a pulsewidth modulated signal (e.g., a pulsewidth modulated signal which provides one or more amplitude modulated signals).

In FIG. 18 input signal Q_carr (e.g., 270 degree or inverted Quadrature-Phase carrier signal) is coupled to a first input terminal of comparator A4, and input signal Q_mod (90 degree or Quadrature-Phase modulating/modulation signal) is coupled to a second input terminal of A4; for example, input signal Q_mod is coupled to a first terminal of a capacitor C4, and a second terminal of capacitor C4 is coupled to the second terminal of comparator A4 wherein a first terminal of resistor R4 is coupled to the second input terminal of comparator A4 and a second terminal of resistor R4 is coupled to a voltage source, Vb4, wherein Vb4 is set to provide a slice level (e.g., at zero modulation) for comparator A4, which provides a set pulsewidth (e.g., at zero modulation) or a range of pulsewidths (e.g., when a modulating signal is non zero in amplitude). Output signal Vout4 from comparator A4 provides a pulsewidth modulated signal (e.g., a pulsewidth modulated signal which provides one or more amplitude modulated signals).

In FIG. 18 input signal I_carr\ (e.g., 180 degree or inverted In-Phase carrier signal) is coupled to a first input terminal of comparator A5, and input signal I_mod\ (180 degree or inverted In-Phase modulating/modulation signal) is coupled to a second input terminal of A5; for example, input signal I_mod\ is coupled to a first terminal of a capacitor C5, and a second terminal of capacitor C5 is coupled to the second terminal of comparator A5 wherein a first terminal of resistor R5 is coupled to the second input terminal of comparator A5 and a second terminal of resistor R5 is coupled to a voltage source, Vb5, wherein Vb5 is set to provide a slice level (e.g., at zero modulation) for comparator A5, which provides a set pulsewidth (e.g., at zero modulation) or a range of pulsewidths (e.g., when a modulating signal is non zero in amplitude). Output signal Vout5 from comparator A5 provides a pulsewidth modulated signal (e.g., a pulsewidth modulated signal which provides one or more amplitude modulated signals).

In FIG. 18 input signal Q_carr\ (e.g., 270 degree or inverted Quadrature-Phase carrier signal) is coupled to a first input terminal of comparator A6, and input signal Q_mod\ (270 degree or inverted Quadrature-Phase modulating/modulation signal) is coupled to a second input terminal of A6; for example, input signal Q_mod\ is coupled to a first terminal of a capacitor C6, and a second terminal of capacitor C6 is coupled to the second terminal of comparator A6 wherein a first terminal of resistor R6 is coupled to the second input terminal of comparator A6 and a second terminal of resistor R6 is coupled to a voltage source, Vb6, wherein Vb6 is set to provide a slice level (e.g., at zero modulation) for comparator A6, which provides a set pulsewidth (e.g., at zero modulation) or a range of pulsewidths (e.g., when a modulating signal is non zero in amplitude). Output signal Vout6 from comparator A6 provides a pulsewidth modulated signal (e.g., a pulsewidth modulated signal which provides one or more amplitude modulated signals).

In FIG. 18 input signal I_carr (e.g., 0 degree or In-Phase carrier signal) is coupled to a first input terminal of comparator A7, and input signal I_mod\ (180 degree or inverted In-Phase modulating/modulation signal) is coupled to a second input terminal of A7; for example, input signal I_mod\ is coupled to a first terminal of a capacitor C7, and a second terminal of capacitor C7 is coupled to the second terminal of comparator A7 wherein a first terminal of resistor R7 is coupled to the second input terminal of comparator A7 and a second terminal of resistor R7 is coupled to a voltage source, Vb7, wherein Vb7 is set to provide a slice level (e.g., at zero modulation) for comparator A7, which provides a set pulsewidth (e.g., at zero modulation) or a range of pulsewidths (e.g., when a modulating signal is non zero in amplitude). Output signal Vout7 from comparator A7 provides a pulsewidth modulated signal (e.g., a pulsewidth modulated signal which provides one or more amplitude modulated signals).

In FIG. 18 input signal Q_carr (e.g., 90 degree or Quadrature-Phase carrier signal) is coupled to a first input terminal of comparator A8, and input signal Q_mod\ (270 degree or inverted Quadrature-Phase modulating/modulation signal) is coupled to a second input terminal of A8; for example, input signal Q_mod\ is coupled to a first terminal of a capacitor C8, and a second terminal of capacitor C8 is coupled to the second terminal of comparator A8 wherein a first terminal of resistor R8 is coupled to the second input terminal of comparator A8 and a second terminal of resistor R8 is coupled to a voltage source, Vb8, wherein Vb8 is set to provide a slice level (e.g., at zero modulation) for comparator A8, which provides a set pulsewidth (e.g., at zero modulation) or a range of pulsewidths (e.g., when a modulating signal is non zero in amplitude). Output signal Vout8 from comparator A8 provides a pulsewidth modulated signal (e.g., a pulsewidth modulated signal which provides one or more amplitude modulated signals).

In FIG. 18 although Vb1 through Vb8 may be independently set voltages, Vb1 through Vb8 may (e.g., also) be set to a same voltage. One example embodiment includes Vb1=Vb2=Vb3=Vb4=Vb5=Vb6=Vb7=Vb8. Note that in FIG. 18 each signal is labeled with an example phase angle or phase shift below it such as “0” below the text of I_carr (e.g., for 0 degree), or with “90” below the text of Q_carr (e.g., for 90 degrees, or with “180” below the text of I_mod\, or with “270” below the text of Q_carr\ (e.g., for 270 degrees), and note that other phase angles or other phase shifts may be used.

In FIG. 18 a carrier signal may include a triangle waveform (e.g., to provide double edge pulsewidth modulation), a sawtooth waveform (e.g., to provide single edge pulsewidth modulation), a nonlinear waveform (e.g., rectified sine wave, parabolic waveform, an absolute value of a sinusoidal waveform, a saturating waveform, a compressed wavefrom, or variable slope waveform) to lower sideband distortion (or to linearize amplitude modulation), and/or an arbitrary/other waveform.

In one or any embodiment (e.g., in reference to any drawings or figures), a carrier frequency waveform including a pre-distorted triangle waveform to reduce amplitude of a sideband distortion signal such as reducing sideband harmonic distortion. For example when an input terminal of a comparator is coupled to a pre-distorted triangle waveform wherein an output of the comparator provides a pulsewidth modulated signal that includes at least one sideband signal; for example a pre-distorted triangle waveform may include a parabolic waveform, a parabolic waveform portion forming a curved “V” shape wherein the curved “V” shape portion is coupled to an input to a comparator and wherein a modulation signal is coupled to another input of the comparator, whereby the modulation signal levels are compared in the “V” shape portion to provide a pulsewidth modulated which includes a reduced amplitude sideband distortion signal. In another example, a pre-distorted waveform (e.g., a parabolic carrier frequency waveform) may be utilized to linearize or to increase linearity of a pulsewidth modulator in terms of providing an amplitude modulated signal such as an amplitude modulated single sideband signal (e.g., single sideband signal with suppressed carrier signal or single sideband signal with carrier signal).

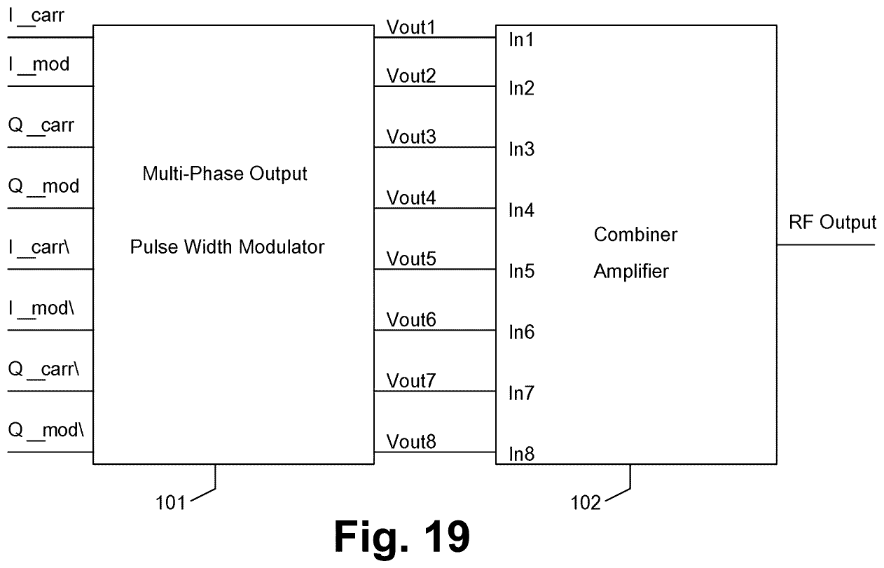

FIG. 19 shows an example embodiment where a multiple phase out pulsewidth modulator system/apparatus/method, block 101, receives multiple input signals including one or more of: I_carr (e.g., an In-Phase carrier signal), I_mod (e.g., an In-Phase modulating signal), Q_carr (e.g., a Quadrature-Phase carrier signal), Q_mod (e.g., a Quadrature-Phase modulating signal), I_carr\ (e.g., an inverted or 180 degrees In-Phase carrier signal), I_mod\ (e.g., an inverted to 180 degrees In-Phase modulating signal), Q_carr\ (e.g., an inverted or 270 degrees Quadrature-Phase carrier signal), and/or Q_mod\ (e.g., an inverted or 270 degrees Quadrature-Phase modulating signal). Block 101 provides one or more output signals Vout1, Vout2, Vout3, Vout4, Vout5, Vout6, Vout7, and/Vout8. The one or more output signals Vout1, Vout2, Vout3, Vout4, Vout5, Vout6, Vout7, and/or Vout8 provide one or more pulsewidth modulated to block 102, which may include a combiner and/or amplifier. An output of block 102 provides an RF signal, which may include one or more of the following: one or more amplitude modulated signals, one or more single sideband signals, one or more modulated signals with one or more suppressed carrier signals, one or more modulated signals with one or more suppressed carrier signals, two or more amplitude modulated signals with different carrier frequencies, two or more single sideband signals with different frequencies, one or more modulated signals with two or more suppressed carrier signals wherein the suppressed carrier signals include different frequencies, and/or two or more modulated signals with one or more suppressed carrier signals wherein the suppressed carrier signals include different frequencies. In one embodiment, to synthesize a single sideband suppressed carrier signal, block 102 may receive four to eight signals from 101 such as any 4 to 8 of signals Vout1, Vout2, Vout3, Vout4, Vout5, Vout6, Vout7, and/or Vout8. An example modulated signal may include a single sideband signal and/or a single sideband suppressed carrier signal.

In one embodiment a single carrier frequency with one or more phases is utilized or included in block 101, which then provide signals (e.g., Vout1, Vout2, Vout3, Vout4, Vout5, Vout6, Vout7, and/Vout8) of a single carrier frequency with multiple phases to combiner/amplifier 102. Combiner and/or amplifier 102 may provide multiple pulsewidth modulated signals (e.g., of the one carrier frequency and/or of multiple phases), which provide two or more modulated signals with one or more suppressed carrier signals wherein the suppressed carrier signals include different frequencies (e.g., from a single fundamental carrier frequency such as a frequency of an unmodulated pulsewidth modulated signal, or [1/(period of the pulses)]=carrier frequency).

A modulated signal may include a single sideband signal, an amplitude modulated signal, an amplitude modulated suppressed carrier signal, double sideband suppressed carrier signal, and/or a single sideband suppressed carrier signal.

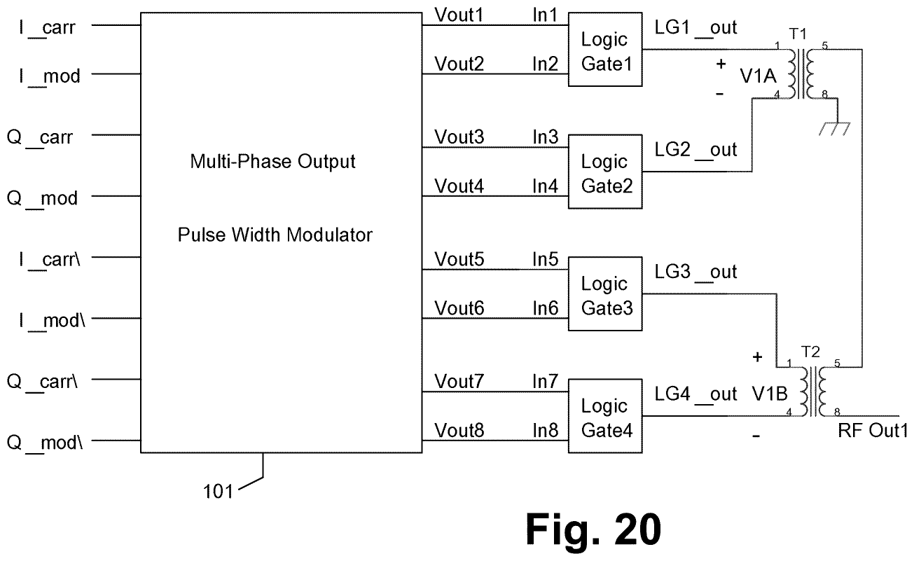

FIG. 20 shows an example embodiment including a multiple phase output pulsewidth modulator 101, provides multiple pulsewidth modulated signals of a single carrier frequency with one or more phases. Block 101 is coupled to input signals: I_carr (e.g., an In-Phase carrier signal), I_mod (e.g., an In-Phase modulating signal), Q_carr (e.g., a Quadrature-Phase carrier signal), Q_mod (e.g., a Quadrature-Phase modulating signal), I_carr\ (e.g., an inverted or 180 degrees In-Phase carrier signal), I_mod\ (e.g., an inverted or 180 degrees In-Phase modulating signal), Q_carr\ (e.g., an inverted or 270 degrees Quadrature-Phase carrier signal), and/or Q_mod\ (e.g., an inverted or 270 degrees Quadrature-Phase modulating signal). In FIG. 20 output signals from block 101 are coupled for example to logic gates (e.g., combination of one or more logic gates, including one or more OR gate, NOR gate, inverter gate, NAND gate, and/or AND gate). Mult-Phase Output Pulse Width Modulator 101 (e.g., Mult-Phase may include a meaning of multiple phases or multi-phase) provides a set of signals, which when combined via logic gates, summers, subtractors, and/or arithmetic operators, one or more suppressed carrier signals is provided (e.g., via signals LG1_out, LG2_out, LG3_out, and/or LG4_out coupled to T1, and/or T2). A suppressed carrier signal may include a single sideband (or double sideband) suppressed carrier signal. In FIG. 20, Vout1 is coupled to input In1 of Logic Gate1, Vout2 is coupled to input In2 of Logic Gate1, Vout3 is coupled to input In3 of Logic Gate2, Vout4 is coupled to input In4 of Logic Gate2, Vout5 is coupled to input In5 of Logic Gate3, Vout6 is coupled to input In6 of Logic Gate3, Vout7 is coupled to input In7 of Logic Gate4, and/or Vout8 is coupled to input In8 of Logic Gate4. Output signal LG1_out from Logic Gate1 (e.g., an OR gate or other logic gate) is coupled to a first terminal of transformer T1 (e.g., first terminal of a primary winding of T1), output signal LG2_out from Logic Gate2 (e.g., an OR gate or other logic gate) is coupled to a second terminal of transformer T1 (e.g., second terminal of a primary winding of T1), output signal LG3_out from Logic Gate3 (e.g., an OR gate or other logic gate) is coupled to a first terminal of transformer T2 (e.g., first terminal of a primary winding of T2), and/or output signal LG4_out from Logic Gate4 (e.g., an OR gate or other logic gate) is coupled to a second terminal of transformer T2 (e.g., second terminal of a primary winding of T2). Secondary windings of T1 and T2 are coupled (e.g., in series) to subtract or to suppress a carrier signal when there is no modulation (e.g., when I_mod, Imod\, Q_mod, and/or Q_mod\=0 or zero amplitude; or when I_mod, Imod\, Q_mod, and/or Q_mod\≠0, a non zero amplitude modulation signal condition). As an example shown in FIG. 20 the secondary windings of T1 and T2 are configured/coupled/connected in such a manner as to at least partially cancel a carrier signal while passing through at least one sideband signal to provide output signal RF Out1. Signal RF Out1 may be coupled to an input of a filter (e.g., a filter including any combination of band pass, low pass, and/or high pass), wherein an output the filter provides a modulated signal such as a single sideband signal, single sideband suppressed carrier signal, double sideband signal, and/or double sideband suppressed carrier signal. Signal RF Out1 may include multiple modulated signals of different frequencies including multiple single sideband signals of different sidebands at different frequencies (e.g., a first single sideband signal including a lower sideband at a first carrier frequency, a second single sideband signal including an upper sideband at a second carrier frequency or vice versa in terms of lower and/or upper sideband). An example with non zero values of I_mod, Imod\, Q_mod, and/or Q_mod\, which provides a (e.g., non-zero) modulation signal, RF Out1 provides a modulated signal including at least one single sideband suppressed carrier signal.

For an example in FIG. 20, carrier signals are present in both primary (e.g, and/or both secondary windings) of T1 and T2 and secondary windings of T1 and T2 are coupled in series such that carrier signals are canceled (e.g., subtracted or added out of phase), which provides for a single sideband suppressed carrier signal is provided an output signal, RF Out1.

In FIG. 20, one example includes: LG1_out a logically combination of Vout1 and Vout2 (e.g., Vout1 OR Vout2) wherein signals Vout1 and Vout2 may be included/referenced from FIG. 18; LG2_out a logically combination of Vout3 and Vout4 (e.g., Vout3 OR Vout4) wherein signals Vout3 and Vout4 may be included/referenced from FIG. 18; LG3_out a logically combination of Vout5 and Vout6 (e.g., Vout5 OR Vout6) wherein signals Vout5 and Vout6 may be included/referenced from FIG. 18; LG4_out a logically combination of Vout7 and Vout8 (e.g., Vout7 OR Vout8) wherein signals Vout7 and Vout8 may be included/referenced from FIG. 18. Signals LG1_out and LG2_out are subtracted via primary winding terminals of T1 and/or signals LG3_out and LG4_out are subtracted via primary winding terminals of T2. Secondary winding signals from T1 and T2 are combined in a manner to attenuate or cancel a carrier signal while providing a single sideband suppressed carrier signal at RF Out1. In another example the act or implementation of subtracting a carrier signal from the combination of pulsewidth modulated signals LG1_out, LG2_out, LG3_out, and/or LG4_out reduces sideband distortion or reduces sideband distortion sufficiently (e.g., to avoid implementing pre-distortion of one or modulating signals to reduce sideband distortion and/or to avoid implementing providing a modified carrier frequency waveform such as a parabolic carrier frequency waveform to reduce sideband distortion). Measured sideband distortion from each of the single pulsewidth modulated signals from Vout1, Vout2, Vout3, Vout4, Vout5, Vout6, Vout7, and/or Vout8 (e.g., from FIG. 18, 19, 20, and/or other figures) is higher than when a combination two or more signal from Vout1, Vout2, Vout3, Vout4, Vout5, Vout6, Vout7, and/or Vout8 are combined (e.g., logically combined) and/or subtracted. For example measured sideband distortion from just one of the signals Vout1, Vout2, Vout3, Vout4, Vout5, Vout6, Vout7, or Vout8 is higher than the sideband distortion at RF Out1 in FIG. 20. In another example adding, combining, and/or subtracting two or more signals from Vout1, Vout2, Vout3, Vout4, Vout5, Vout6, Vout7, and/or Vout8 will provide less sideband distortion than sideband distortion from one of the signal from Vout1, Vout2, Vout3, Vout4, Vout5, Vout6, Vout7, or Vout8.

In FIG. 20, transformer T1 and/or transformer T2 may be substituted with a differential amplifier, push pull amplifier, and/or combining network.

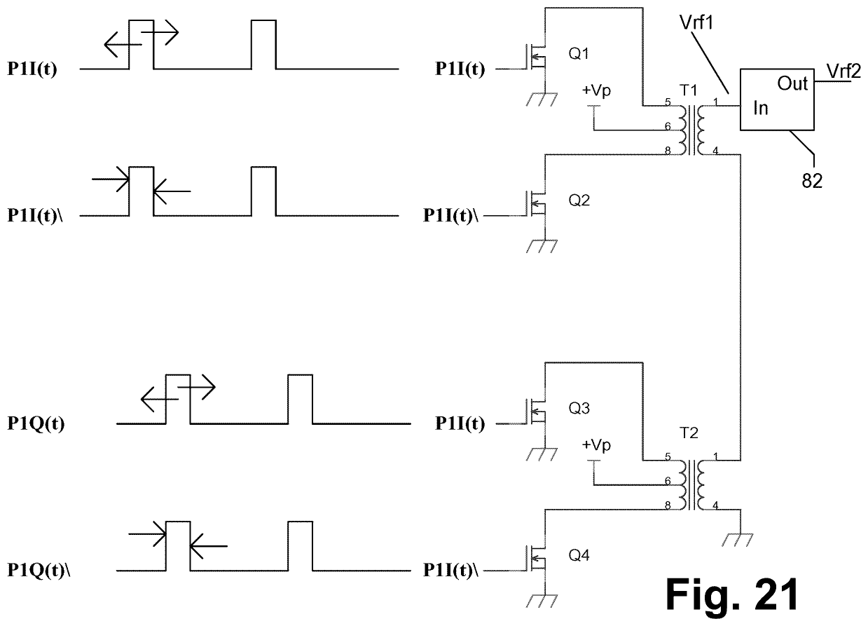

FIG. 21 shows an example of providing at least one single sideband signal or for providing a plurality of signals (e.g., pulses) to an amplifier system (e.g., including class A, class B, class C, class D, class E, class S, switch mode, and/or linear mode) to provide one or more single sideband signals. One or more single sideband signals may include one or more single sideband suppressed carrier signals. Amplifying devices Q1, Q2, Q3, and/or Q4 may be operated as switches or amplifying devices Q1, Q2, Q3, and/or Q4 may be operated as current sources (e.g., voltage dependent current sources). In one example, an input terminal of a first amplifying device (e.g., Q1) is coupled to a first pulsewidth modulated signal (e.g., P1I(t)), wherein the first pulsewidth modulated signal includes a zero phase (e.g., In-Phase) carrier signal and wherein the first pulsewidth modulated signal is modulated with a 0 degree (e.g., In-Phase) first modulating signal; an input terminal of a second amplifying device (e.g., Q2) is coupled to a second pulsewidth modulated signal (e.g., P1I(t)\), wherein the second pulsewidth modulated signal includes a zero (e.g., In-Phase) phase carrier signal and wherein the second pulsewidth modulated signal is modulated with a second modulating signal (e.g., the second modulating signal being 180 degrees out of phase of the zero degree (or the second modulating signal is inverted with respect to the) first modulating signal, or the second modulating signal is inverted with respect to the first In-Phase modulating signal); an input terminal of a third amplifying device (e.g., Q3) is coupled to a third pulsewidth modulated signal (e.g., P1Q(t)), wherein the third pulsewidth modulated signal includes a 90 degrees phase (e.g., Quadrature-Phase) carrier signal and wherein the third pulsewidth modulated signal is modulated with a 90 degree (e.g., Quadrature-Phase) third modulating signal; an input terminal of a fourth amplifying device (e.g., Q4) is coupled to a fourth pulsewidth modulated signal (e.g., P1Q(t)\), wherein the fourth pulsewidth modulated signal includes a 90 degrees phase (e.g., Quadrature-Phase) carrier signal and wherein the fourth pulsewidth modulated signal is modulated with an inverted 90 degree (e.g., inverted Quadrature-Phase or 270 degrees) fourth modulating signal. An output terminal of the first amplifying device is coupled to a first terminal of a first subtractor or first transformer, and an output terminal of the second amplifying device is coupled to a second terminal of a first subtractor or first transformer, wherein the first subtractor or first transformer attenuates or suppresses one or more carrier signals included in the first pulsewidth modulated signal and/or the second pulsewidth modulated signal. An output terminal of the third amplifying device is coupled to a first terminal of a second subtractor or second transformer, and an output terminal of the fourth amplifying device is coupled to a second terminal of a second subtractor or second transformer, wherein the second subtractor or second transformer attenuates or suppresses one or more carrier signals included in the third pulsewidth modulated signal and/or the fourth pulsewidth modulated signal. An output signal from the first subtractor or first transformer is combined or subtracted with an output signal from the second subtractor or second transformer to provide at least one single sideband (e.g., suppressed carrier, or non-suppressed carrier) signal (e.g., when modulation signal is non zero amplitude and/or when modulation signal is 0 amplitude). Combined or subtracted signals from the first subtractor and second subtractor, or from first transformer (e.g., T1 secondary winding) and/or second transformer (e.g., T2 secondary winding) may provide signal Vrf1 to be coupled to an input of a filter (e.g., 82), wherein an output of the filter (e.g., block 82) provided at least one amplitude modulated signal (e.g., Vrf2) including a single sideband signal or a single sideband suppressed carrier signal (e.g., Vrf2). In one or more embodiments, an act of a subtractive operation from an output signal of the first subtractor/transformer and an output signal from the second subtractor/transformer provides improved linearity in terms of sideband distortion products when compared to the individually pulsewidth modulated signals such as from the first pulsewidth modulated signal (e.g., P1I(t)), the second pulsewidth modulated signal (e.g., P1I(t)\), the third pulsewidth modulated signal (e.g., P1Q(t)), or the fourth pulsewidth modulated signal (e.g., P1Q(t)\). By processing, combining, and/or subtracting multiple (e.g., phase) pulsewidth modulated signal, lower distortion in terms of sideband distortion signal(s) is provided when compared to a single pulsewidth modulated signal.

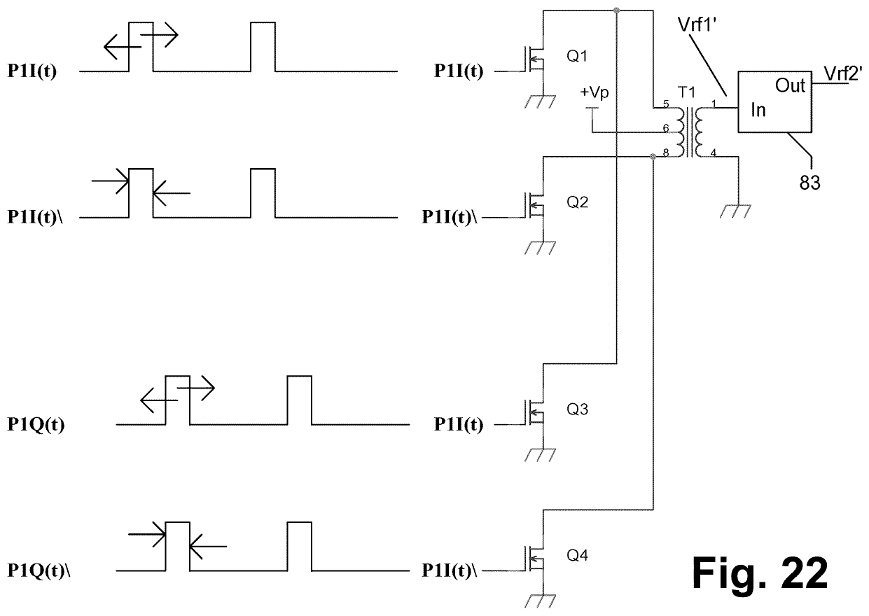

FIG. 22 shows an example of providing at least one single sideband signal or for providing a plurality of signals to an amplifier system (e.g., including class A, class B, class C, class D, class E, class S, switch mode, and/or linear mode) to provide one or more single sideband signals. One or more single sideband signals may include one or more single sideband suppressed carrier signals. Amplifying devices Q1, Q2, Q3, and/or Q4 may be operated as switches or amplifying devices Q1, Q2, Q3, and/or Q4 may be operated as current sources (e.g., voltage dependent current sources). In one example, an input terminal of a first amplifying device (e.g., Q1) is coupled to a first pulsewidth modulated signal (e.g., P1I(t)), wherein the first pulsewidth modulated signal includes a zero phase (e.g., In-Phase) carrier signal and wherein the first pulsewidth modulated signal is modulated with a 0 degree (e.g., In-Phase) first modulating signal; an input terminal of a second amplifying device (e.g., Q2) is coupled to a second pulsewidth modulated signal (e.g., P1I(t)\), wherein the second pulsewidth modulated signal includes a zero (e.g., In-Phase) phase carrier signal and wherein the second pulsewidth modulated signal is modulated with a second modulating signal (e.g., the second modulating signal being 180 degrees out of phase of the zero degree (or the second modulating signal is inverted with respect to the) first modulating signal, or the second modulating signal is inverted with respect to the first In-Phase modulating signal); an input terminal of a third amplifying device (e.g., Q3) is coupled to a third pulsewidth modulated signal (e.g., P1Q(t)), wherein the third pulsewidth modulated signal includes a 90 degrees phase (e.g., Quadrature-Phase) carrier signal and wherein the third pulsewidth modulated signal is modulated with a 90 degree (e.g., Quadrature-Phase) third modulating signal; an input terminal of a fourth amplifying device (e.g., Q4) is coupled to a fourth pulsewidth modulated signal (e.g., P1Q(t)\), wherein the fourth pulsewidth modulated signal includes a 90 degrees phase (e.g., Quadrature-Phase) carrier signal and wherein the fourth pulsewidth modulated signal is modulated with an inverted 90 degree (e.g., inverted Quadrature-Phase or 270 degrees) fourth modulating signal. An output terminal of the first amplifying device is coupled to a first terminal of a first transformer, and an output terminal of the second amplifying device is coupled to a second terminal of first transformer, T1, wherein for example, the first transformer attenuates or suppresses one or more carrier signals included in the first pulsewidth modulated signal and/or the second pulsewidth modulated signal. An output terminal of the third amplifying device is coupled to a first terminal of the first transformer, T1, and an output terminal of the fourth amplifying device is coupled to a second terminal of the first transformer, T1. An output signal (e.g., Vref1′) from the first transformer e.g., via secondary winding of T1) provides at least one single sideband (e.g., suppressed carrier, or non-suppressed carrier) signal (e.g., when modulation signal is non zero amplitude and/or when modulation signal is 0 amplitude). Signal Vre1′ may be coupled to an input of a filter (e.g., 83), wherein an output of the filter (e.g., block 83) provided at least one amplitude modulated signal (e.g., Vrf2′) including a single sideband signal or a single sideband suppressed carrier signal (e.g., Vrf2′).

In one or more embodiments (e.g., shown in FIG. 21 and/or FIG. 22), an output signal (e.g., Vrf1 in FIG. 21 and/or Vrf1′ in FIG. 22) from a combination of a first subtractor/transformer and an output signal from a second subtractor/transformer provides improved (e.g., amplitude modulation) linearity in terms of sideband distortion products when compared to amplitude modulated signal provided by an individual pulsewidth modulated signal such as (e.g., only one of) a first pulsewidth modulated signal (e.g., P1I(t)), a second pulsewidth modulated signal (e.g., P1I(t)\), a third pulsewidth modulated signal (e.g., P1Q(t)), or a fourth pulsewidth modulated signal (e.g., P1Q(t)\).

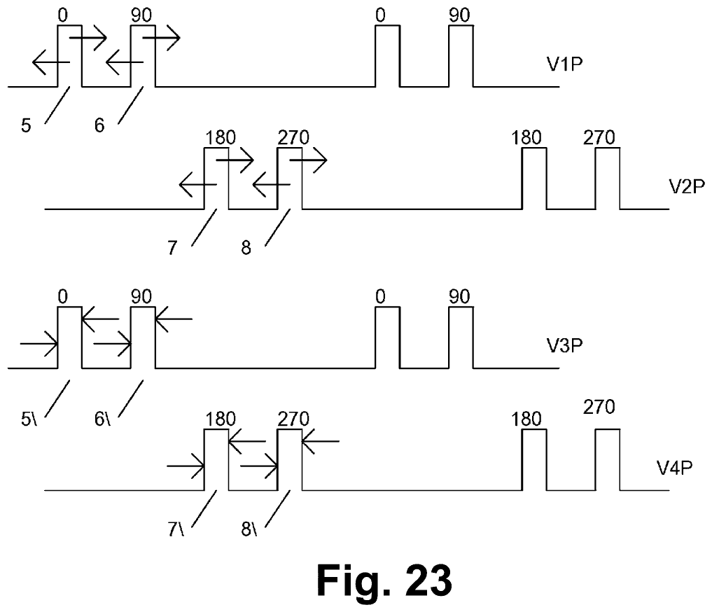

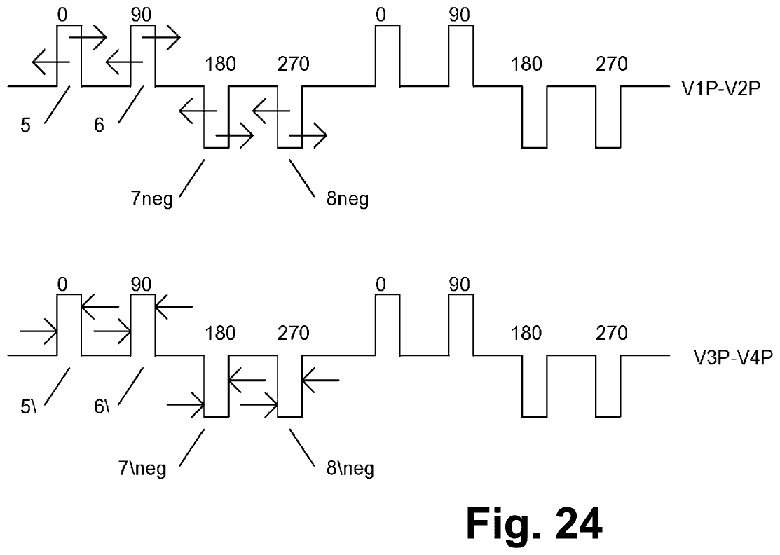

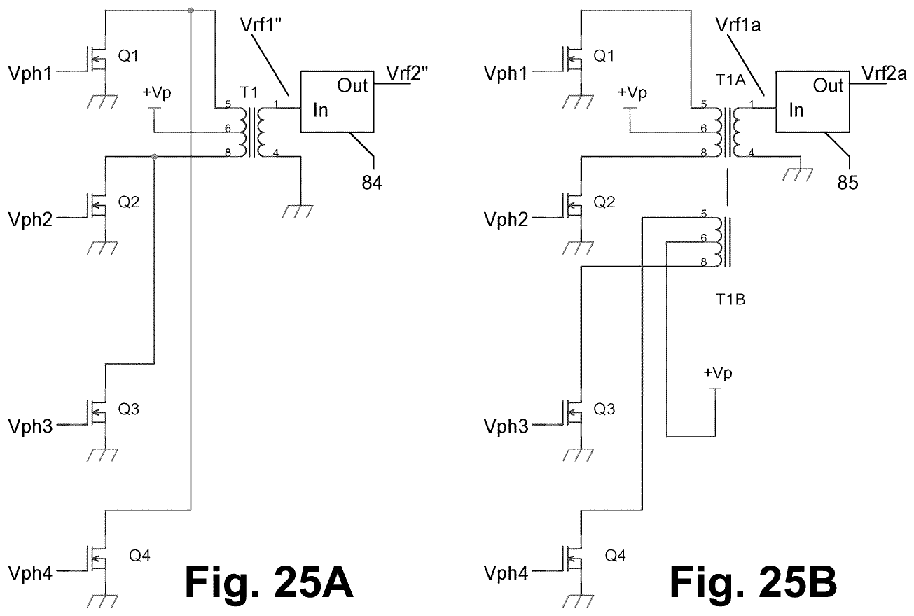

FIG. 23 shows an example embodiment. Signal VIP may be a combination of two pulsewidth modulated pulses at 0 degree and 90 degrees (e.g., in reference to a carrier frequency and/or carrier signal). The pulsewidth modulated signal, 5, is modulated with a first modulating signal including a 0 degree carrier signal phase, and the pulsewidth modulated signal, 6, is modulated with a second modulating signal including a 90 degree carrier signal phase. Signal V2P may be a combination of two pulsewidth modulated pulses at 180 degree and 270 degrees (e.g., in reference to a carrier frequency and/or carrier signal). The pulsewidth modulated signal, 7, is modulated with the first modulating signal including a 180 degree carrier signal phase, and the pulsewidth modulated signal, 8, is modulated with the second modulating signal including a 270 degree carrier signal phase. Signal V3P may be a combination of two pulsewidth modulated pulses at 0 degree and 90 degrees (e.g., in reference to a carrier frequency and/or carrier signal). The pulsewidth modulated signal, 5\, is modulated with an inverted (e.g. inverted phase or 180 degress) first modulating signal including a 0 degree carrier signal phase, and the pulsewidth modulated signal, 6\, is modulated with the inverted (e.g., inverted phase or 180 degrees) second modulating signal including a 90 degree carrier signal phase. Signal V4P may be a combination of two pulsewidth modulated pulses at 180 degree and 270 degrees (e.g., in reference to a carrier frequency and/or carrier signal). The pulsewidth modulated signal, 7\, is modulated with the inverted (e.g., inverted phase or 180 degrees) first modulating signal including a 180 degree carrier signal phase, and the pulsewidth modulated signal, 8\, is modulated with the inverted (e.g., inverted phase or 180 degrees) second modulating signal including a 270 degree carrier signal phase. In FIG. 23 one example of providing a single sideband suppressed carrier signal includes (V1P minus V3P)=(V1P−V3P), (V3P minus V1P)=(V3P−V1P), (V2P minus V4P)=(V2P−V4P), and/or (V4P minus V2P)=(V4P−V2P). Another example of providing another single sideband signal (e.g., for increased power output when compared to includes (V1P minus V3P)=(V1P−V3P), (V3P minus V1P)=(V3P−V1P), (V2P minus V4P)=(V2P−V4P), and/or (V4P minus V2P)=(V4P−V2P)) includes the following: [(VIP−V2P)−(V3P−V4P)], [(V2P−V1P)−(V3P-V4P)], [(VIP−V2P)−(V4P−V3P)], and/or [(V2P−V1P)−(V4P-V3P)]. Signals [(VIP−V2P)−(V3P−V4P)], [(V2P−V1P)−(V3P−V4P)], [(VIP−V2P)−(V4P−V3P)], and/or [(V2P−V1P)−(V4P−V3P)] may provide one or more single sideband suppressed carrier signal. In a single sideband signal including a carrier signal of frequency, f_{carrier}, and a (e.g., sine wave modulation signal including) modulation frequency, f_{mod}, a single sideband signal will provide a sideband signal whose frequency is either (f_{carrier}+f_{mod}) or (f_{carrier}−f_{mod}), wherein a single sideband signal having (e.g., single sideband, double sideband, or sideband) distortion will include one or more signals whose frequency (or frequencies) includes (f_{carrier}+nf_{mod}) or (f_{carrier}−nf_{mod}), n≥2 with n being an integer number. It was observed that reduced (e.g., sideband) distortion was provided by a signal represented by a combination of signals (e.g., combining/subtracting signals in FIG. 23, FIG. 24, FIG. 25A, and/or FIG. 25B) such as [(V1P−V2P)−(V3P−V4P)], (V2P−V1P)−(V3P−V4P)], [(V1P−V2P)−(V4P−V3P)], and/or [(V2P−V1P)−(V4P−V3P)] when compared to individual (e.g., pulsewidth modulated) signals, 5, 6, 5\, and/or 6 in FIG. 23, or when compared to individual (e.g., paired) signals shown in V1P, V2P, V3P, and/or V4P in FIG. 23. In one example pertaining to FIG. 23 a first modulating signal may include an In Phase modulating signal and/or a second modulating signal may include a Quadrature Phase modulating signal.

FIG. 24 shows at least one example embodiment/waveform including one or more (e.g., bipolar, AC, and/or tri-level) signals (V1P−V2P) and/or (V3P−V4P). In one example, positive signals are denoted by 5, 6, 5\, and or 6\; negative signals are denoted by 7neg, 8neg, 7\neg, and/or 8\neg.

In FIG. 24 (and/or FIG. 23 or other drawings/figures including pulsewidth modulation or pulses), arrows shown expanding shows the pulses (e.g., outward) to represent pulses being modulated by a non inverting modulation signal, whereas pulses shown with arrows in an inward or compressing manner represent pulses being modulated by an inverting modulation signal.

FIG. 25A shows an embodiment (e.g., utilizing at least 4 unique combination of phases for modulation and carrier signals) for providing a single sideband signal or for providing single sideband suppressed carrier signal. For example, a first pulsewidth modulated signal Vph1 may include signal V1P from FIG. 23, which is coupled to an input of amplifier (e.g., switching or linear amplifier) Q1, a second pulsewidth modulated signal Vph2 may include signal V2P from FIG. 23, which is coupled to an input of amplifier (e.g., switching or linear amplifier) Q2, a third pulsewidth modulated signal Vph3 may include signal V3P from FIG. 23, which is coupled to an input of amplifier (e.g., switching or linear amplifier) Q3, and/or a fourth pulsewidth modulated signal Vph4 may include signal V4P from FIG. 23, which is coupled to an input of amplifier (e.g., switching or linear amplifier) Q4. An output terminal from amplifier Q1 is coupled to a first terminal of a primary winding of T1, an output terminal from amplifier Q2 is coupled to a second terminal of a primary winding of T1, a potential difference between the first and second terminals of primary winding of T1 provides a signal of k₁×(V1P−V2P); an output terminal from amplifier Q3 is coupled to the second terminal of a primary winding of T1, an output terminal from amplifier Q4 is coupled to the first terminal of a primary winding of T1, a potential difference between the first and second terminals of primary winding of T1 provides a signal of k₁×(V4P−V3P)=−k₁(V3P−V4P); the combined signals of k₁×(V1P−V2P) plus −k₁(V3P−V4P) is provided across the first and second terminals of the primary winding of T1, which is equivalently [k₁−(V1P−V2P)−k₁(V3P−V4P)]. An output signal across secondary winding of T1 is provided by: Vrf1″→k₂[(V1P−V2P)−(V3P−V4P)], which for example provides at least one single sideband signal with suppressed carrier. Vrf1″ may be coupled to an input of a filter (e.g., 84), which outputs with signal Vrf2″ one or more amplitude modulated signals (e.g., one or more single sideband amplitude modulated signals and/or one or more single sideband amplitude modulated signals with suppressed carrier). Note that k₁ and/or k₂ may include one or more scaling factors (e.g., one or more constants).

FIG. 25B shows an embodiment (e.g., utilizing at least 4 unique combination of phases for modulation and carrier signals) for providing a single sideband signal or for providing single sideband suppressed carrier signal. For example, a first pulsewidth modulated signal Vph1 may include signal V1P from FIG. 23, which is coupled to an input of amplifier (e.g., switching or linear amplifier) Q1, a second pulsewidth modulated signal Vph2 may include signal V2P from FIG. 23, which is coupled to an input of amplifier (e.g., switching or linear amplifier) Q2, a third pulsewidth modulated signal Vph3 may include signal V3P from FIG. 23, which is coupled to an input of amplifier (e.g., switching or linear amplifier) Q3, and/or a fourth pulsewidth modulated signal Vph4 may include signal V4P from FIG. 23, which is coupled to an input of amplifier (e.g., switching or linear amplifier) Q4. In FIG. 25B, transformer T1A/T1B includes two independent primary windings and one (e.g., output) secondary winding. In FIG. 25B, An output terminal from amplifier Q1 is coupled to a first terminal of a first primary winding of T1A, a output terminal from amplifier Q2 is coupled to a second terminal of the first primary winding of T1A, a potential difference between the first and second terminals of first primary winding of T1A provides a signal of k₁−(V1P−V2P); an output terminal from amplifier Q4 is coupled to a first terminal of second primary winding of T1B, an output terminal from amplifier Q3 is coupled to a second terminal of second primary winding of T1B, a potential difference between the first and second terminals of primary winding of T1 provides a signal of k_{1′}×(V4P−V3P)=−k_{1′}(V3P−V4P); the combined signals of k_{1′}×(V1P−V2P) plus −k_{1′}(V3P−V4P) is provided across the secondary winding of the transformer (e.g., T1A/T1B) to provide an output signal Vrf1a which is equivalently expressed as: [k_{2′}×(V1P−V2P)−k_{2′}(V3P−V4P)]=k_{2′}[(V1P−V2P)−(V3P−V4P)]=Vrf1a. Signal Vrf1a for example provides at least one single sideband signal with suppressed carrier. Vrf1a may be coupled to an input of a filter (e.g., 85), which outputs with signal Vrf2a one or more amplitude modulated signals (e.g., one or more single sideband amplitude modulated signals and/or one or more single sideband amplitude modulated signals with suppressed carrier). Note that k_{1′} and/or k_{2′} may include one or more scaling factors (e.g., one or more constants).

In one or more examples, detailed description of FIG. 23 and/or FIG. 24 provides definitions, characterizations, and/or descriptions of V1P, V2P, V3P, and/or V4P.

An amplitude modulated signal may include an amplitude modulated signal with a carrier signal, lower sideband signal, and/or upper sideband signal.

An embodiment includes a method/apparatus to provide nonlinear pulsewidth modulation which subsequently provides improved linearity in one or more amplitude modulated signals. The one or more amplitude modulated signal(s) may include an amplitude modulated signal with a carrier signal, lower sideband signal, and/or upper sideband signal. The one or more amplitude modulated signal may include a single sideband amplitude modulated signal with a carrier signal, a single sideband amplitude modulated signal with a suppressed carrier signal, and/or, a double sideband amplitude modulated signal with a suppressed carrier signal. Modulating a pulsewidth linearly (e.g., via a modulating signal and linear function such as a triangle waveform or signal coupled to inputs of a comparator, wherein the comparator outputs a pulsewidth modulated signal) provides a distorted amplitude modulated signal and the applicant has found experimentally that modulating a pulsewidth non-linearly via a non-linear carrier waveform (e.g., a rectified sine wave, a full wave rectified waveform, and/or a parabolic waveform) improved amplitude modulation linearity and/or lowered distortion in sideband signals in an amplitude modulated signal (e.g., a single sideband signal, a double sideband signal, a single sideband suppressed carrier signal, a double sideband suppressed carrier signal, and/or a double sideband signal with a carrier signal).

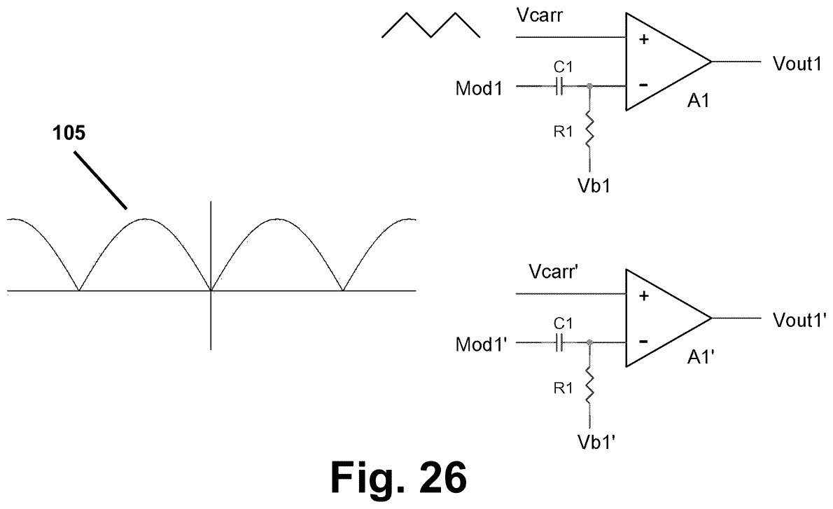

FIG. 26 with comparator A1, carrier signal Vcarr (e.g., a ramp signal or triangle waveform), mod1 modulation signal, modulation signal bias voltage Vb1, and output signal Vout1 (e.g., pulsewidth modulated output signal) shows a method of providing an amplitude modulated signal with a linear waveform such as a triangle waveform or a sawtooth waveform. This method/apparatus (e.g., A1 circuitry and associated components) provides an amplitude modulation signal with distortion products related to one or more sidebands, or this method/apparatus produces a nonlinear amplitude modulation effect. It should be noted that utilizing multiple pulsewidth modulators with nonlinear modulation effects can provide a reduced nonlinear amplitude modulation effect via combining the outputs of two or more signals from (e.g., two or more) pulsewidth modulators. In FIG. 26 A1 circuitry and associated components provide a linear pulsewidth modulator (e.g., the pulsewidth output from Vout1 is proportional to the amplitude of the modulation signal, Mod1) while providing a nonlinear amplitude modulation effect (e.g., with distortion signal related to one or more sideband signal or added sideband signals such that a demodulation of the amplitude modulation signal Vout1 provides harmonic and/or intermodulation distortion related to the modulation signal Mod1, wherein a modulation signal may include a sinusoidal wave or include a sine wave). It should be noted that with a linear carrier signal (e.g., ramp, sawtooth, or triangle waveform) sideband distortion (or nonlinear transfer function) can be characterized with a portion of a sine wave or a portion of a sin(x) function; for example, a nonlinear transfer function in terms of sideband distortion may be characterized by a portion of a sin(x) function.

In FIG. 26 with comparator A1′, carrier signal Vcarr′ (e.g., a rectified sine wave, full wave rectified sine wave, and/or parabolic waveform), mod1′ modulation signal, modulation signal bias voltage Vb1, and output signal Vout1′ (e.g., pulsewidth modulated output signal) distortion products related to sidebands and/or reduced nonlinear amplitude modulation effect may be provided via utilizing a nonlinear carrier signal (e.g., carrier signal Vcarr′ that is nonlinear compared to a ramp/sawtooth signal or a triangle waveform). In FIG. 26 carrier signal Vcarr′ may include a rectified sine wave, full wave rectified sine wave, and/or parabolic waveform to provide non linear pulsewidth modulation (e.g., pulsewidth from Vout′ is not proportional to an amplitude level of modulated signal Mod1′). Amplitude modulation distortion attenuation (or reduction) is provided by a nonlinear pulsewidth modulation via modulation signal Mod1′ (e.g., a distortion free modulation signal) with a nonlinear carrier signal (e.g., such as a rectified sine wave, full wave rectified sine wave, and/or parabolic waveform). For example as the modulation signal changes linearly in an increasing manner, the pulsewidth increases in a nonlinear manner such as characterized with a sin⁻¹(x) function (e.g., an inverse sine function or an inverse sine function within a portion). By utilizing for example a rectified sine wave for a carrier signal, Vcarr′, at least a portion of the rectified sinewave carrier signal tracks (or cancels, attenuates, and/or reduces) the sine nonlinearity transfer function of amplitude modulation signals, which then reduces sideband distortion.

FIG. 26 shows an example nonlinear carrier signal, 105, that may include a rectified sine wave, which may be an example of Vcarr′, a nonlinear waveform for providing a linearized amplitude modulation signal via a pulsewidth modulated signal. For example, with a full wave rectified sine wave coupled to a first input terminal of a comparator (e.g., A1′) and a modulating signal (e.g., Mod1′) coupled to a second terminal of the comparator (e.g., a1′), the output signal of the comparator (e.g., A1′) included an upper sideband signal with frequency (f_{c}+f_{mod}), a lower sideband signal with frequency (f_{c}−f_{mod}), a 2^{nd} harmonic upper sideband signal with frequency (f_{c}+2×f_{mod}), and/or a 2^{nd} harmonic lower sideband signal with frequency (f_{c}−2×f_{mod}). Note for example, f_{c}=carrier frequency and/or f_{mod}=modulation frequency. With a triangle wave carrier signal (e.g., Vcarr or Vcarr associated with comparator A1), and with comparable amplitudes of an upper sideband signal with frequency (f_{c}+f_{mod}), and/or of a lower sideband signal with frequency (f_{c}−f_{mod}); by experiment, it was found that the triangle wave carrier included/provided at least 3 times more in amplitude of the 2^{nd} harmonic upper sideband signal with frequency (f_{c}+2×f_{mod}), and/or at least 3 times more in amplitude of the 2^{nd} harmonic lower sideband signal with frequency (f_{c}−2×f_{mod}) when compared to a full wave rectified sine wave carrier signal, Vcarr′. Other nonlinear carrier signals may be utilized to provide lower distortion of sidebands of frequency (f_{c}+n×f_{mod}) and/or (f_{c}−n×f_{mod}), with n an integer and n≥2. Another example nonlinear carrier signal includes a signal with a variable slope such as (e.g., either) a variable positive slope or a variable negative slope.

FIG. 26 shows a parabolic waveform may be another example of Vcarr′, a nonlinear waveform for providing a linearized amplitude modulation signal via a pulsewidth modulated signal. A parabolic sine wave (or rectified sine wave) carrier signal showed for example when compared to a triangle wave carrier signal to provide lower amplitude(s) of sideband distortion signals (e.g., such as a 2^{nd} harmonic upper sideband signal with frequency (f_{c}+2×f_{mod}), and/or a 2^{nd} harmonic lower sideband signal with frequency (f_{c}−2×f_{mod}). A general characterization of sideband distortion signal can be expressed by signals including frequency (or frequencies) of (f_{c}+n×f_{mod}) and/or (f_{c}−n×f_{mod}), where n≥2, an n is an integer.

An alternative (e.g., embodiment) waveform or function coupled to a pulsewidth modulator may include an absolute value function such as |y(t)| where for example y(t)=Asin(ωt) and/or where |Asin(ωt)| may be utilized for a carrier signal in a pulsewidth modulator (e.g., to linearize amplitude modulation, or to reduce one or more sideband distortion signals. In one example an absolute value function is equivalent to a full wave rectification of a signal, which can be used for providing nonlinear pulsewidth modulation, which provides for low amplitude(s) of sideband distortion signals (e.g., as previously mentioned). In another embodiment, a waveform coupled to a pulsewidth modulator (e.g., to reduce sideband distortion or to linearize amplitude modulation) may include |Asin(ωt)|+Bsin(ωt), which for example provides half wave rectified signal. An embodiment may include at least a portion of |Asin(ωt)| and/or Bsin(ωt), which for example provides a carrier signal to a pulsewidth modulation system. For example, a carrier signal including at least a portion of |Asin(ωt)| and/or Bsin(ωt) provides a nonlinear carrier signal into a pulsewidth modulator which provides to lower one or more sideband distortion signal in an output amplitude modulation signal from the pulsewidth modulator.

Another embodiment includes processing (e.g., a modulating signal and/or a carrier signal) one or more modulating signals to reduce sideband distortion of one or more pulsewidth modulated signals (e.g., wherein the one or more pulsewidth modulated signals provides one or more amplitude modulated signals, wherein the one or more amplitude modulated signals includes a single sideband signal, a single sideband suppressed carrier signal, a double sideband suppressed carrier signal, and/or a double sideband signal with carrier).

An example nonlinear carrier signal includes a signal or waveform with a variable slope such as (e.g., either) a variable positive slope or variable negative slope. For example, a signal or waveform with a variable slope such as (e.g., either) a variable positive slope or variable negative slope provides a nonlinear carrier signal into a pulsewidth modulator which provides to lower one or more sideband distortion signal in an output amplitude modulation signal from the pulsewidth modulator.

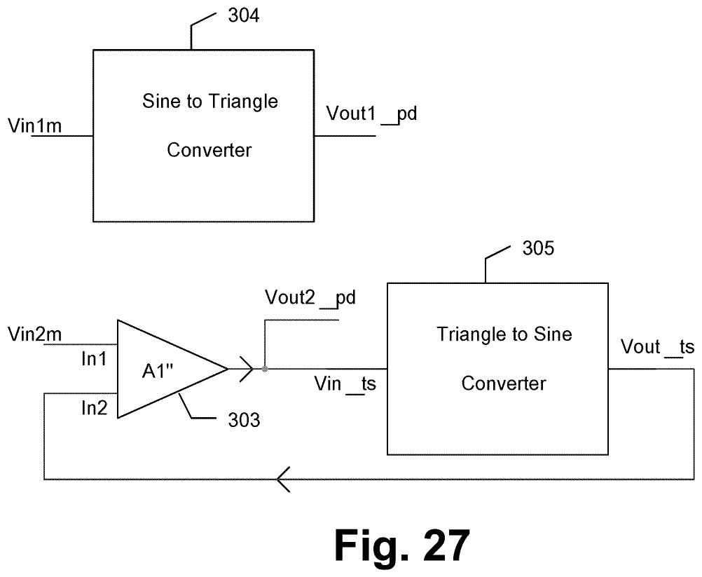

For example, see FIG. 27, which illustrates at least one embodiment of this application. In FIG. 27 block 304, a modulating signal is coupled to an input of a sine to triangle wave converter, which processes the modulating signal to provide a reduction in sideband distortion (e.g., sideband of a single sideband amplitude modulated signal, a single sideband signal, a suppressed carrier signal with one or more sidebands, and/or a carrier signal with one more sidebands). An output of sine to triangle converter, Vout1_pd is then coupled to a modulation input terminal of a pulsewidth modulator (e.g., to provide a linearized amplitude modulated signal).

One embodiment of a sine to triangle waveform converter to provide improved amplitude modulation linearity to a pulsewidth modulator is shown with amplifier 303 and block 305 in FIG. 27. A modulating signal, Vin2m is coupled to a first input terminal of amplifier A1″ and an output terminal of amplifier A1″ (e.g., 303) is coupled to triangle to sine wave converter circuit (e.g., a triangle to sine wave converter circuit may include a transfer function of f(x)=tanh(x) such as a hyper tangent function, and/or a modified hyper tangent function). An output signal, Vout_ts, of the triangle to sine wave converter (e.g., block 305) is coupled to a second input terminal of amplifier A1″ (e.g., 303) to form a feedback system or feedback circuit. Via feedback signal Vout_ts and amplifier A1″, a pre-distortion signal to the triangle to sine wave converter is provided as Vout2_pd, wherein Vout2_pd provides an equivalent output signal of a sine to triangle wave converter. A combination of a feedback amplifier and triangle to sine wave converter provides a system which synthesizes a sine to triangle converter. For example, Vout2_pd (e.g., output of a sine wave to triangle wave converter) may be coupled to a modulation input terminal of a pulsewidth modulator to improve amplitude modulation linearity or to provide lower sideband distortion.

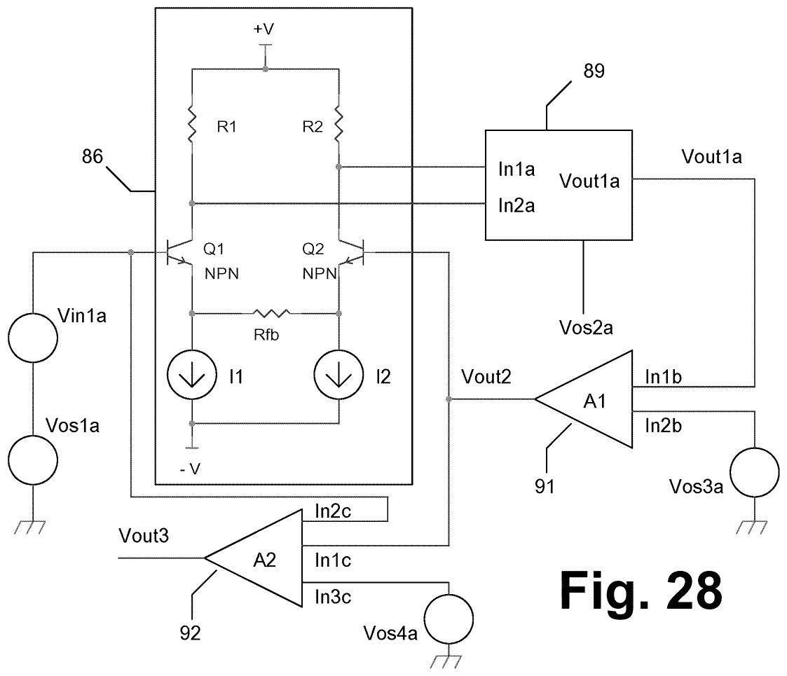

A sine wave to triangle wave converter example is shown in FIG. 28. A triangle to sine wave converter includes Q1 Rfb, Q2, current sources I1 and I2, and output loads R1 and/or R2 (e.g., block 86 in FIG. 28). Typically, if a triangle wave signal is coupled to the base of Q1 and/or Q2, an output signal from collector of Q1 and/or collector of Q2 will provide a sine wave signal. Resistor Rfb is adjusted or determined to provide an optimal sine wave signal (e.g., a sine wave signal output with lowest harmonic distortion when a triangle wave input signal). Typically current sources I1 and/or I2 will be adjusted or set for an optimal sine wave signal (e.g., sine wave signal with minimal distortion). In FIG. 28, a sinusoidal input signal Vin1a is combined optionally with an input offset voltage Vos1a and coupled to the base of Q1 (e.g., base of Q1 is a first input to a triangle to sine wave converter). One or more output terminals via the collector of Q1 and/or the collector of Q2 is coupled one or more inputs of an optional processor, 89. In one example, processor 89 may include a differential amplifier or a differential input to single ended output system/circuit. An output signal from 89, Vout1a, is coupled to a first input of amplifier A1, or 91 (e.g., In1c). An output signal from A1 or 91, Vout2, is coupled to the base of Q2 (e.g., a second input to a triangle to sine wave converter). Vout2 is a signal that is close to sinewave, but not exactly because Vout2 includes a predistortion signal to the nonlinearity of Q1 and Q2 circuit. Because Vout2 is coupled to the base of Q2, and feedback is utilize to linearize the nonlinearity transfer function of Q1 and Q2 (e.g., a tanh(x) curve or a nonlinear curve or a portion of a sine function), the voltage across the bases of Q1 and Q2 form an inverse (e.g., tanh(x) or sine) transfer function. Amplifier A2, 92, includes differential inputs In1c and In2c, which are coupled to the bases of Q1 and Q2. Amplifier A2, 92, provides a signal indicative of the voltage across the base of Q1 and the base of Q2. Vout3 then provides a predistortion signal to a modulation input terminal of a pulsewidth modulator to linearize amplitude modulation or to reduce sideband distortion. The example in FIG. 28 includes optional offset voltage sources Vos3a coupled to (e.g., In2b) a second input of amplifier A1 and/or Vos4a coupled to (e.g., In3c) a third input amplifier A2. The emitter of Q1 is coupled to the emitter of Q2. Resistor Rfb, which provides a modified tanh(x) function includes a first lead of Rfb coupled to the emitter of Q1 and a second lead of Rfb coupled to the emitter of Q2. Current sources I1 and I2 while in one example includes I1=I2, may include an embodiment which includes I1≠I2 to for example to shape a modified tanh(x) to provide an offset symmetry or asymmetrical transfer function (e.g., to linearize an amplitude modulation function via pulsewidth modulator).

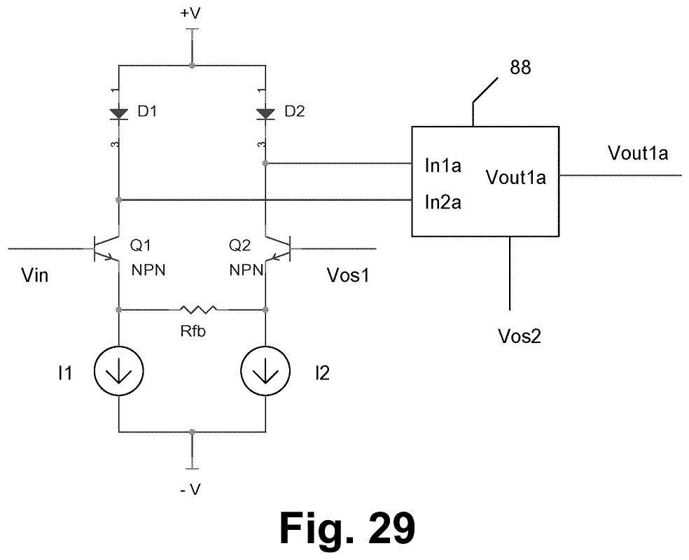

FIG. 29 shows an embodiment which provides a pre-distorted signal to a modulation input terminal of a pulsewidth modulator (e.g., to linearize an amplitude modulation function or to reduce sideband distortion). A differential pair transistor circuit includes Q1 and Q2 with the emitter of Q1 coupled to the emitter of Q2. Resistor Rfb may provide a coupling component to couple the emitter of Q1 to the emitter of Q2. A sine wave input signal is coupled to a first the base of Q1 and/or an offset voltage is coupled to the base of Q2. An output signal from the collector of Q1 and/or the collector of Q2 is coupled optionally to a first input and/or second input block 88, a processor. Output signal Vout1a in FIG. 29 provides a (e.g., pre-distortion) signal to a modulator input terminal of a pulsewidth modulator which reduces sideband distortion or which linearizes an amplitude modulation function. Optionally, an offset voltage, Vos2 may be coupled to processor 88. A differential pair amplifier such as shown with Q1 and Q2 in FIG. 29 (or with Q1 and Q1 and its associated circuitry in FIG. 28) may provide a function characterized as y=a₁x+a₂x²+a₃x³+any higher order terms. With an input signal Vin or an input signal Vin combined with an offset voltage (e.g., Vos1), the output signal from collector Q1, collector Q2, and/or Vout1a may provide an expansive transfer function similar to the arc sine of x (e.g., arcsin(x) or sin⁻¹(x)), which then provides a pre-distortion signal to a modulation input of a pulsewidth modulator such that the pulsewidth modulator provides a linearized amplitude modulated signal or a reduced amplitude of a distortion sideband signal (e.g., when compared to coupling a non pre-distorted signal into the modulation input of a pulsewidth modulator). One embodiment may include I1=I2 or I1≠I2. For example, an imbalance in the current sources for Q1 and/or Q2 may provide yet another nonlinear transfer function suitable for coupling into a modulation input of a pulsewidth modulator (e.g., to reduce sideband distortion and/or to provide a more linear amplitude modulation function).

As previously mentioned, a sine wave to triangle wave converter (or processor) may be included in a pulsewidth modulator to provide an amplitude modulated signal (e.g., a linearized amplitude modulated signal and/or an amplitude modulated signal with reduced sideband distortion signal(s)). One or more sine wave to triangle wave converter is described in U.S. Pat. No. 11,177,786 issued on Nov. 16, 2021 with application Ser. No. 16/866,399 filed on May 4, 2020. U.S. Pat. No. 11,177,786 issued on Nov. 16, 2021 with application Ser. No. 16/866,399 filed on May 4, 2020 is incorporated by reference in this application.

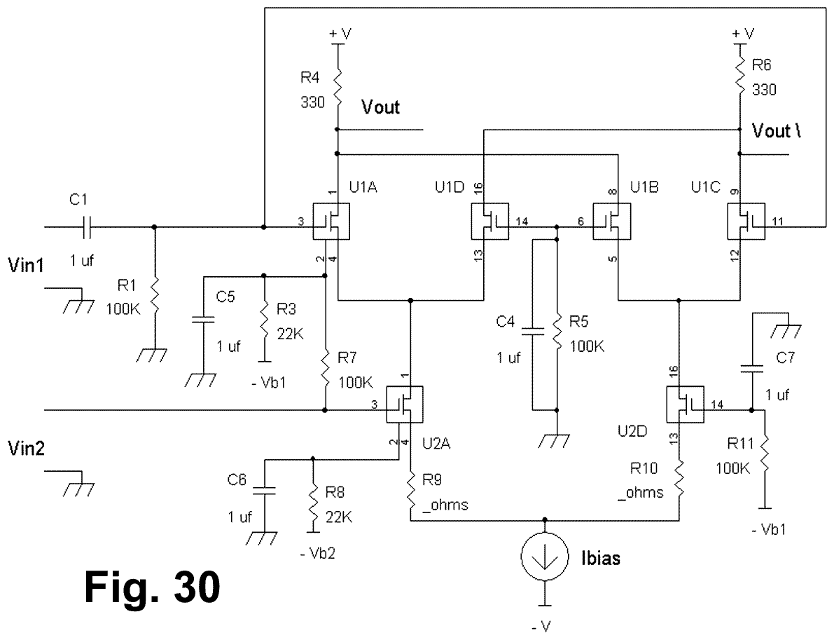

FIG. 30 shows an FET four quadrant multiplier circuit that is found to have new use that includes a sine wave to triangle wave processing method or a sine wave to triangle wave apparatus or a sine wave to triangle wave circuit. That is, the circuit in FIG. 30 includes a sine wave to triangle wave converter. A first differential amplifier comprising of U1A and U1D has either its input terminals or output terminals cross coupled with a second differential amplifier comprising U1B and U1C. The source terminals of U1A and U1D are coupled and further coupled to a first current signal via U2A. The source terminals of U1B and U1C are coupled and further coupled to a current signal via U2D. A first signal (e.g., Vin1) terminal is coupled to the gate terminals of U1A and U1D while the gate terminals of U1B and U1C are coupled to a second signal terminal (e.g., ground or inverting phase first signal). The source terminals of U1B and U1C are coupled and further coupled to a second signal current via U2D. The first signal current via the drain of U2A comprises a DC current, DCQ, and a Vin2 AC signal current. The second signal current via the drain of U2D comprises substantially the same DC current as DCQ with an inverted phase Vin2 AC signal current. The drain terminals of U1A and U1B are coupled together and provide an output terminal Vout; the drain terminals of U1C and U1D are coupled together and provide an output terminal Vout\. Although load resistors R4 and R6 have example resistance values of 330Ω each, other resistance values may be used. The load resistors R4 and or R6 may be substituted by coupling the drains of the FET that were coupled to R4 and R6 to the input terminals of grounded gate amplifiers or to the input terminals of grounded base amplifiers or to the input terminals of transresistance amplifiers. With a sine wave signal included to Vin1 and a signal included into Vin2, signal output from Vout or Vout\ includes a triangle waveform. Vin2 may be a voltage close to the voltage of −vb1. R9 and R10 are optional source degeneration or local feedback resistors for U2A and U2D, which provides a more linear transfer function for (e.g., a third) differential amplifier U2A and U2D. DC biasing for all FETs are provided by current source Ibias. Although in FIG. 30, insulated gate, MOS, or enhancement mode FETs are shown, depletion mode or JFETs (Junction Field Effect Transistor) may be used. Yet alternatively, bipolar transistors with series emitter degeneration resistors (e.g., in the locations of U1A, U1B, U1C, and U1D) may also provide sine wave to triangle wave conversion. FIG. 30 can provide a mixer or multiplier function with a modulated (e.g., with Vin2 included for a modulating signal) triangle waveform output for a sinewave input (e.g., sine wave signal at Vin1).

In FIG. 30 Vin1 can include a modulating waveform. With Vin2 set to a DC signal, the output of the circuit at Vout or Vout\ provides a pre-distorted modulating signal to a pulsewidth modulator, wherein the pre-distorted modulating signal provide for a linearized amplitude modulation effect or wherein the pre-distorted modulating signal provides for lower sideband distortion in an amplitude modulated signal (e.g., from a pulsewidth modulated signal). In FIG. 30 with Vin2 set to a DC signal/voltage, output signal Vout or Vout\ provides a sine wave to triangle converter for input signal Vin1.

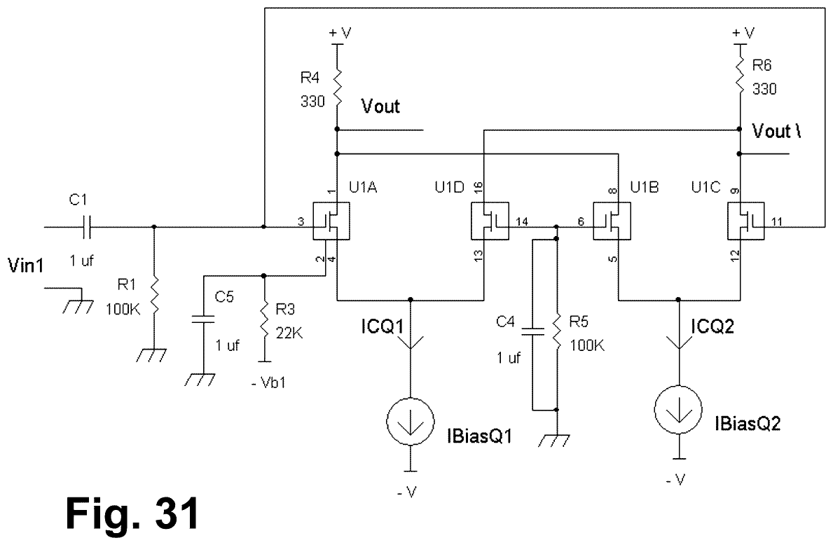

FIG. 31 shows a sine to triangle wave converter circuit. Field Effect Transistors U1A, U1B, U1C, and U1D are similarly connected as described for FIG. 30. The source terminals of U1A and U1D are coupled together and further coupled to a current source IBiasQ1 denoted by ICQ1. The source terminals of U1B and U1C are coupled together and further coupled to a current source IBiasQ2 denoted by ICQ2. Sine wave to triangle wave conversion is provided by coupling a sine wave signal for Vin1 and having unequal currents for IBiasQ1 and IBiasQ (e.g., ICQ1≠ICQ2 or IBiasQ1≠IBiasQ2). An output signal is provided via Vout or Vout\.

Alternatively in FIG. 31, two resistors may be substituted for current sources IBiasQ1 and IBiasQ2 to provide sine wave to triangle wave conversion. Preferably the current flowing through these two resistors is not equal. In FIG. 31, the FETs U1A, U1B, U1C, and U1D may be substituted with depletion mode devices, or bipolar transistors with series emitter resistors (e.g., series emitter degeneration resistors).

In FIG. 31 Vin1 can include a modulating waveform. With ICQ1≠ICQ2 or IBiasQ1≠IBiasQ2, the output of the circuit at Vout or Vout\ provides a pre-distorted modulating signal to a pulsewidth modulator, wherein the pre-distorted modulating signal provide for a linearized amplitude modulation effect or wherein the pre-distorted modulating signal provides for lower sideband distortion in an amplitude modulated signal (e.g., from a pulsewidth modulated signal). In FIG. 31 with ICQ1≠ICQ2 or IBiasQ1≠IBiasQ2, output signal Vout or Vout\ provides a sine wave to triangle converter for input signal Vin1.

Note that the circuits in FIG. 30 and FIG. 31 are not the same as a triangle wave to sine wave converter, where the input signal is a triangle wave (e.g., instead of a sine wave signal) and the output signal is a sine wave (e.g., instead of a triangle waveform).

The examples of sine to triangle converter shown in FIG. 30 and/or FIG. 31 may process a modulation signal by coupling a modulation signal to an input to the sine to triangle converter and coupling an output signal from the sine to triangle converter to a modulation input of a pulsewidth modulator (e.g., to provide a linearized amplitude modulation signal, or to provide for reduced sideband distortion).

In FIG. 30 and/or FIG. 31 example resistor values and/or capacitor values are shown, and other resistor values and/or capacitor values may be used.

An embodiment of this application may include a pre-distorted modulation signal (or processed modulation signal) and/or a nonlinear carrier signal (e.g., a parabolic signal, rectified signal, full wave rectified signal, half wave rectified signal, an absolute value function including A|sin(ωt)|, and/or a curved function). For example, to provide a linearized amplitude modulation function (e.g., a more linear amplitude modulation signal modulator, or to provide reduced sideband signal distortion) an embodiment may include a pre-distorted modulation signal (or processed modulation signal, or processed signal including a sine to triangle converter, or a signal processed with a hyper-tangent function, or a signal processed with an inverse hyper-tangent function, or a signal processed with an inverse sine function, or a signal processed with a sine function, or a signal processed with a modified hyper-tangent function, or a signal processed with a triangle to sine converter, or a signal processed with modified inverse hyper-tangent function, or a signal processed with a nonlinear transfer function) and/or a nonlinear carrier signal (e.g., a parabolic signal, rectified signal, full wave rectified signal, half wave rectified signal, an absolute value function including A|sin(ωt)|, and/or a curved function).

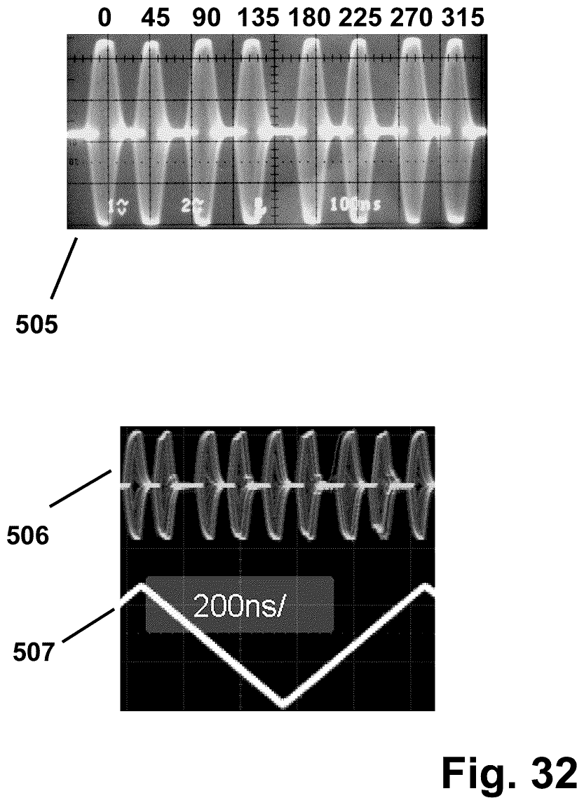

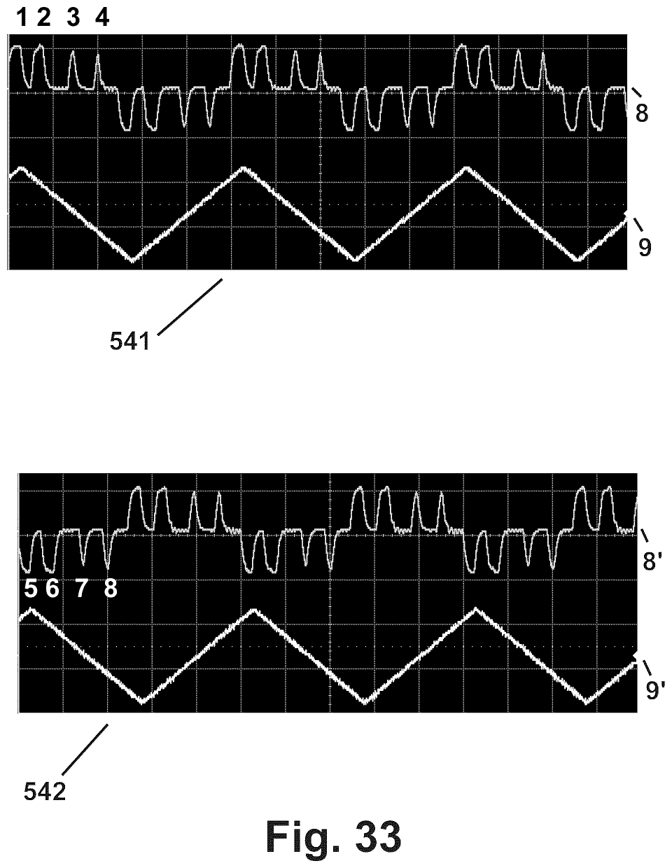

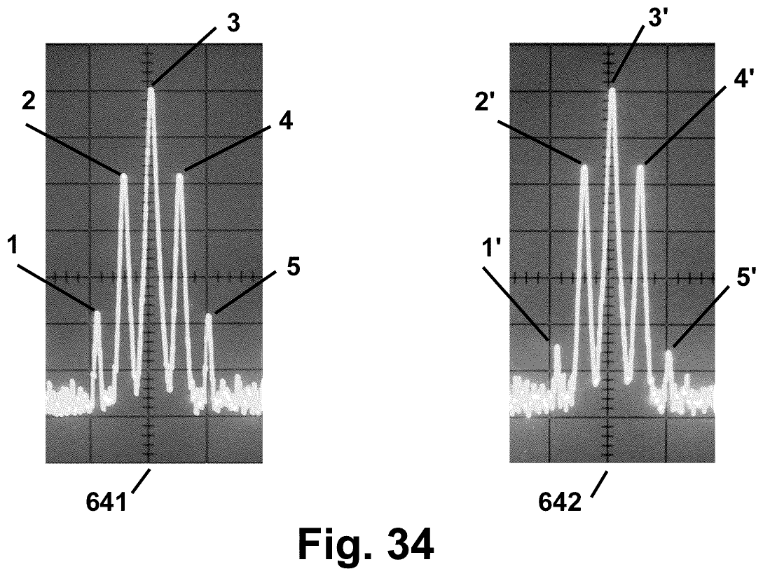

Experiments revealed in those one or more embodiments (e.g., including multiple pulsewidth modulation signals, multiple pulsewidth modulation signal described in FIG. 17 through FIG. 25B including any of the following signals: RFout1 in FIG. 20, Vrf1 in FIG. 21, Vrf1′ in FIG. 22, Vrf1″ in FIG. 25A, Vrf1a in FIG. 25B, any combination of signals in FIG. 24 of (V1P−V2P) and/or (V3P−V4P), any combination of signals in FIG. 23 of V1P, V2P, V3P, and/or V4P, any combination of the signals in FIG. 22 of P1I(t), P1I(t)\, P1Q(t), and/or P1Q(t)\) providing a single sideband (e.g., suppressed carrier signal or non-suppressed carrier) at a fundamental frequency also provided at least one single sideband signal (e.g., with unexpected result) of the opposite sideband (e.g., an opposite sideband signal at a harmonic). For example, by processing (e.g., including subtracting) multiple pulsewidth modulated signals to provide an amplitude modulated single sideband signal of lower sideband at a fundamental frequency, a single sideband signal of upper sideband is provided at a 3^{rd} harmonic frequency, 7^{th} harmonic frequency, and/or 11^{th} harmonic frequency. For another example, by processing (e.g., including combining or adding) multiple pulsewidth modulated signals to provide an amplitude modulated single sideband signal of lower sideband at a fundamental frequency, a single sideband signal of upper sideband is provided at a 3^{rd} harmonic frequency, 7^{th} harmonic frequency, and/or 11^{th} harmonic frequency. In another example, by processing (e.g., including subtracting) multiple pulsewidth modulated signals to provide an amplitude modulated single sideband signal (e.g., of lower sideband) at a fundamental frequency, at the 2^{nd} harmonic frequency a double sideband signal with a carrier signal was provided. In yet another example, by processing (e.g., including combining or adding) multiple pulsewidth modulated signals to provide an amplitude modulated single sideband signal (e.g., of lower sideband) at a fundamental frequency, and at the 4^{th} harmonic frequency, a (e.g., strong or dominant amplitude) carrier signal is provided with suppressed lower sideband signal and/or suppressed upper sideband signal. In the previous examples, the amplitude modulated single sideband signal may include a single sideband suppressed carrier signal or a single sideband signal with a carrier signal. Also note that with phasing changes of pulsewidth modulated signals or changes in combining pulsewidth modulated signals, the sidebands can be switched or reversed. For example: By processing (e.g., including subtracting or adding) multiple pulsewidth modulated signals to provide an amplitude modulated single sideband signal of upper sideband at a fundamental frequency, a single sideband signal of lower sideband is provided at a 3^{rd} harmonic frequency, 7^{th} harmonic frequency, and/or 11^{th} harmonic frequency. For another example, by processing (e.g., including combining or adding) multiple pulsewidth modulated signals to provide an amplitude modulated single sideband signal of upper sideband at a fundamental frequency, a single sideband signal of lower sideband is provided at a 3^{rd} harmonic frequency, 7^{th} harmonic frequency, and/or 11^{th} harmonic frequency. In another example, by processing (e.g., including subtracting) multiple pulsewidth modulated signals to provide an amplitude modulated single sideband signal (e.g., of upper sideband) at a fundamental frequency, at the 2^{nd} harmonic frequency, a double sideband signal with carrier signal was provided. In yet another example, by processing (e.g., including combining or adding) multiple pulsewidth modulated signals to provide an amplitude modulated single sideband signal (e.g., of upper sideband) at a fundamental frequency, and at the 4^{th} harmonic frequency, a (e.g., strong or dominant amplitude) carrier signal is provided with suppressed lower sideband signal and/or suppressed upper sideband signal. In the previous examples, the amplitude modulated single sideband signal may include a single sideband suppressed carrier signal or a single sideband signal with a carrier signal. In the above examples and/or observations stated an eight phase signal such as shown in FIG. 32 and/or FIG. 33 will provide for example multiple single sideband signals from 8 phases of pulsewidth modulated signals such that at a harmonic of a fundamental carrier frequency will provide another single sideband suppressed carrier signal of the opposite sideband when compared to the single sideband suppressed carrier signal at fundamental frequency. In another example where 4 phases of are utilized such as shown in FIG. 20 utilizing four different phases via signals Vout1 through Vout4 or via signals Vout5 through Vout8, signals V1A and/or V1B from FIG. 20 via combination logic also provide multiple single sideband signals (e.g., with carrier signal) wherein multiple single sideband signals from 4 phases of pulsewidth modulated signals such that at a harmonic of a fundamental carrier frequency will provide another single sideband (e.g., with carrier or with suppressed carrier) signal of the opposite sideband when compared to a single sideband signal at the fundamental frequency.

FIG. 32 shows waveform 505, an example of a multiple phase and multiple level (e.g., tri-level) signal to provide at least one single sideband signal. In waveform 505 there are 8 different phases of pulsewidth modulated signal with example phases at 0 degree, 45 degrees, 90 degrees, 135 degrees, 180 degrees, 225 degrees, 270 degrees, and/or 315 degrees (or other example phases may be used; or including phase angles not necessarily space at 45 degrees apart). Waveform 505 (or an embodiment) may be provided by at least part (or whole) from methods or apparatuses shown and described in one of more of the following figures: FIG. 1, FIG. 2, FIG. 4, FIG. 5A, FIG. 5B, FIG. 5C, FIG. 6, FIG. 7, FIG. 8, FIG. 9, FIG. 10, FIG. 11, FIG. 12, FIG. 14, FIG. 15, FIG. 17, FIG. 18, FIG. 19, FIG. 20, FIG. 21, FIG. 22, FIG. 23, FIG. 24, FIG. 25A, FIG. 25B, and/or FIG. 26.

In FIG. 32 waveform 505 shows a total of 8 different phase signals, which are provided with First Phase carrier signals having four example phases, 0 degree, 90 degrees, 180 degrees, and 270 degrees combined with Second Phase carrier signals having four example phases, 0 degree, 90 degrees, 180 degrees, and 270 degrees. In one example, the Second Phase carrier signals are 45 degrees phase shifted from the First Phase signals, when combining (or subtracting) four First Phase carrier pulsewidth modulated signals with four Second Phase carrier signals, an 8 phase pulsewidth modulated signal is provided; for example, the 8 phase pulsewidth modulated signals provide one or more single sideband (e.g., suppressed carrier) signals; the 8 phase pulsewidth modulated signals provide one or more single sideband (e.g., suppressed carrier) signals with improved amplitude modulation linearity and/or lower sideband distortion. In another example, an 8 phase pulsewidth modulation method/apparatus is shown in FIG. 18, FIG. 19, and/or FIG. 20. Another example may include (e.g., via T1 and T2 in FIG. 20) signal RF Out1 in FIG. 20 to provide waveform 505 and waveform 506 in FIG. 32. Signal RF Out1 in FIG. 20 may also provide waveform 8 and waveform 8′ in FIG. 33. One embodiment includes processing a first set of multiple phase pulsewidth modulated signal modulated with a non inverting modulation signal and a second set of multiple pulsewidth modulated signals modulated with an inverting modulation signal. For example, if one of the pulsewidth modulated signals in the first set includes a signal such as PWa(t) and one of the pulsewidth modulated signals in the second set includes a signal such as PWb(t) shown in FIG. 10, 11, and/or 12, processing (e.g., by subtraction or combination logic) PWa(t) and PWb(t) will provide two pulsewidth modulated signals such as the two pulsewidth modulated signals shown in 107 and 108 in FIG. 10, FIG. 11, and/or FIG. 12. In one embodiment a first set of four (e.g., phase) sequence pulsewidth modulated signals is processed (e.g., with a processor) with a second set of four (e.g., phase) sequence pulsewidth modulated signals, which an output signal of the processor will provide two pulsewidth modulated signal for each of the four sequence pulsewidth modulated signals, which provides a total of 4×2=8 pulsewidth modulated signals or eight pulsewidth modulated signals in sequence such as shown in FIG. 32 waveform 505 and/or waveform 506, or eight pulsewidth modulated signals in sequence such as shown in FIG. 33 waveform 8 and/or waveform 8′; processing may include subtracting, combining, and/or combination logic.

In FIG. 32 an example carrier waveform is shown in 507 (e.g., a linear carrier waveform, or a triangle wave), which in this example waveform 507 shows 1 period or 1 cycle. Above the 1 cycle carrier waveform 507 are the multiple phased pulsewidth modulated signals (e.g., with three levels, tri-levels, and/or bipolar levels) shown in 506.

FIG. 33 shows two more examples of multiple phase pulsewidth modulated signal to provide single sideband signals. Dual trace oscilloscope waveforms in 541 shows a linear carrier signal 9 with associated multiple (e.g., eight) phase and multiple polarity signals shown in 8. The waveform shown in 8 of FIG. 33 shows 8 different phases of pulsewidth modulated signal within a cycle of a carrier signal 9. Dual trace oscilloscope waveforms in 544 shows a linear carrier signal 9′ with associated multiple (e.g., eight) phase and multiple polarity signals shown in 8′. The waveform shown in 8′ of FIG. 33 shows 8 different phases of pulsewidth modulated signal within a cycle of a carrier signal 9′. In one example comparison in FIG. 33, the signal from waveform 8′ provides an approximate inversion of the waveform shown in 8, which confirms or provides that the (e.g., 8) multiple phase pulsewidth modulated signal include varying widths of pulses and/or positive and negative polarities to provide at least one single sideband (e.g., suppressed carrier) signal. An embodiment may include multiple phase (e.g., at least 4 different phases, or 8 different phases) pulsewidth modulated signals which for example spaced 45 degrees or one-eighth period (e.g., wherein one period is equal to the reciprocal of the fundamental frequency of the carrier signal for example; or period P=(1/f_{c}) and (P/8) apart from each pulsewidth modulated pulse, wherein f_{c}=a carrier frequency). In another example, the (e.g., eight) multiple phase pulsewidth modulated signals may be spaced other than 45 degrees.

An alternate embodiment to the examples of utilizing 8 phases illustrated in FIG. 32 and/or FIG. 33, may include utilizing 4 phases (e.g., instead of 8) of pulsewidth modulated signals to provide one or more single sideband signals. In one example of using 4 phases, the four phase pulsewidth signal to provide at least one single sideband signal may comprise pulsewidth modulated signals at: 0 degree+φ1, 45 degrees+φ2, 90 degrees+φ3, and 135 degrees+φ4; where φ1, φ2, φ3, and/or φ4 are equal, or φ1, φ2, φ3, and/or φ4 are different or arbitrary offset angles (e.g., offset angle: a positive angle or negative angle or a zero degree angle).

FIG. 33 shows an example of providing/generating one or more single sideband signals with bipolar or AC (alternating current) pulsewidth modulated signals. For example, in waveform 541 of FIG. 33 the first four pulsewidth modulated pulses labeled 1, 2, 3, and 4 are shown on the top trace, and these four pulsewidth modulated pulses labeled 1, 2, 3, and 4 at the time of capturing the oscilloscope waveform shows that that pulsewidth modulated pulses labeled 1, 2, 3, and 4 include positive pulses of varying pulsewidths. At another time waveform 542 shows the first sequence of four pulsewidth modulated pulses labeled 5, 6, 7, and 8 wherein these four pulsewidth modulated pulses labeled 5, 6, 7, and 8 include negative pulses of varying pulsewidth. Note that in both oscilloscope waveforms 541 and 542, the triggering is referenced off the bottom triangle carrier waveform to provide an accurate representation that the pulses 1 through 8 shown are not only varying in pulsewidths, but also varying in polarity. When the modulation of the pulsewidth modulation is displayed over multiple sweeps, the one or more pulsewidth modulation signals related to FIG. 33 is shown in FIG. 32 waveform 505 and/or 506 for example. Waveform 505 and/or waveform 506 show(s) positive and negative pulses displayed over a longer exposure time.

FIG. 33 waveform 541 shows an example of double pulse pulsewidth modulation in (e.g., positive) pulses 1 and 2 which is similar to FIG. 10 pulses, 111 and 112. In FIG. 10 if pulsewidth of PWb(t) is wider than the pulsewidth of PWa(t) and there is a subtraction process such as [PWb(t)−PWa(t)]>0 a non negative value, then two positive pulses will be provided as shown in 107 and/or 108 of FIG. 10 (e.g., pulses 111 and 112 in FIG. 10 or pulses 1 and 2 in FIG. 33). Because modulation signal may include positive and negative values, there will be a time when pulsewidth of PWa(t) is wider than the pulsewidth of PWb(t), which will provide via a subtraction process such as [PWb(t)−PWa(t)]≤0 a non positive value (see FIG. 10) that provides two pulsewidth modulated negative pulses, which is illustrated in FIG. 33 waveform 542, and for example negative pulses 5 and 6 (or pulses 7 and 8).

FIG. 34 shows a comparison of pulsewidth modulated signals (e.g., which may (or may not) include double edge pulsewidth modulated signals) providing amplitude modulation signals in spectrum 641 and in spectrum 642. In spectrum 641, the amplitude modulation signal is provided by a linear carrier signal (e.g., for providing linear pulsewidth modulation with a triangle wave or with a sawtooth waveform) with a sinusoidal modulating signal; this spectrum with a linear carrier signal includes carrier signal 3 (e.g., frequency of f_{c}), lower sideband signal 2 (e.g., frequency of f_{c}−f_{mod}), upper sideband signal 4 (e.g., frequency of f_{c}+f_{mod}), distortion signal lower sideband 1 (e.g., resulting in 2^{nd} harmonic distortion or amplitude modulation nonlinearity of frequency f_{c}−2f_{mod}), and/or distortion signal upper sideband 5 (e.g., resulting in 2^{nd} harmonic distortion or amplitude modulation nonlinearity of frequency f_{c}+2f_{mod}). With 10 dB per division scale, there is about a 30 dB difference between upper sideband signal 4 and upper sideband distortion signal 5, or about a 3% distortion factor, and similar measurements were found for lower sideband signal 2 and its distortion signal lower sideband 1 having about a 3% distortion factor. Spectrum 642 is provided by a pulsewidth modulation signal utilizing a nonlinear carrier signal such one shown in FIG. 26, waveform 105, which will reduce distortion. In spectrum 642 the amplitude modulation signal provided by a non linear carrier signal (e.g., to provide nonlinear pulsewidth modulation by utilizing any of the following example signals: a rectified sine wave, a full wave rectified sine wave, a parabolic waveform, a variable positive slope waveform, or a variable slope negative slope waveform) with a sinusoidal modulating signal includes carrier signal 3′ (e.g., frequency of f_{c}), lower sideband signal 2′ (e.g., frequency of f_{c}−f_{mod}), upper sideband signal 4 (e.g., frequency of f_{c}−f_{mod}), distortion signal lower sideband 1′ (e.g., resulting in 2^{nd} harmonic distortion or amplitude modulation nonlinearity of frequency f_{c}−2f_{mod}), and/or distortion signal upper sideband 5′ (e.g., resulting in 2^{nd} harmonic distortion or amplitude modulation nonlinearity of frequency f_{c}+2f_{mod}). With 10 dB per division scale, there is about a 40 dB difference between upper sideband signal 4′ and upper sideband distortion signal 5′, or about a 1% distortion factor; similarly there is about a 40 dB difference between lower sideband signal 2′ and lower sideband distortion signal 1′, or about a 1% distortion. In comparison with a linear waveform carrier signal, a nonlinear carrier signal provides distortion reduction and/or improved amplitude modulation linearity; for example a difference from 3% distortion with the linear waveform carrier signal versus 1% with a nonlinear waveform carrier signal, which provides an improvement of at least 3 fold or of at least 10 dB. It should be noted that the output level of the lower and upper sidebands from the nonlinear carrier example, signals 2′ and 4′ are about 2 dB larger in amplitude than the upper and lower sideband signals 2 and 4 from the linear carrier example. If the input modulation level is reduced about 2 dB in the nonlinear carrier example to match the amplitudes of the (e.g., upper and/or lower) sidebands in the linear carrier example, simple power series distortion analysis would predict that the distortion in the nonlinear carrier example would improve about 2 dB, which would add 2 dB to the original 40 dB number to provide 42 dB; then the difference from the linear carrier example of having a 30 dB figure versus the 42 dB figure will be 12 dB or about a 4 fold improvement for equal sideband amplitudes in both linear carrier and non linear carrier examples.

An example description of a nonlinear carrier for reducing AM (amplitude modulation) distortion or for reducing sideband distortion (e.g., distortion signal whose frequency includes (f_{c}±n f_{mod}), where f_{c}=carrier frequency and f_{mod}=modulation frequency (e.g., for a sinusoidal modulation signal), and n=an integer≥2. One example nonlinear carrier signal includes a minima value and a maxima value, wherein the absolute value of positive slope and/or negative slope at or near the minima value is greater than the absolute values of the slopes near the maxima value; for example the waveform 105 in FIG. 26 (or other waveform) may be characterized in this manner. Another description may include a nonlinear waveform wherein near or at the minima value, the slopes are steeper than the slopes near the maxima values; wherein near a minima value may include a value slightly above the minima value, and/or wherein near the maxima value may include a value slightly below the maxima value. In another example, a nonlinear carrier waveform may include a mirrored version or inverted version of example waveform 105 (or other waveform) in FIG. 26 which includes the following: include a nonlinear waveform wherein near or at the minima value, the slopes are shallower (e.g., less) than the slopes near the maxima values; wherein near a minima value may include a value slightly above the minima value, and/or wherein near the maxima value may include a value slightly below the maxima value. One or more nonlinear carrier waveform may provide nonlinear pulsewidth modulation for the following: reducing AM (amplitude modulation) distortion or for reducing sideband distortion (e.g., distortion signal whose frequency includes (f_{c}±n f_{mod}), where f_{c}=carrier frequency and f_{mod}=modulation frequency (e.g., for a sinusoidal modulation signal), and n=an integer≥2.

Note that a sideband signal may be related or associated with a single sideband signal or a sideband signal may be related or associated with a double sideband signal. A single sideband signal (or a double sideband signal) may include a suppressed carrier signal; alternatively, a single sideband signal (or a double sideband signal) may include a carrier signal

A Quadrature Phase signal may have a positive 90 degrees (e.g., +90°) phase shift relative to an In Phase signal, or a Quadrature Phase signal may have a negative 90 degrees (e.g., −90°) phase shift relative to an In Phase signal.

An embodiment may include one or more method/apparatus as described in FIG. 1 through FIG. 34. In one embodiment example may include one or more of the following: DC restoration, multiple phase pulsewidth modulated signals, combiner, subtractor, processor, pre-distorted modulation signal, modulation signal, linear carrier signal, nonlinear carrier signal, In Phase modulation signal, Quadrature modulation signal, In Phase carrier signal, Quadrature Phase carrier signal, multiple single sideband signals synthesized from a fundamental frequency signal wherein a single sideband signal from a harmonic of the fundamental frequency is an opposite sideband signal when compared to the single sideband signal at the fundamental frequency, sine to triangle converter, comparator, nonlinear pulsewidth modulator, and/or digital mapping technique to equivalently provide pulsewidth modulation which may include linear or nonlinear pulsewidth modulation.

In any of examples mentioned or examples shown in the drawings, one or more of the pulses or waveforms may be implemented via digital hardware, one or more analog circuits, and/or software.

An embodiment may include a method/apparatus to process a signal for providing a single sideband signal comprising a modulating signal coupled to an input terminal of a DC restoration circuit, coupling an output signal from the DC restoration circuit to an input terminal of an In Phase processor; an output terminal of the In Phase processor provides a DC restored modulating In Phase signal. Further comprising coupling the output signal from the DC restoration circuit to an input terminal of a Quadrature Phase processor; an output terminal of the Quadrature Phase processor provides a DC restored modulating Quadrature signal, the DC restored modulating In Phase signal is coupled to a modulating input terminal of a first pulsewidth modulator; the first pulsewidth modulator includes a first phase carrier signal. Also including the first pulsewidth modulator provides a first pulsewidth modulated output signal, the DC restored modulating Quadrature Phase signal is coupled to a modulating input terminal of a second pulsewidth modulator. And further including the second pulsewidth modulator includes a second phase carrier signal, wherein the second pulsewidth modulator provides a second pulsewidth modulated output signal and that the first pulsewidth modulated output signal is combined with the second pulsewidth modulated output signal to provide a first single sideband signal; the first single sideband signal including a suppressed carrier signal when the modulating signal is zero.

An embodiment includes a method/apparatus of providing frequency translation of a modulating signal by coupling the modulating signal to an input terminal of a modulation signal phase processing unit and where the modulation phase processing unit provides the following: an In Phase modulating signal, an inverted In Phase modulating signal, a Quadrature Phase modulating signal, and an inverted Quadrature Phase modulating signal. Further comprising is the following: a first phase carrier signal, a second phase carrier signal, a third phase carrier signal, and a fourth phase carrier signal. Also included are the following: a first pulsewidth modulator including a modulation signal input terminal, a carrier input terminal, and an output signal terminal; a second pulsewidth modulator including a modulation signal input terminal, a carrier input terminal, and an output signal terminal; a third pulsewidth modulator including a modulation signal input terminal, a carrier input terminal, and an output signal terminal; a fourth pulsewidth modulator including a modulation signal input terminal, a carrier input terminal, and an output signal terminal; a fifth pulsewidth modulator including a modulation signal input terminal, a carrier input terminal, and an output signal terminal; a sixth pulsewidth modulator including a modulation signal input terminal, a carrier input terminal, and an output signal terminal; a seventh pulsewidth modulator including a modulation signal input terminal, a carrier input terminal, and an output signal terminal; and an eighth pulsewidth modulator including a modulation signal input terminal, a carrier input terminal, and an output signal terminal. This method/apparatus also includes the following: Coupling the first phase carrier signal to the carrier input terminal of the first pulsewidth modulator and coupling the In Phase modulation signal to the modulation signal input terminal of the first pulsewidth modulator; coupling the second phase carrier signal to the carrier input terminal of the second pulsewidth modulator and coupling the Quadrature Phase modulation signal to the modulation signal input terminal of the second pulsewidth modulator; coupling the third phase carrier signal to the carrier input terminal of the third pulsewidth modulator and coupling the In Phase modulation signal to the modulation signal input terminal of the third pulsewidth modulator; coupling the fourth phase carrier signal to the carrier input terminal of the fourth pulsewidth modulator and coupling the Quadrature Phase modulation signal to the modulation signal input terminal of the fourth pulsewidth modulator. And this method/apparatus includes coupling the third phase carrier signal to the carrier input terminal of the fifth pulsewidth modulator and coupling the inverted In Phase modulation signal to the modulation signal input terminal of the fifth pulsewidth modulator; coupling the fourth phase carrier signal to the carrier input terminal of the sixth pulsewidth modulator and coupling the inverted Quadrature Phase modulation signal to the modulation signal input terminal of the sixth pulsewidth modulator; coupling the first phase carrier signal to the carrier input terminal of the seventh pulsewidth modulator and coupling the inverted In Phase modulation signal to the modulation signal input terminal of the seventh pulsewidth modulator and then coupling the second phase carrier signal to the carrier input terminal of the eighth pulsewidth modulator and coupling the inverted Quadrature Phase modulation signal to the modulation signal input terminal of the eighth pulsewidth modulator. Furthermore this method/apparatus includes coupling the output signal of the first pulsewidth modulator to a first input terminal of a combiner and coupling the output signal of the second pulsewidth modulator to a second input terminal of the combiner and coupling the output signal of the third pulsewidth modulator to a third input terminal of the combiner and coupling the output signal of the fourth pulsewidth modulator to a fourth input terminal of the combiner. This method further includes coupling the output signal of the fifth pulsewidth modulator to a fifth input terminal of the combiner; coupling the output signal of the sixth pulsewidth modulator to a sixth input terminal of the combiner; coupling the output signal of the seventh pulsewidth modulator to a seventh input terminal of the combiner and coupling the output signal of the eighth pulsewidth modulator to a second input terminal of the combiner. The combiner provides an output signal including at least one single sideband signal with suppressed carrier and wherein at least one single sideband suppressed carrier signal provides frequency translation to the modulation signal.

An embodiment includes method to provide multiple single sideband signals includes providing multiple In Phase modulation signals and multiple Quadrature Phase modulation signals to a processor including multiple pulsewidth modulators and providing multiple In Phase carrier signals and multiple Quadrature Phase carrier signals to the processor including multiple pulsewidth modulators. The processor providing at least four pulsewidth modulated signals wherein each of the at least four pulsewidth modulated signals include at least four phases to provide at least a sequence of four pulsewidth modulated signals, and combining at four pulsewidth modulated signals to provide a single sideband signal at a fundamental frequency and a single sideband signal of an opposite sideband at a harmonic of the fundamental frequency. Furthermore, this embodiment may include: A) Four pulsewidth modulated signals of four different phases when combined provides single sideband signal with carrier signal at a fundamental carrier frequency and a single sideband signal with carrier signal of an opposite sideband at a harmonic of the fundamental carrier frequency, and/or B) Eight pulsewidth modulated signals of eight different phases when combined provides single sideband signal suppressed carrier signal at a fundamental carrier frequency and a single sideband signal suppressed carrier signal of an opposite sideband at a harmonic of the fundamental frequency.

This disclosure is illustrative and not limiting; further modifications will be apparent to one skilled in the art and are intended to fall within the scope of the appended claims and or of the embodiments described.

That which is claimed is:

1. A method to process a signal for providing a single sideband signal comprising:
a modulating signal coupled to an input terminal of a DC restoration circuit;
coupling an output signal from the DC restoration circuit to an input terminal of an In Phase processor;
an output terminal of the In Phase processor provides a DC restored modulating In Phase signal;
coupling the output signal from the DC restoration circuit to an input terminal of a Quadrature Phase processor;
an output terminal of the Quadrature Phase processor provides a DC restored modulating Quadrature signal;
the DC restored modulating In Phase signal is coupled to a modulating input terminal of a first pulsewidth modulator;
the first pulsewidth modulator includes a first phase carrier signal;
the first pulse modulator provides a first pulsewidth modulated output signal;
the DC restored modulating Quadrature Phase signal is coupled to a modulating input terminal of a second pulsewidth modulator;
the second pulsewidth modulator includes a second phase carrier signal;
the second pulsewidth modulator provides a second pulsewidth modulated output signal;
the first pulsewidth modulated output signal is combined with the second pulsewidth modulated output signal to provide a first single sideband signal;
the first single sideband signal including a suppressed carrier signal when the modulating signal is zero.

2. The method of claim 1 further comprising a Hilbert Transform to provide the DC restored modulating Quadrature Phase signal.

3. The method of claim 2 further comprising the DC restored modulating In Phase coupled to a modulating input terminal of a third pulsewidth modulator;
the third pulsewidth modulator includes a third phase carrier signal;
the third pulsewidth modulator provides a third pulsewidth modulated output signal;
the DC restored modulating Quadrature phase signal coupled to a modulating input terminal of a fourth pulsewidth modulator;
the fourth pulsewidth modulator includes a fourth phase carrier signal;
the fourth pulsewidth modulator provides a fourth pulsewidth modulated output signal;
the third pulsewidth modulated signal is combined with the fourth pulsewidth modulated signal to provide a second single sideband signal;
the second single sideband signal including a suppressed carrier signal when the modulating signal is zero;
the first single sideband signal is combined or subtracted with the second single sideband signal to provide a third single sideband signal.

4. The method of claim 3 further comprising the signal sideband signal is coupled to an input terminal of a switching amplifier.

5. The method of claim 4 further comprising the switching amplifier includes a Class D, E, or S amplifier.

6. The method of claim 3 further comprising a double edge pulsewidth modulation on a pulse to minimize a phase modulation when compared to a single edge pulse width modulation.

7. The method of claim 6 further comprising to minimize the phase modulation on the single sideband signal.

8. A method of providing frequency translation of a modulating signal comprising:
coupling the modulating signal to an input terminal of a modulation signal phase processing unit;
the modulation phase processing unit provides an In Phase modulating signal, an inverted In Phase modulating signal, a Quadrature Phase modulating signal, and an inverted Quadrature Phase modulating signal, further comprising;
a first phase carrier signal, a second phase carrier signal, a third phase carrier signal, and a fourth phase carrier signal;
a first pulsewidth modulator including a modulation signal input terminal, a carrier input terminal, and an output signal terminal;
a second pulsewidth modulator including a modulation signal input terminal, a carrier input terminal, and an output signal terminal;
a third pulsewidth modulator including a modulation signal input terminal, a carrier input terminal, and an output signal terminal;
a fourth pulsewidth modulator including a modulation signal input terminal, a carrier input terminal, and an output signal terminal;
a fifth pulsewidth modulator including a modulation signal input terminal, a carrier input terminal, and an output signal terminal;
a sixth pulsewidth modulator including a modulation signal input terminal, a carrier input terminal, and an output signal terminal;
a seventh pulsewidth modulator including a modulation signal input terminal, a carrier input terminal, and an output signal terminal;
an eighth pulsewidth modulator including a modulation signal input terminal, a carrier input terminal, and an output signal terminal;
coupling the first phase carrier signal to the carrier input terminal of the first pulsewidth modulator and coupling the In Phase modulation signal to the modulation signal input terminal of the first pulsewidth modulator;
coupling the second phase carrier signal to the carrier input terminal of the second pulsewidth modulator and coupling the Quadrature Phase modulation signal to the modulation signal input terminal of the second pulsewidth modulator;
coupling the third phase carrier signal to the carrier input terminal of the third pulsewidth modulator and coupling the In Phase modulation signal to the modulation signal input terminal of the third pulsewidth modulator;
coupling the fourth phase carrier signal to the carrier input terminal of the fourth pulsewidth modulator and coupling the Quadrature Phase modulation signal to the modulation signal input terminal of the fourth pulsewidth modulator;
coupling the third phase carrier signal to the carrier input terminal of the fifth pulsewidth modulator and coupling the inverted In Phase modulation signal to the modulation signal input terminal of the fifth pulsewidth modulator;
coupling the fourth phase carrier signal to the carrier input terminal of the sixth pulsewidth modulator and coupling the inverted Quadrature Phase modulation signal to the modulation signal input terminal of the sixth pulsewidth modulator;
coupling the first phase carrier signal to the carrier input terminal of the seventh pulsewidth modulator and coupling the inverted In Phase modulation signal to the modulation signal input terminal of the seventh pulsewidth modulator;
coupling the second phase carrier signal to the carrier input terminal of the eighth pulsewidth modulator and coupling the inverted Quadrature Phase modulation signal to the modulation signal input terminal of the eighth pulsewidth modulator;
coupling the output signal of the first pulsewidth modulator to a first input terminal of a combiner;
coupling the output signal of the second pulsewidth modulator to a second input terminal of the combiner;
coupling the output signal of the third pulsewidth modulator to a third input terminal of the combiner;
coupling the output signal of the fourth pulsewidth modulator to a fourth input terminal of the combiner;
coupling the output signal of the fifth pulsewidth modulator to a fifth input terminal of the combiner;
coupling the output signal of the sixth pulsewidth modulator to a sixth input terminal of the combiner;
coupling the output signal of the seventh pulsewidth modulator to a seventh input terminal of the combiner;
coupling the output signal of the eighth pulsewidth modulator to a second input terminal of the combiner;
wherein the combiner provides an output signal including at least one single sideband signal with suppressed carrier and wherein at least one single sideband suppressed carrier signal provides frequency translation to the modulation signal.

9. The method of claim 8 further comprising the combiner provides multiple pairs of combined signals and two or more of the multiple pairs of combined signals are subtracted to provide a first subtracted signal and a second subtracted signal, wherein the first subtracted signal is subtracted from the second subtracted signal.

10. The method of claim 8 further comprising the first phase carrier signal, the second phase carrier signal, the third phase carrier signal, and the fourth phase carrier signal each includes a nonlinear waveform to reduce sideband distortion for at least one single sideband suppressed carrier signal.

11. The method of claim 10 wherein the nonlinear waveform includes a rectified sine wave signal or a parabolic waveform.

12. The method of claim 8 further comprising the modulation signal includes DC restoration.

13. The method of claim 8 wherein double edge pulsewidth modulated signals are included in the output signals of the first pulsewidth modulator, the second pulsewidth modulator, the third pulsewidth modulator, the fourth pulsewidth modulator, the fifth pulsewidth modulator, the sixth pulsewidth modulator, the seventh pulsewidth modulator, and the eighth pulsewidth modulator.

14. The method of claim 10 wherein the nonlinear waveform may be characterized as absolute value of a sine function.

15. The method of claim 8 further comprising a pre-distorted modulation signal and/or a nonlinear carrier signal to provide for an improved amplitude modulation linearity of single sideband signal.

16. The method of claim 15 wherein the pre-distorted modulation signal is provided by processing the modulation signal with a sine to triangle converter circuit.

17. The method of claim 16 wherein the sine to triangle converter circuit includes field effect multiplier transistor circuit, a triangle wave to sine wave converter, and/or a differential amplifier with diode loads.

18. A method to provide multiple single sideband signals comprising:
providing multiple In Phase modulation signals and multiple Quadrature Phase modulation signals to a processor including multiple pulsewidth modulators;
providing multiple In Phase carrier signals and multiple Quadrature Phase carrier signals to the processor including multiple pulsewidth modulators;
the processor providing at least four pulsewidth modulated signals wherein each of the at least four pulsewidth modulated signals include at least four phases to provide at least a sequence of four pulse width modulated signals;
combining at four pulsewidth modulated signals to provide a single sideband signal at a fundamental frequency and a single sideband signal of an opposite sideband at a harmonic of the fundamental frequency.

19. The method in claim 18 where four pulsewidth modulated signals of four different phases when combined provides single sideband signal with carrier signal at a fundamental carrier frequency and a single sideband signal with carrier signal of an opposite sideband at a harmonic of the fundamental carrier frequency.

20. The method in claim 18 where eight pulsewidth modulated signals of eight different phases when combined provides single sideband signal suppressed carrier signal at a fundamental carrier frequency and a single sideband signal suppressed carrier signal of an opposite sideband at a harmonic of the fundamental frequency.
